(19) United States
(12) Patent Application Publication
(10) Pub. No.: US 2014/0014403 A1
(43) Pub. Date: Jan. 16, 2014

(54) ENERGY STORAGE AND DISPENSING FLEXIBLE SHEETING DEVICE

(71) Applicants: Robert J. Miller, La Jolla, CA (US); Marsha Grade, Niskayuna, NY (US); Amber Brooks, Clifton Park, NY (US); Trevor Simmons, Rhinebeck, NY (US); Frank Kovacs, Clifton Park, NY (US); Kenneth Lenseth, Voorheesville, NY (US); Luis Sanchez, Scotia, NY (US); George Allen, La Jolla, CA (US)

(72) Inventors: Robert J. Miller, La Jolla, CA (US); Marsha Grade, Niskayuna, NY (US); Amber Brooks, Clifton Park, NY (US); Trevor Simmons, Rhinebeck, NY (US); Frank Kovacs, Clifton Park, NY (US); Kenneth Lenseth, Voorheesville, NY (US); Luis Sanchez, Scotia, NY (US); George Allen, La Jolla, CA (US)

(21) Appl. No.: 13/417,199

(22) Filed: Mar. 9, 2012

Related U.S. Application Data
(63) Continuation of application No. 13/135,608, filed on Jul. 11, 2011, now abandoned.

(51) Int. Cl. H05K 1/18

(52) U.S. Cl. 174/260

(57) ABSTRACT

An energy storing and dispensing sheeting having addressable energy storing cells is disclosed. A free-forming process of fabricating energy storing sheets is disclosed. An interconnect interface for operatively coupling the energy storing sheeting to an external element is disclosed. A flexible printed circuit board with patterned energy storing layers is disclosed. An adhesive, flexible energy storing sheeting is disclosed. Energy storing sheet that can be mechanically tuned and patterned as a structural building material is disclosed. A networked grid storage embodiment of a structural energy storing sheeting is disclosed. An energy storing sheeting powering computer memory and integrated circuits is disclosed. A puncture tolerant energy storage device is disclosed. An ultracapacitor having a separator, symmetric or asymmetric electrodes, electrolyte and a current collector is disclosed. A battery, supercapacitor and hybrid device is disclosed. Variable RC time constants and voltages within an energy storing sheeting are disclosed.

### PRIORITY CLAIM

This is a continuation patent application, which claims the benefit of priority from co-pending U.S. patent application Ser. No. 13/135,608 to Miller et al., entitled “Energy Storage and Dispensing Flexible Sheeting Device” and filed Jul. 11, 2011, which is fully incorporated herein by reference for all purposes to the extent not inconsistent with the present patent application.

### TECHNICAL FIELD

The disclosed method and apparatus relates to the storage of electrical energy, and more particularly, some embodiments relate to use of a flexible pad or strip of energy storing material from which energy can be recovered.

### BACKGROUND

In today's modern world of electronics, it is axiomatic that electrical power is a fundamental requirement for almost any device to operate. Few new products today can function without some source of electrical power, however small that amount of electrical power might be.

In a significant number of applications, there is a significant advantage to having a portable source of electrical power. In such cases, electrical power is typically stored within a structure. Storing electrical power has traditionally been confined to conventional batteries. Such batteries are typically of solid construction and susceptible to damage if punctured or otherwise structurally compromised. Furthermore, the size and weight of such batteries significantly influences the construction of those products that require electrical power.

Therefore, it would be a significant advantage to be able to reduce the constraints that are placed on electronic devices by allowing for a more flexible, lightweight and durable means for storing and dispensing electrical power that can conform to the size and shape of the device into which the power source is to be used.

### SUMMARY OF DISCLOSED METHOD AND APPARATUS

The following presents a simplified summary of one or more embodiments in order to provide a basic understanding of some aspects of such embodiments. This summary is not an extensive overview of the one or more embodiments, and is intended to neither identify key or critical elements of the embodiments nor delineate the scope of such embodiments. Its sole purpose is to present some concepts of the described embodiments in a simplified form as a prelude to the more detailed description that is presented later.

One embodiment of the presently disclosed method and apparatus provides a versatile energy storing “tape” that is dispersed as discrete segments from a roll containing the tape. The tape enables rapid prototyping of devices having a wide variety of power supply requirements. The tape can be used for virtually any application requiring power. In one embodiment, the tape is flexible with a bending radius of 1 cm or less. Furthermore, the tape has robust mechanical properties that allow the tape to be flexed multiple times. Still further, the disclosed tape can supply physically “formable power”. In accordance with one embodiment of the disclosed method and apparatus, the tape includes a standard pin-out interface to which external components can be soldered.

In an aspect, an electronic tape (Etape™) is described herein. Etape™ is a flexible energy storing tape roll with or without an adhesive backing that can be formatted like any other tape product of similar nature. It can in fact be substituted for masking tape, duct tape or ribbon-like material. The difference is that it can be charged and discharged when properly interfaced to a power supply or load respectively. High voltages can be formatted by z-folding back onto a common surface to form a brick-like or prismatic device or by shingling multi-layered strips into an alternate pattern such that the underside to topside are interconnected to form large areas of power at high voltage in a fashion similar to roofing materials. In addition, the Etape can be cut to form or folded or adhered to many surface types. To make electrical contact, the tape can be inductively or direct connected to loads or power.

The Etape allows for a dynamic patterning for receiving one or more components. This may be performed at a print shop thereby offering customizable fit to form. The patterns may include holes, slots and filled vias.

The energy source comprises a battery, supercapacitor, solar cells or any other source of power. Also, the energy source comprises a power plane and a ground plane.

E-Tape™ design characteristics: A versatile energy storing tape or ribbon that is dispersed as discrete segments from a roll containing the same. The design of the tape or ribbon is in a manner that enables the rapid prototyping of power supply requirements for virtually any application requiring power. The novel properties include its flexible format with a bending radius of 1-cm or less, robust mechanical properties that enable multiple flex or formable power, stackable in series for increased voltage or parallel for increased capacitance. The design includes a means of interfacing electronic components by means of standard pin-out and soldering.

Flexible PCB: at least one segment is dispensed from a roll and the pin-outs of the design are used to attach various electronic components to the flexible “printed circuit board.”

In this application, at least one segment is dispensed from a roll and the pin-outs of the design are used to attach various electronic components to the flexible “printed circuit board.”

### BRIEF DESCRIPTION OF THE DRAWINGS

The disclosed method and apparatus, in accordance with one or more various embodiments, is described with reference to the following figures. The drawings are provided for purposes of illustration only and merely depict examples of some embodiments of the disclosed method and apparatus. These drawings are provided to facilitate the reader's understanding of the disclosed method and apparatus. They should not be considered to limit the breadth, scope, or applicability of the claimed invention. It should be noted that for clarity and ease of illustration these drawings are not necessarily made to scale.

The figures are not intended to be exhaustive or to limit the claimed invention to the precise form disclosed. It should be understood that the disclosed method and apparatus can be practiced with modification and alteration, and that the invention should be limited only by the claims and the equivalents thereof.

### DETAILED DESCRIPTION

While various embodiments of the disclosed method and apparatus have been described above, it should be understood that they have been presented by way of example only, and should not limit the claimed invention. Likewise, the various diagrams may depict an example architectural or other configuration for the disclosed method and apparatus. This is done to aid in understanding the features and functionality that can be included in the disclosed method and apparatus. The claimed invention is not restricted to the illustrated example architectures or configurations, rather the desired features can be implemented using a variety of alternative architectures and configurations. Indeed, it will be apparent to one of skill in the art how alternative functional, logical or physical partitioning and configurations can be implemented to implement the desired features of the disclosed method and apparatus. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the disclosed method and apparatus is described above in terms of various exemplary embodiments and implementations, it should be understood that the various features, aspects and functionality described in one or more of the individual embodiments are not limited in their applicability to the particular embodiment with which they are described. Thus, the breadth and scope of the claimed invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosed method and apparatus may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

“Print forming” is defined as any direct contact or non-contact marking technology that is recognizable to one experienced in the field of printing and electronic printing.

“Indirect print” is defined as any non-contact print forming technology where individual droplets of marking material (ink) are used as markers on a substrate or material or in-flight. At least one of the technologies known as spray (ultra-sonic or aerosol), ink jet, airbrush are typically used alone or in combination with other print forming technologies.

“Direct print” is defined as any direct contact print forming technology where the physiochemical nature of the substrate (receiving surface) and a marking device such as a nano imprinting, drum, roll, bar, slide (transfer surface) jointly participate in establishing the amount of marking material (ink) transferred and the resulting properties of the final printed film. At least one of the marking technologies commonly known as screen print, gravure, flexographic, nano imprinting or draw bar are typically used alone or in combination with other print forming technologies.

“Nanoscale interlock” is defined as the pinning of near surface print formed thick-film materials through physical interlacing and subsequent interactions between high aspect ratio particles or polymeric materials on a nanoscale. Said pinning may or may not include electron transfer common to chemical bond formation. Typical film based geometric aspect ratios (z verses the x-y plane of films) of the interlocked materials pinned are at least 1:1 where higher aspect ratios are desired and at least 3:1 may be preferable. The intent is to build physical legs of high aspect ratio with subsequently high surface areas into the receiving or transferred surfaces or both. Typical length scales of the interlacing frequency within the x-y plane of the film also termed the interval lengths are typically 10-nm to 300-nm but may be as much as 1-micron. Smaller scales are common to chemical bonding which may or may not be solicited in our devices.

“Large scale interlock” is defined as the near surface pinning of print formed thick-film materials at interval lengths exceeding 1-um. When such large scale interlocks include high aspect ratio legs a desirable interlock may still be formed provided that the total surface area gain is suitable. Devices when built as layered structures without high aspect ratio interlacing are commonly referred to as laminated structures with or without an adhesive present. A high aspect ratio large dimensioned leg with suitably high surface area is feasible and included within this invention.

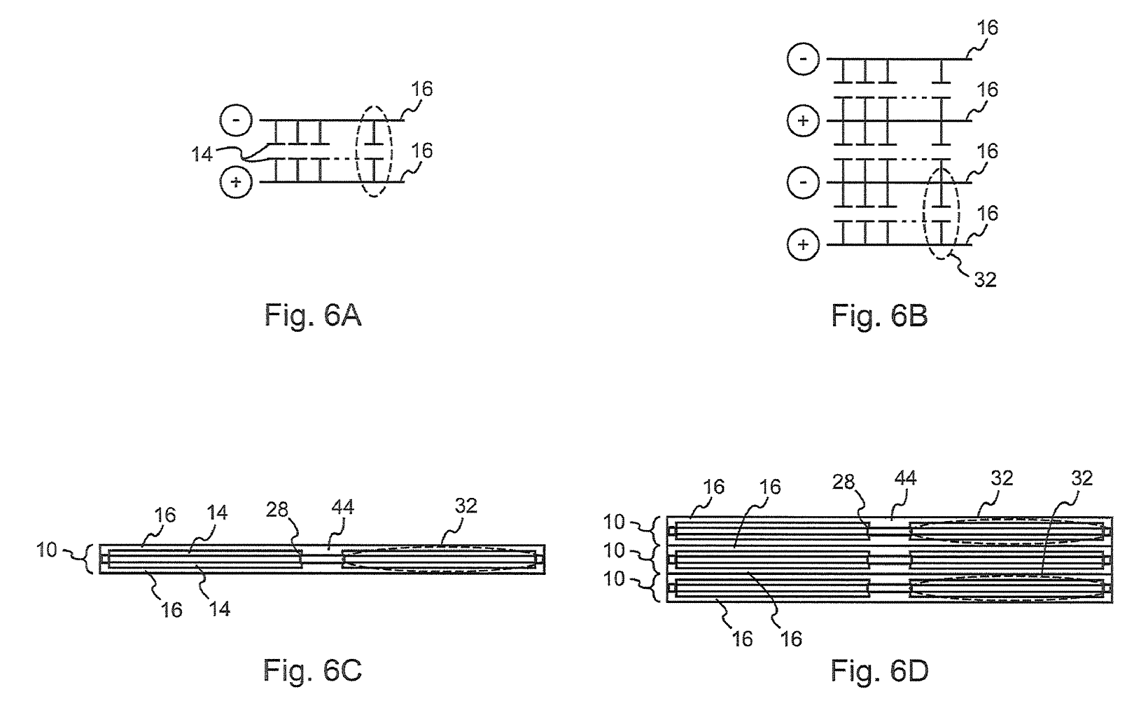

“Ring-seal” is defined as a special case of interlocking between at least two materials utilizing nanoscale or large-scale or both interlocking mechanisms. The intent is to form a concentration gradient between the two materials using print forming manufacturing technologies. The result is the formation of a volume element comprised of a known concentration of the respective starting materials. In addition to controlling x-y concentration profiles, z-axis profiles may also be controlled by print forming. A representation of the ring-seal is depicted within FIGS. 6A and 6B and will be described herein below.

“Nanocomposite” is defined as a physical interlacing between dissimilar materials on a nanoscale typically sub-micron in dimension. For printed films, maximizing weak physical interactions within multi-layered print formed materials by increasing the effective contact area with high aspect ratio legs and by reducing the length scale of the interlocking frequency in the x-y plane to nanoscale is a desirable aspect of the embodiments described herein. By so doing, homogenous composite like properties are possible between films of highly heterogeneous print formed thick-film materials.

### BRIEF DESCRIPTION OF THE DRAWINGS

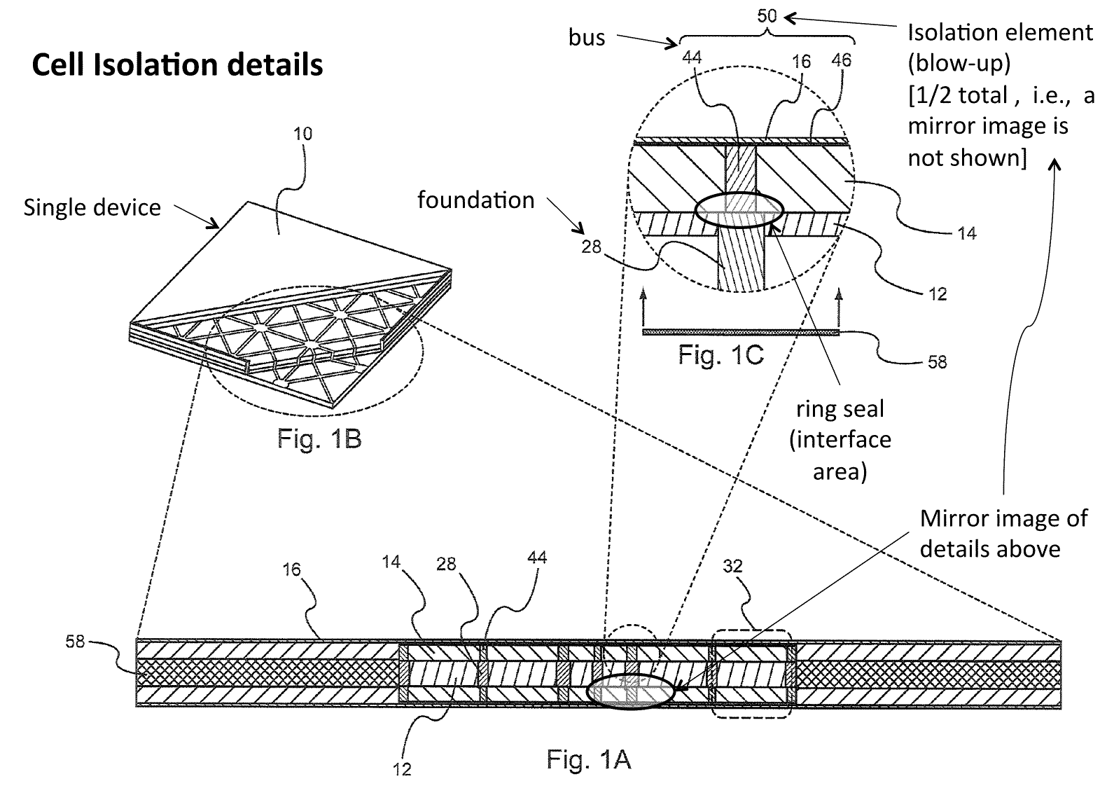

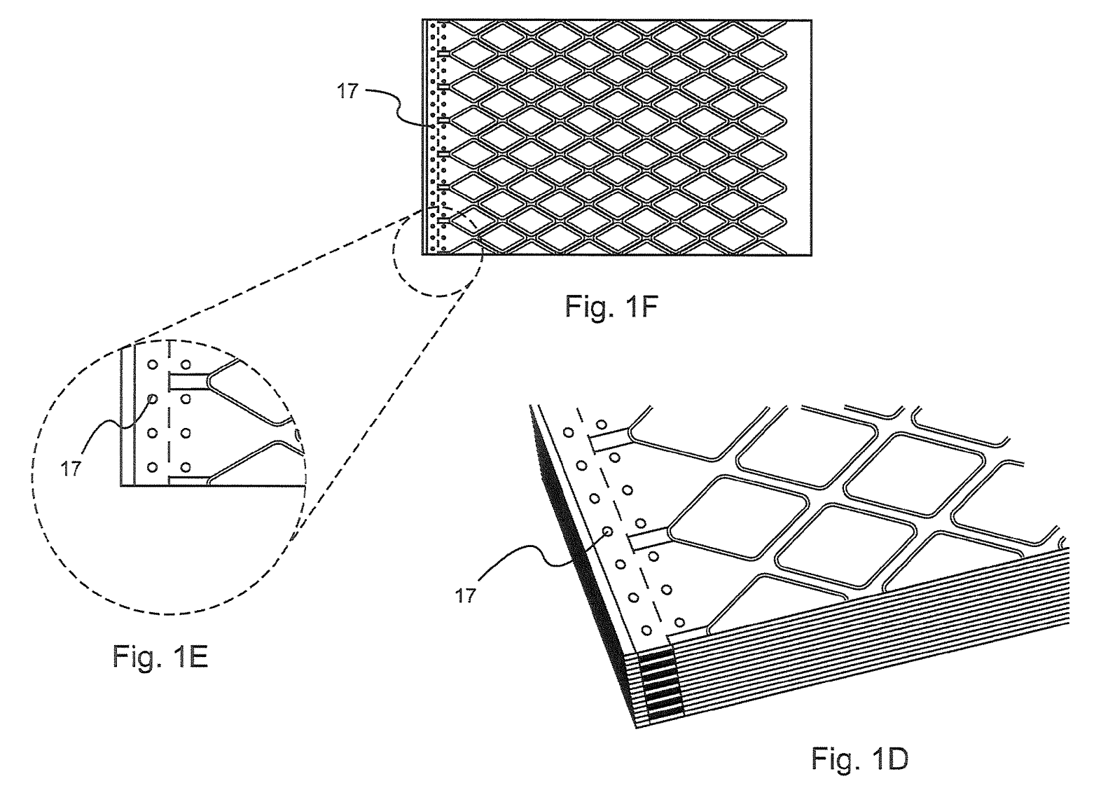

FIG. 1A depicts a perspective cutaway view of a structural sheet for storing energy and providing fault tolerance in accordance with one embodiment;

FIG. 1B depicts a layered view from the top of the structural sheet with the device layers shown cutaway in accordance with one embodiment;

FIG. 1C depicts an intersection of a foundation and current bus walls in accordance with one embodiment;

FIG. 1D depicts an end pin out for a multi-layered stack of individual devices in accordance with one embodiment;

FIG. 1E depicts a close-up view of the pin out in accordance with one embodiment;

FIG. 1F depicts a perspective view of the structural sheet with the pin out connector layer in accordance with one embodiment;

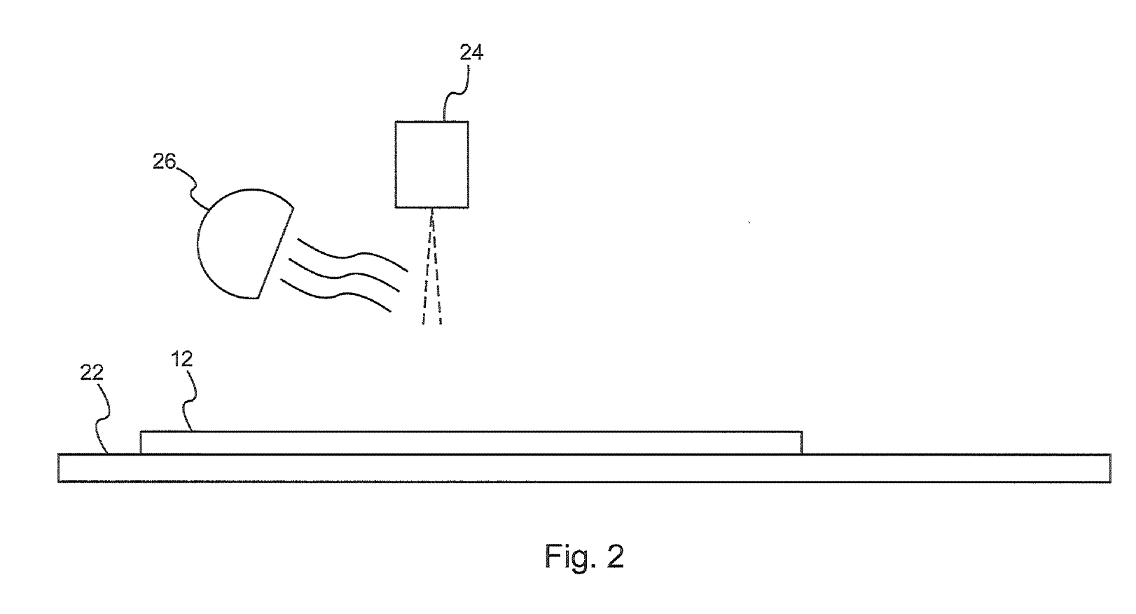

FIG. 2 depicts a step of applying a separator layer to make the sheet of FIGS. 1-2, in accordance with one embodiment;

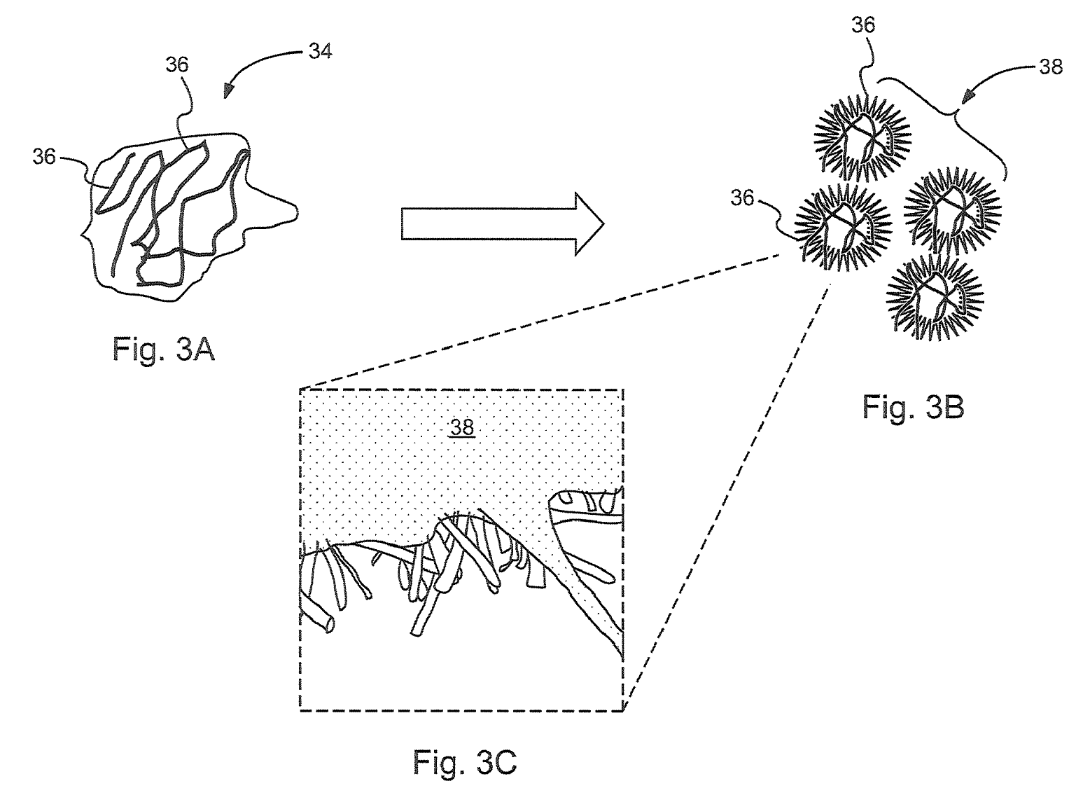

FIG. 3A depicts a representation of the first of two stages of creating electrode in accordance with one embodiment;

FIG. 3B depicts a representation of the second of two stages of creating electrode in accordance with one embodiment;

FIG. 3C depicts a close-up microscopic image of the surface of an electrode particle in accordance with one embodiment;

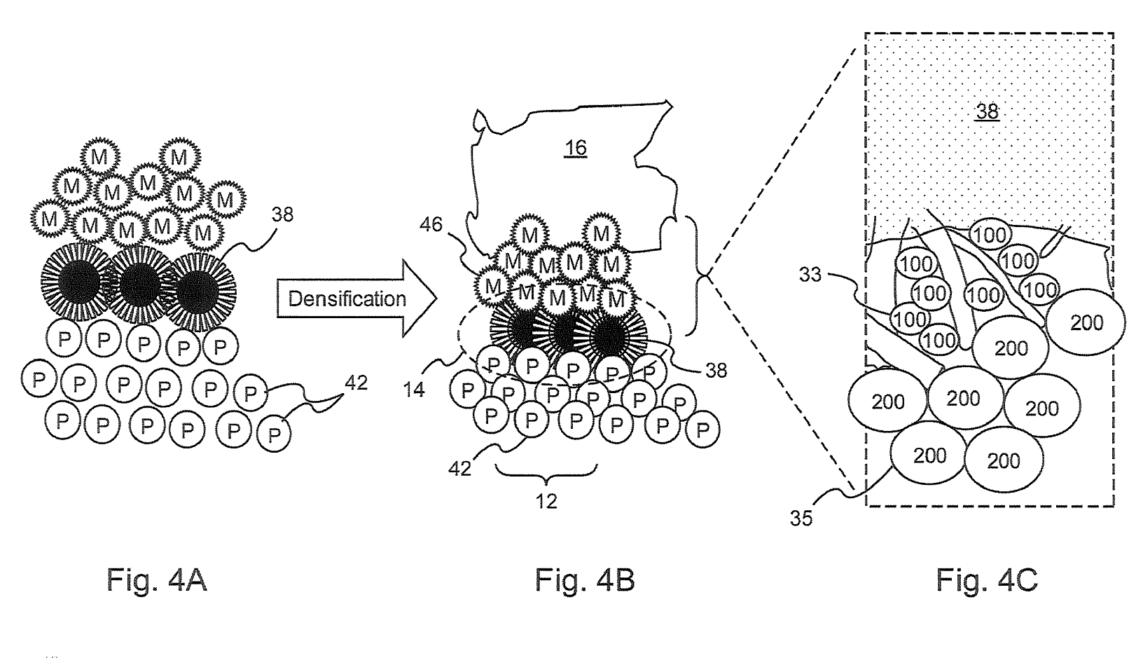

FIG. 4A depicts a nano-scale representation in the first step of forming the interlock between the separator layer of FIG. 2 and the electrode layer of FIG. 1 and a cap layer of a current collector in accordance with one embodiment;

FIG. 4B depicts a nano-scale representation of the interlock between the separator layer of FIG. 3 and the electrode layer of FIGS. 4A-4C and the cap layer of the current collector in accordance with one embodiment;

FIG. 4C depicts a nanoscale representation of the detailed interlock between the electrode and the cap layer of the current collector layer in accordance with one embodiment;

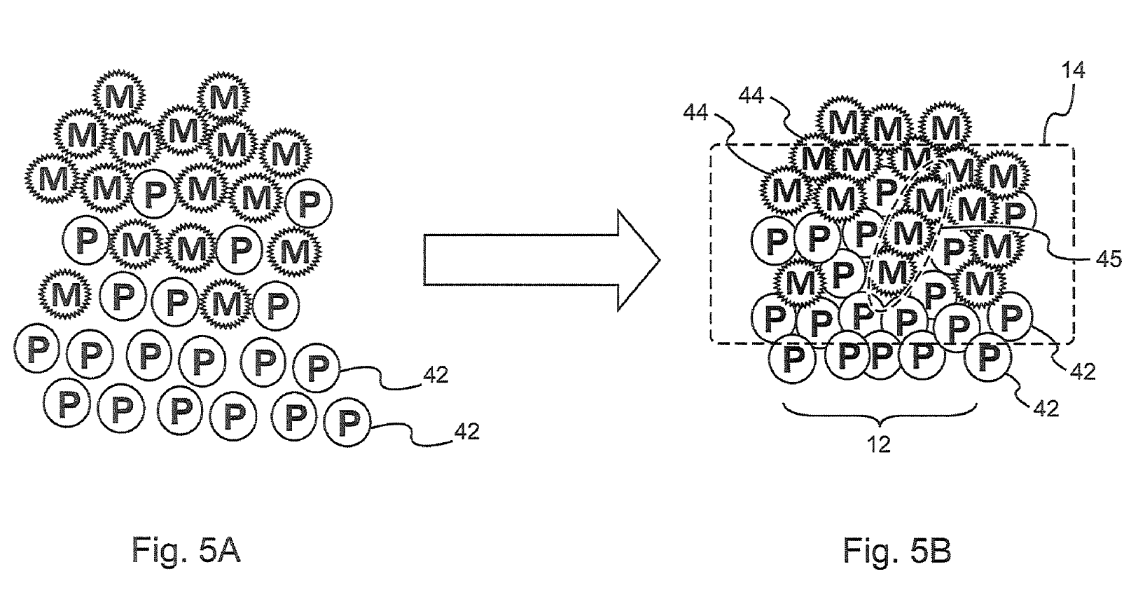

FIG. 5A depicts a representation of the first step of formation of a ring seal of the structural sheet in accordance with one embodiment;

FIG. 5B depicts a representation of the second step of formation of a ring seal of the structural sheet in accordance with on embodiment;

FIG. 6A depicts an equivalent circuit for a single layer of the structural sheet device with energy storage;

FIG. 6B depicts an equivalent circuit for a multi-layered structural sheet device with energy storage;

FIG. 6C depicts a cross sectional view of a single layer of the structural sheet device with energy storage that comprises the energy storing unit shown in FIG. 1;

FIG. 6D depicts a multi-layered structural sheet device with energy storage that comprises a plurality of the energy storing units shown in FIG. 1, stacked together; and

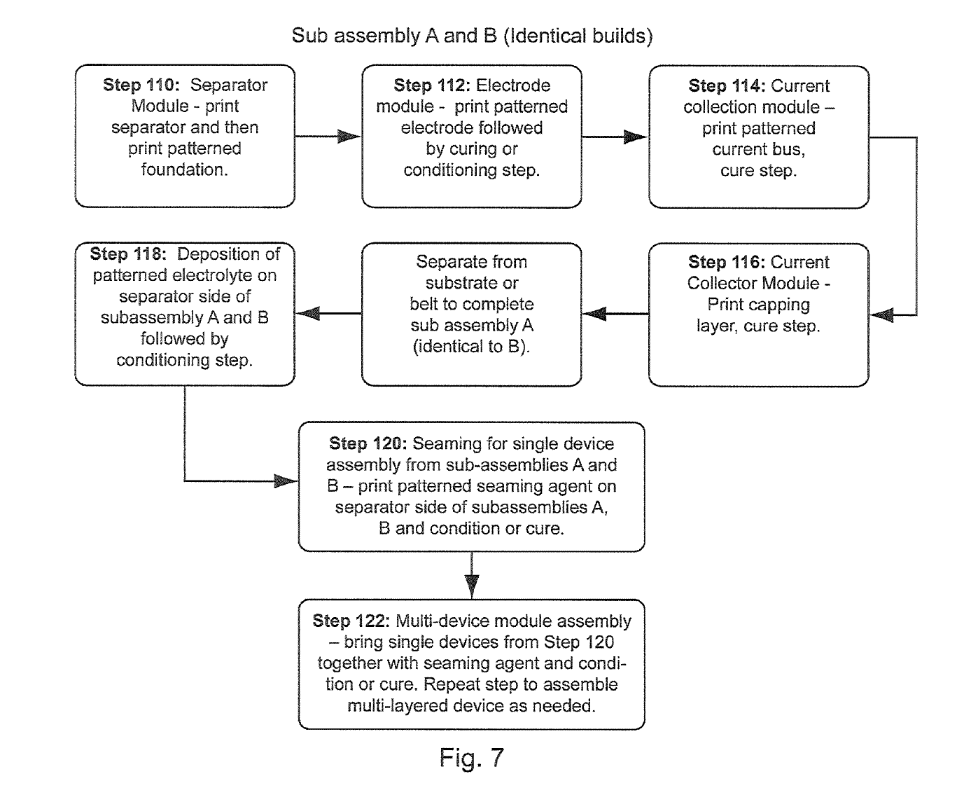

FIG. 7 depicts a process diagram for creating the structural sheet and an integrated stack in accordance with one embodiment.

Referring now to FIGS. 1A-1F, an embodiment of structural sheet 10 for storing energy and providing fault tolerance is shown. The sheet 10 may be made or manufactured using print forming processes. Each of the components of the sheet 10 may be manufactured with a print formed process. Both direct printing and indirect printing processes are contemplated. The sheet 10 may have an energy storage density that is greater than 10-mWh/ft2 and is capable of withstanding greater than 5-KPa stress under at least 5% strain. The sheet 10 may be made from one or more sub assemblies 18, 20 that are print formed onto a substrate or substrate 22. The substrate 22 may be mismatched to the thermal properties of the sub assemblies for easy dismounting the sub assemblies from the substrate at the end of a process line. The substrate 22 may be a tempered glass, or a SS web, or a consumable carbon based veil for example.

In general, the batch processed sheet 10 depicted in FIGS. 1A-1F is fabricated by first print forming two sub-assemblies, then dismounting the two sub-assemblies from the substrate 22 or substrates, then loading with electrolyte that is compatible from the foundation side then adding a seaming plasticizing agent to the foundation side then aligning the two sub-assemblies with their foundations facing one another and sealing by calendaring the two sub-assemblies into a single sheet device 10. It should be understood that the sub assemblies may be identical sub assemblies. The sub assemblies may be dismounted from the substrate 22 and aligned foundation-to-foundation and seamed into the energy storing structural sheet 10.

The sheet 10 may include a print formed separator layer 12 that is located between two print formed electrodes 14 and current buses 44 and two electrode cap layers 46 and two print formed current collectors 16. An electrical pinout 17 or connection plane may be print formed onto the current collector 16 to output energy for external distribution that is stored in the sheet 10 or input energy to charge the sheet 10. A planar interconnection enables higher cycling frequency when connected to a planar thermal heat sink (not illustrated). The separator layer 12 is shown as the middle layer of the sheet 10. For symmetrical builds, the print formed current collector 16, electrode 14 and current bus 44 ensemble above and below the separator layer 12 are the same. Variations to a symmetrical build are feasible for incorporating hybrid, battery, or supercapacitor technologies into the sheet. When the layering above and below are the same, the sheet 10 may be created by printing the above sub assembly and the below sub assembly on the substrate 22 as shown in the cutaway perspective view of FIG. 2. In one embodiment, once each of the steps to create the two sub assemblies have been applied, the above sub assembly and the below sub assembly may then be folded along a print formed perforated crease 56 that serves as an alignment feature together to form the completed sheet 10.

Referring now to FIG. 2, a possible first step of making the sheet 10 is shown. This step first may indirectly print the porous separator film 12 onto the substrate 22. The separator film 12 may be an electrically insulating material made from a Cellulose Triacetate (CTA) solution. The solution may be a 1.67 wt % CTA solution, for example. However, it should be understood that other CTA concentrations are contemplated. In addition to the CTA, the solution may include other compounds such as Chloroform, Acetone and Methanol. The separator film 12 compound may be derived from an ink solution that is printable by indirect printing onto the substrate 22. Furthermore, the substrate 22 may be glass or any other appropriate flat surface that would be apparent to one skilled in the art.

The separator film 12 may be formed using an indirect print by being uniformly sprayed onto the flat substrate 22 by known means. One or more spray layers may be applied and interlaced along the surface such that the separator film 12 is uniformly formed. A heat lamp 26 may be utilized between the glass and the nozzle 24 in order to cure the sprayed solution as it is being transferred between the nozzle 24 and the substrate 20. This curing may help define the porosity and elasticity of the final separator film 12.

Furthermore, many embodiments are contemplated for performing the method of applying the separator film 12. Those skilled in indirect print forming processing are familiar with these methods to control the printed thick film properties of various materials. Thus, the pores and the elasticity of the separator 12 are tunable by the print forming of the separator 12.

All of these parameters may be changed with the goal of creating a separator film 12 having a thickness between 5-40 microns that is porous, having well defined pore structures demonstrating suitable dielectric properties for the voltage range at thicknesses of interest. The pores may be torturous and have an effective length that is 2 to many times greater than the true thickness of the separator 12. The pores may further be utilized to enable proper meshing with the electrode layers 14, described herein below. The separator film 12 may incorporate encapsulated particles such as ceramics or conductive materials to reduce the propensity for dielectric breakdown. The porous separator 12 may further incorporate carbon nanotubes or nano-fibrous materials at a concentration density that is below the percolation threshold that may also entangle with the electrode layer 14 on either side of the separator film 12 such that the mechanical strength between the two materials is improved significantly. Dissimilar nanoparticles may be used to build torturous pores. Furthermore, while spraying using the nozzle 24 is shown in FIG. 3, other embodiments are contemplated for printing the uniform separator film 12 onto the substrate 14. While one of the embodiments contemplated includes the separator film 12 being used with the sheet 10, the separator film 12 may also be manufactured and sold as a sub-assembly unit for other sheets (not shown) or purposes. Thus, energy may be storable in the separator 12 for electrical double layered capacitors.

Referring still to FIG. 1, the sheet 10 may further include a patterned non-porous foundation 28 that is printed over the separator layer 12 on the substrate 14 in a manner that enables the closing or blocking of the immediately underlying porous separator film. The foundation 28 may be directly printed onto the porous film of the separator film 12 in such a matter to enable to conversion of the porous film into the patterned non-porous foundation 28 grid without impacting the uniformity of thickness throughout the separator surface. The foundation 28 grid may be made such that massively parallel porous separator cells 32 are formed that are separated by the non-porous foundation 28. The foundation 28, in conjunction with the separator film 12, may facilitate stress management within the sheet 10, helping to allow the sheet to be mechanically flexible and also aid in handling or mounting without damaging the electrical properties of the device. Further, the cells may provide puncture tolerance to the sheet 10.

The foundation 28 may be another CTA solution. However, the solution for the foundation 28 may have a much greater CTA wt % as it is applied by a direct print method. For example, the solution may be 9% CTA. The foundation 28 may be an ink solution that is indirectly printable on the substrate 22. The ink formulation may include a dilute CTA solution like previous discussed for the separator film. This precise indirect printing is accomplished by moving the nozzle or substrate in order to achieve the patterned desired. The pattern in which the foundation 28 is applied is a number of boxes with X's through them to create four triangular cells 32 per box. Thus, the triangular cells 32 of FIG. 2 are actually the portion of the separator film 12 that the foundation 28 was not applied. The triangular cells 32 therefore still have the porous surface of the separator film 12 after the foundation 28 has been applied, while the outline of the cells 32 and the outline of both of the sub assemblies 18, 20 may comprise the nonporous foundation 28. The cells 32 may be fault tolerant, self healing structural cells 32 in that a puncture of one cell may not affect the rest of the cells 32 of the sheet 10. The grid created by the cells 32 and the foundation 28 and current bus 44 may enable a puncture tolerance and mechanical toughness to the plurality of cells 32. It is understood that the absolute dimensions of the cell 32, foundation 28 and current bus 44 and ratios of a grid defined by the foundation 28 or current bus 44 to the cell 32 can be varied throughout the dynamic range of the type of printing technology used and more practically, greater than 5 microns widths for the grid components and greater than 25 micron widths for the cell.

While triangular cells 32 are shown in the Figures, it should be understood that other shaped cells are also envisioned. For example, circular, rhombus, rectangular cells, square cells, or any other appropriately shaped cells may be utilized. The purpose of the cells 32 is to isolate damaged cells during processing, handling or otherwise and to provide additional strength to the sheet 10. Thus, if a single of the cells 32 becomes punctured, the undamaged portion of the sheet 10 may function normally. It should be further understood that the size of the sheet 10, and the cells 32 may vary according to the requirements of the specific application. In the embodiment depicted in the Figures, the two dimensional area of each cell may be about 31 mm.sup.2 Thus, the length of each “box” of four triangular cells 32 may be about 12.5 mm in one embodiment. It should be understood that the actual dimensions of each cell can vary and that typically the minimum dimension is 0.01 mm to 0.1 mm and typically the maximum dimension is 0.1 mm to 20 mm Finally, the repeat unit of the sheet 10 is at the dimensions of a single cell 32. As such, unique designs within the sheet 10 can be envisioned during the fabrication process such as presence and absence of cells 32 to match a application or the cutting out of patterns such as an article of clothing or perhaps a donut shape for rail gun or coil gun application.

Once the foundation 28 has been applied, the substrate 22 is ready for the application of the electrode layer 14. The electrode layer 14 may be made by a separate electrode preparation process, partially shown in FIGS. 3A-3C. To prepare the electrode solution, first a nano mix may be added to a gelable solution that would become a sol-gel. A nano mix may consist of any nanoscale materials or blends. For example, a polymers, metals, oxides of metals, ceramic or other type material may be used with the nano mix. The nano mix may be a blend of nano materials such as carbon nanotubes (CNT) and fat, long aligned CNT bundles that resemble yarn when viewed with a SEM microscope. If carbon is used as the nano material, the carbon density may be greater than 0.5-g/cc. For example, the carbon density may be between 0.5 and 2 g/cc. The nano material should preferably have high strength, low density, a high aspect ratio (length vs. diameter), and may be fusible with pulse radiation or other means. The gelable liquid that may be comprised of precursory materials for aerogel formation together with the nano mix may then be gelled and then dried into an aerogel in a similar manner to the way in which pure sol-gel is turned into an aerogel from a liquid solution. Once in sol-gel form, the gelled system may be further dried in the similar manners to which sol-gel is dried into aerogel. The drying may be an air dry process or a super critical fluid CO.sub.2 process that is known to those skilled in the art.

Once the drying is completed, a hardened porous material may result from the aerogel and nano mix blend. The porous properties of the hardened materials can be adjusted by varying the ratio of the constituents within the nano blend and the properties of the starting sol-gel. Pores ranging from macropores (greater than 50 nm) to micropores (under 2 nm) are thus feasible within the hardened materials. The hardened material at this stage may not be carbonized or fully conductive. While the nano-materials may be conductive, the hardened material may still include particles other than carbon most notably the aerogel component. The hardened porous material may then be pyrolyzed, for example, in order to produce a substance that is richer in carbon after the resulting volatile moieties of the aerogel are oxidized off during the pyrolysis process. The pyrolysis may result in a material that is shrunk from its original size and may involve a conditioning environment during or post-pyrolysis to induce unique properties to the nanomix or aerogel components.

Referring still to FIGS. 3A-3C, a representation of a pyrolyzed material 34 is shown. The pyrolyzed material 34 is shown having the nano mix 36 interspersed throughout. The pyrolyzed material 34 may further be a highly porous material. The pyrolyzed material 34 may then be ground into a powder, depicted by electrode particles 38. The grinding process may include a cryogenic ball milling process. However, other processes are contemplated such as room temperature milling. Each particle is designed to contain a mixture of macropores, mesopores and micropores in order to tune the mass transport properties and charge carrying capacity of the particles.

As shown in FIGS. 3A-3C, once the powdered electrode particles 38 are created, the electrode particles 38 may have a high porosity electrode core and a matrix of conductive nano materials that protrude from the high porosity electrode core. The electrode particles 38 may be a “hairy particle,” where this matrix of long nano mix components sticks out like hairs around the carbon blend of materials that predominantly makes up the particle. The “hairy” electrode particle 38 may be an energy storing electrode that is capable of interlocking with neighboring particles and provides suitable nano-scale tethering to the layers above and below the electrode 38 when applied to the sheet 10. The electrode particle 38 may thus be capable of interlocking with another layer in any direction to allow high density and constant power with increasing thickness of an electrode layer that comprises a plurality of the electrode particles 38. The electrode particle 38 may have optimal mass transport of electrolyte between the particles while also containing high surface area microstructures, for example of the aerogel, within.

Once the electrode particles 38 are created in powdered form, this powder may be turned into an ink by mixing the powder with a suitable rheological modifier such as hexane or another liquid organic material such as alcohol. The powder may be combined with the coupling agents, rheological agents with ultrasonic dispersion. The ink may be combined with or without a dispersing agent included, such as a surfactant. The resulting electrode ink may provide a linear relationship between the printed electrode's 14 thickness and energy and power density, and also contain the nano mix “hairs” which facilitate in the bonding and anchoring of the electrode to the porous separator. Furthermore, the energy storing electrode may be preloaded with electrolyte prior to printing, and either before or after becoming an ink.

The electrode ink may be applied to create the electrode layer 14. The electrode layer 14 may be applied to the substrate 22 over only the porous separator film cells 32. The ink may thus be sprayed using an indirect print. The electrode layer 14 may be applied over the separator film 12 in more than one layer. The hairy nano material of the electrode layer 14 is configured to nanoscale interlock between adjacent particles and with the particles of the separator film 12 in such a way to assure a high percentage of the protruding nano materials being intercalated within the previous separator film 12 pores. Temperature and pressure treatment may be utilized in order to form a highly entangled interfacial zone between the separator film 12 and the electrode layer 14. For example, after each layer of the electrode is applied, the electrode layer 14 may be flash cured with a pulsed radiation light source. While the process for applying the electrode layer 14 may be a wet process as described hereinabove, dry processes are also contemplated. For example, the electrode layer 14 may be electrostatically deposited onto a transfer drum then directly printed onto the separator film 12.

Referring now to FIGS. 4A-4C, a molecular view is shown of how the electrode layer 14 is interlocked with the separator film 12 and the current collector particles 16 (described hereinbelow). More particularly, the electrode particles 38 are shown mixed within a printed film and then fused with collector and separator particles 42. One embodiment assumes a plasticized separator particle (gel like surface) entrapping the nanomix hairs of the electrode particles. However, other embodiments that form nanoscale and large scale interlocking are possible. A schematic representation of nanoscale interlocking using 100-nm beads 33 overlaid on an invented hairy particle 38 are illustrated to scale in FIG. 5C In the illustration, 200-nm beads 35 are shown not to be able to interlock with the particles 38.

The current bus 44 may then be applied to the substrate 22 between the individual electrodes 14 and directly over the previously applied foundation 28 once the electrodes 14 have been applied. The current bus 44 may be print formed onto a non porous foundation layer that isolates porous separator and active cells 32 electrically and mechanically and prevents electrolyte transport, such as the non-porous foundation layer 28. The current bus 44 may be dimensioned for optimal thermal, mechanical and current carrying needs of an application. The ratio of the current bus to the cell 32 size and thus the porous separator 12 may be configured for optimal mechanical, thermal, and electrical properties. The current bus 44 may be part of a current collection ensemble 50 that comprises the current bus 44, the current collectors 16. Thus, the current bus 44 may be applied over the foundation 28 in the patterned area. The current bus 44 may be deposited in such a way that the nanomix materials of the electrode particles may become intercalated together with the current bus 44. The current bus 44 may be sintered and cured, depending on the temperature and pressure requirements of the application process. The degree of densification of the current bus 44 may be a carefully controlled process parameter. Upon final densification, the current bus 44 may serve as part of a pressure tight seal provided by the current collection ensemble 50. This seal may serve to prevent cross contamination between adjacent cells. The current bus 44 may be created with an ink, such as a Dupont silver, copper, nickel, aluminum or carbon ink. The current bus 44 may be conductive, and serve to transport currents to and from the input and output pins 18. Alternatives such as none conductive ribs that electrically isolate each cell and replace the current bus 44 or conductive materials doped polymeric materials are possible.

Referring to FIGS. 5A and 5B, the patterned current bus 44 may be interlocked with the non-porous foundation 28 with a ring seal. To accomplish the interlocking by print forming two approaches are described. Option 1, a gradient is dynamically formulated within two dissimilar inks labeled “M” and “P” respectively. A printed gradient is first formed within a detached vessel and is known to those familiar with continuous flow wet processing. In summary, “M” is added to the vessel that contains a high percentage of “P” while the vessel containing “P” is being extracted and printed onto the device by the printing apparatus. In so doing, “M” is enriching while “P” is being diluted over the print period. The depth of the gradient formed within the z-axis of the build is determined by relative flow rates of the “M” and “P” constituents. For shallow thin-film builds the fusing may be completed at the end of the mixed film illustrated as a “volume element” in FIGS. 5A-5B. More specifically, this may be accomplished with pulse radiation if the inks are composed principally of nanomaterials and polymeric dispersions. Yet another means (option 2) of formulating the gradient is to encapsulate the conductive nanomaterial, M with polymeric material, P that is compatible with the foundation 28 material. In this case a gradient is still formed with encapsulated M and a dispersion of P. Yet another option is to utilize the deposition properties of indirect print technologies such as by a spray application. Spray applicators can be designed to have a wide range of concentration gradients within the deposition cone of the nozzle. By tuning the overlapping and deposition properties of two separate nozzles 24 for solution M and P respectively, a gradient of M and P can be accomplished as a function of the deposition thickness and time. As with the former gradient, curing frequency is adjusted to assure complete cure of the films formed due to a complex transmissivity function as a function of thickness. The aspect ratio and thereby the properties of the legs, 45 developed are correlated to the cone geometrics, relative concentration of M and P, film forming properties of M and P, and the deposition rates of the two nozzles.

The current collection ensemble 50 may further include a cap layer 46. The cap layer 46 may be printed over the entirety of the substrate 14 with a wet or dry process. Shown in FIGS. 4A-4C is the cap layer 46 being applied over the electrode layer 14. The cap layer 46 may be formed by placing nano-material over the electrode such that once fused with pulse radiation or other suitable means, the mechanical properties of the outer 0.3 to 3 microns of the electrode material become a cap that is infused with conductive nano mix of the electrode. The cap layer 46 may work in conjunction with the current bus 44 and current collector 16 to form the pressure tight seal preventing cross contaminating between adjacent cells. The cap layer 46 may be overlaid in such a manner to assure good intercalation, particularly with the previous current bus 44 and electrode layer 14 with which the cap layer 46 may contact. The cap layer 46 may be composed of a dispersed solid consisting of micron sized pure metal particles or alloys with nano materials such as copper, gold, carbon, or silver. The purpose of the cap may be to enable thick-film build up while offering low processing temperature and to meet desired electrical and mechanical specifications after densification. The electrode particle 38 may further form a green state build after application of the electrode particles 38 and the cap layer 46 that, upon sintering and shrinkage of a containment chamber for the electrode particle 38, allows the release of entrapped gasses through the open porous structure of the chamber.

A third portion of the current collector ensemble 50 may be the plurality of current collector layers 16. The combination of the cap layer 46 and the electrically conducting continuous current collector layers may be configured to collect current, balance current between adjacent cells and transport it in a z-axis to an adjacent device. FIGS. 4A-4C depict a cross sectional view of a current collector and cap interlock to the electrode in accordance with one embodiment. The goal of the current collector layers 50 may be to build up metallic current collecting capacity and mechanically support the arrayed and sealed capacitive cells beneath. The current collector layers 50 may provide that the sheet is able to withstand over 0.5 psi, and preferably between four and ten psi, of internal pressure without breaking down or harming the energy storage capabilities. The current collector ensemble 50 may collectively prevent the electrolyte from escaping out of the sheet 10 during activation. The current collector ensemble 50 may also be a moisture and environmental barrier. As such, the current collector ensemble 50 may be the final layers applied to the sheet 10 prior to assembling the fully printed device.

A third portion of the current collector module 50 may be one or more current collector layers 16. The current collector module 50 may be an electrically conducting current carrying layer 16 that is print formed over a sub assembly that comprises the separator 12, the foundation, 28, the electrode 14 and the bus 44. The material of the electrically conducting current collector may assure an interlocking between the electrically conducting current collector 16 and the electrode 14. The combination of the cap layer 46 and the electrically conducting continuous current collector layers may be configured to collect current and transport it in a z-axis to an adjacent device. The goal of the current collector layers 16 may be to build up metallic current collecting capacity and mechanically support the arrayed and sealed capacitive cells beneath. The current collector layers 16 may provide that the sheet is able to withstand over three psi, and preferrably between four and ten psi, of internal pressure without breaking down or harming the energy storage capabilities. The current collector layer 16 may be fused by pulse radiation over the cap 46. The current collector layers 16 may collectively prevent the electrolyte from being pumped out of the sheet 10 during activation. The current collector layers 16 may also be a moisture and environmental barrier. The current collector layers 16 may be the final layers applied to the sheet 10 prior to assembling the fully printed device. The current collector layers 16 and the cap 46 may be predominantly z-axis conductors. This z-axis conduction may be further provided by a high strength conductive carbon veil that is configured to enhance the mechanical properties and increase strength.

Further contemplated is an external current bus (not shown) that is coupled to the outside of the two identical sub assemblies 18, 20. The external current bus may have a geometry that is parallel to the internal current bus 44, and the foundation layer 28. The external current bus may further be in operable communication with the pinout 17.

Assembling the batched processed sheet 10 from the printed substrate 22 may comprise several steps. First, a printed sub assembly may be dismounted from the substrate 22. This dismounting may be accomplished by a cold finger, roller or refrigeration. For example, cooling may shear the physical bonds between the separator and foundation film 12, 28 and the substrate 22 so that the sub-assembly or the pre-assembled sheet 10 may be carefully removed from the substrate 22. The second sub assembly may be dismounted from the same substrate 22 or a different substrate (not shown) in a similar manner. The sub assemblies may be dismounted and stored in suitable packaging material for further processing.

Once the batched processed pre-assembly sheet 10 or sub assembly is separated from the substrate 22, the sheet 10 or sub assembly may be flipped 180.degree. such that the collector layers 50 are facing the substrate 22 while the separator layer 12 is faced upwards. The reversed pre-assembly for sheet 10 or sub assembly may then be inserted into a vacuum oven or other environmentally controlled chamber for a predetermined amount of time. This temperature and time may help to drive off residual solvents from the carbon electrode materials and activate the electrode within the sheet 10. Once removed from the oven or other environmentally controlled chamber and cooled to room temperature, a room temperature ionic liquid (RTIL) electrolyte may be applied to the sheet 10. The RTIL may be applied directly to the triangular cell area 32. The RTIL may be allowed to soak for a predetermined time period, for example for thirty minutes to fill in any of the unfilled pores of the separator film 12 and electrode layer 14. Once the soaking or wetting has been completed, excess RTIL may be removed with, for example, an absorbent roller. Common RTIL electrolytes may be utilized assuming compatibility with the various materials used in the sheet 10. As such, phosphorous hexafluoride, PF.sub.6 anion's are preferred over boron tetrafluoride, BF.sub.4 anions for CTA based devices. In addition, the cation selection is critical for similar reasons. For CTA, a proprietary cation is preferred in combination with the PF.sub.6 anion. In the case of CTA, aqueous systems are not compatible. Furthermore, the electrolyte may be a solid electrolyte with different application processes that may be known to those skilled in the art.

Once the pre-assembled sheet 10 has been loaded with electrolyte on the substrate 22, the sheet 10 may treated with a seaming agent by print forming and then folded along a line of perforation or crease to enable alignment between the two sub-assemblies. A seam 58 may be formed between the two sub assemblies by applying a plasticizing agent along the seam to attack the CTA of the separator layer 12 that is exposed due to the 180.degree. rotation described hereinabove. To properly fold the sheet 10, the cells 32 and current bus grid may be properly aligned or matched up. It should be understood that while the embodiment described herein requires the folding step, other embodiments are contemplated. For example, the sheet 10 may be printed on both sides of the separator film 12, rather than requiring a folding step. It is further contemplated that each of the steps of creating the sheet 10, described hereinabove, may be done in a computerized printing process whereby lengths of the sheet 10 may be created. It is contemplated that precise roll-to-roll, (R2R) printing processes may be utilized to print lengths of the device at 1 m/s or more.

After the folding step, a sealing device (not shown) may be used to seal the grid portion and the surrounding portion of the sheet 10. The sealing device may include protrusions in the shape of the current bus grid and the surrounding portion that is around the current bus grid. This is because the triangular cells 32 of the sheet may actually protrude from the current bus grid shape channels prior to folding. Thus, folding the above sub assembly and the below sub assembly together may result in an unwanted spacing between the current bus grid of the above sub assembly and the current bus grid of the below sub assembly. The sealing device may be used to seal the current bus grid of the above sub assembly with the current bus grid of the below sub assembly, along with sealing the area around the outside of the grid of the sheet 10. Said sealing device may be an embossed roll in an R2R line that may also be heated.

As previously stated, the sheet 10 may be stackable in several layers, as shown in FIGS. 6C and 6D. A single sheet 10 device, as shown in FIGS. 6A and 6B, may be extremely thin, therefore allowing several of the devices to be stacked together, as shown in FIGS. 6C and 6D, and connected in either series or parallel, thus providing more energy storage per unit length of the sheet 10. For example, an odd numbered plurality of the sheets 10 may be integrated together in series with a seaming agent. Alternately, an even numbered plurality of sheets 10 may be integrated together in parallel with a seaming agent. A filled vias may be print formed into the patterned current bus to integrate the plurality of high strengths, high energy density structural sheets and enable parallel arrangements between devices.

Further, the sheet 10 may be made to accommodate any shape or size. While the embodiment depicted in the Figures is roughly square or rectangular in shape, other embodiments are contemplated such as circular shapes, rectangular, triangular, ovular, or any other shape that would be useful in an application of the sheet 10.

Referring now to FIG. 7, a method 100 is shown for creating a structural sheet such as the sheet 10. The method 100 may include a step 110 of applying a separator module, such as the separator layer 12 and the foundation 28 to a substrate such as the substrate 22. The method 100 may include a step 112 of applying an electrode, such as the electrode 14. The method 100 may further include a step 114 of applying a current bus, such as the current bus 44. The method 100 may still further include a step 116 of applying a cap layer, such as the cap 46. Further, the method 100 may include a step 118 of loading electrolytes into the opposite surface behind the separator module. Further, the method 100 may comprise a step 120 of assembling a sheet such as the sheet 10. Finally, the method 100 may include a step 122 layering several sheets together. It should be understood that the steps outlined hereinabove to the method 100 may be done in other orders or including other steps there between that will be apparent to those skilled in the art and further described herein. It should be understood that the method 100 is presented in this order by way of exemplification.

The sheet 10 may be useful in a variety of different applications. The thin nature of the device along, with its pliability and flexibility, are advantages that may allow the sheet 10 to provide energy in many scenarios. For example, the sheet 10 may be used as an energy storage elongated “tape,” that is segmented for easy disassembly or assembly in series or parallel configurations based on user choice. The sheet 10 may be used to store energy for solar photovoltaic devices, in both grid-integrated and off grid applications. It is further contemplated that the sheet 10 be embeddable in automobile frames or within advanced soldier uniforms. Still further, the sheet 10 may be used for digital camera flashes, or for cordless surgical or dental tools. Also contemplated are applications for the sheet 10 as structurally conformable or integrated into structures of weapons such as guided missiles s, aeroplanes such as unmanned aerial vehicles (UAVs) or underwater vehicles, as, decoupling capacitors underlaid on printed circuit boards, industrial or production power tools, model airplanes, cars or helicopters, high stakes packaging, military battery or supercapacitor packs and generators, night vision goggles, portable defibrillators, embedded in building materials such as roads, concrete walls floors, insulation, barrier sheet materials or the like, hand held power tools, transmission lines wrapped in the device to integrate storage directly into the grid, fabric integrated batteries, embedding battery or supercapacitor in electric fencing, flexible displays (newspapers or the like), medical diagnostic watches or monitors worn by patients, eco-sensors, regenerative braking for hybrid vehicles, regenerative energy capture in elevators, forklifts, motors in other devices, within laptops, as batteries embedded under the skin with medical devices, cordless phones, toys, thin film battery or supercapacitor hybridization (RFID tags), bluetooth headsets, cell phones, marine sealed batteries, handheld video game consoles, tasers, high end flashlights, cordless lawnmowers or string trimmers, electric toothbrushes, shoes, wireless devices such as microphones, vacuums, remote sensors, elevators and docks, or the like. It should be understood that some devices require larger batteries than desirable due to the power density requirements of the device during energy consumption spikes (for example with flashes, or high energy activities on a device that does not always require high energy). In this case, the sheet 10 may be implemented as a high power density supplement within a casing, for example, to supplement the standard battery or supercapacitor for these high power density applications. This may allow for the standard battery or supercapacitor of the device to be decreased in size significantly.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer-readable media can include but are not limited to magnetic storage devices (e.g., hard disk, floppy disk, magnetic strips, etc.), optical disks (e.g., compact disk (CD), digital versatile disk (DVD), etc.), smart cards, and flash memory devices (e.g., EPROM, card, stick, key drive, etc.). Additionally, various storage media described herein can represent one or more devices and/or other machine-readable media for storing information. The term “machine-readable medium” can include, without being limited to, wireless channels and various other media capable of storing, containing, and/or carrying instruction(s) and/or data. Additionally, a computer program product may include a computer readable medium having one or more instructions or codes operable to cause a computer to perform the functions described herein.

Further, the steps and/or actions of a method or algorithm described in connection with the aspects disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to the processor, such that the processor can read information from, and write information to, the storage medium. In the alternative, the storage medium may be integral to the processor. Further, in some aspects, the processor and the storage medium may reside in an ASIC. Additionally, the ASIC may reside in a user terminal. In the alternative, the processor and the storage medium may reside as discrete components in a user terminal. Additionally, in some aspects, the steps and/or actions of a method or algorithm may reside as one or any combination or set of codes and/or instructions on a machine readable medium and/or computer readable medium, which may be incorporated into a computer program product.

While the foregoing disclosure discusses illustrative aspects and/or aspects, it should be noted that various changes and modifications could be made herein without departing from the scope of the described aspects and/or aspects as defined by the appended claims. Accordingly, the described aspects are intended to embrace all such alterations, modifications and variations that fall within scope of the appended claims. Furthermore, although elements of the described aspects and/or aspects may be described or claimed in the singular, the plural is contemplated unless limitation to the singular is explicitly stated. Additionally, all or a portion of any aspect and/or aspect may be utilized with all or a portion of any other aspect and/or aspect, unless stated otherwise.

To the extent that the term “includes” is used in either the detailed description or the claims, such term is intended to be inclusive in a manner similar to the term “comprising” as “comprising” is interpreted when employed as a transitional word in a claim. Furthermore, the term “or” as used in either the detailed description or the claims is intended to mean an inclusive “or” rather than an exclusive “or”. That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

### BRIEF DESCRIPTION OF THE DRAWINGS

FIG. 1 is a flow diagram describing an embodiment of the method to manufacture the current collector side of a flexible printed circuit board.

FIG. 2 is a flow diagram describing an embodiment of the method to manufacture the separator side of a flexible printed circuit board.

FIG. 3 is a flow diagram describing an embodiment of the method to align and join the current collector side and separator side of a half-build of a flexible printed circuit board.

FIG. 4 is a flow diagram describing an embodiment of the method to join two single-layer half-builds of a flexible printed circuit board.

FIG. 5 is a graphical representation and flow diagram of a simplified processing line utilizing an embodiment of the method to manufacture a flexible printed circuit board with energy storing capabilities.

FIG. 6 is a detailed exploded view of a subset of the method of manufacture represented FIG. 7A is a graphical representation of a processing line utilizing an embodiment of the method to manufacture a flexible printed circuit board with energy storing capabilities.

FIG. 7B is a graphical representation of a processing line utilizing an another embodiment of the method to manufacture a flexible printed circuit board with energy storing capabilities.

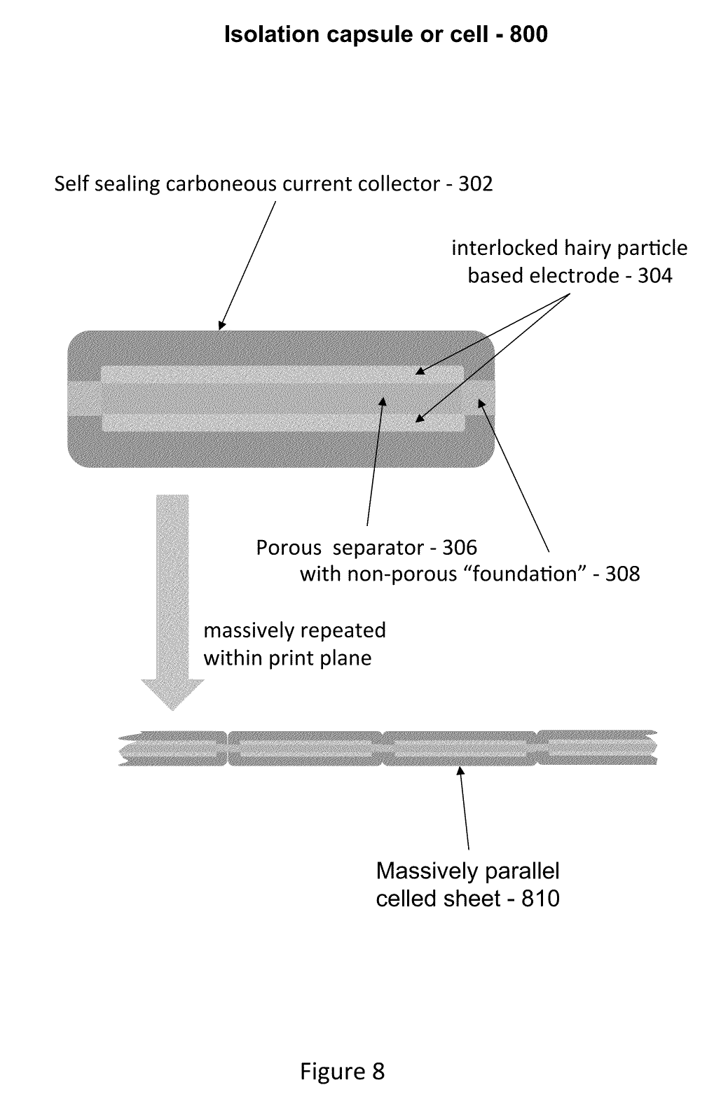

FIG. 8 is a cut-away view of an embodiment of a forward sequence build collector design.

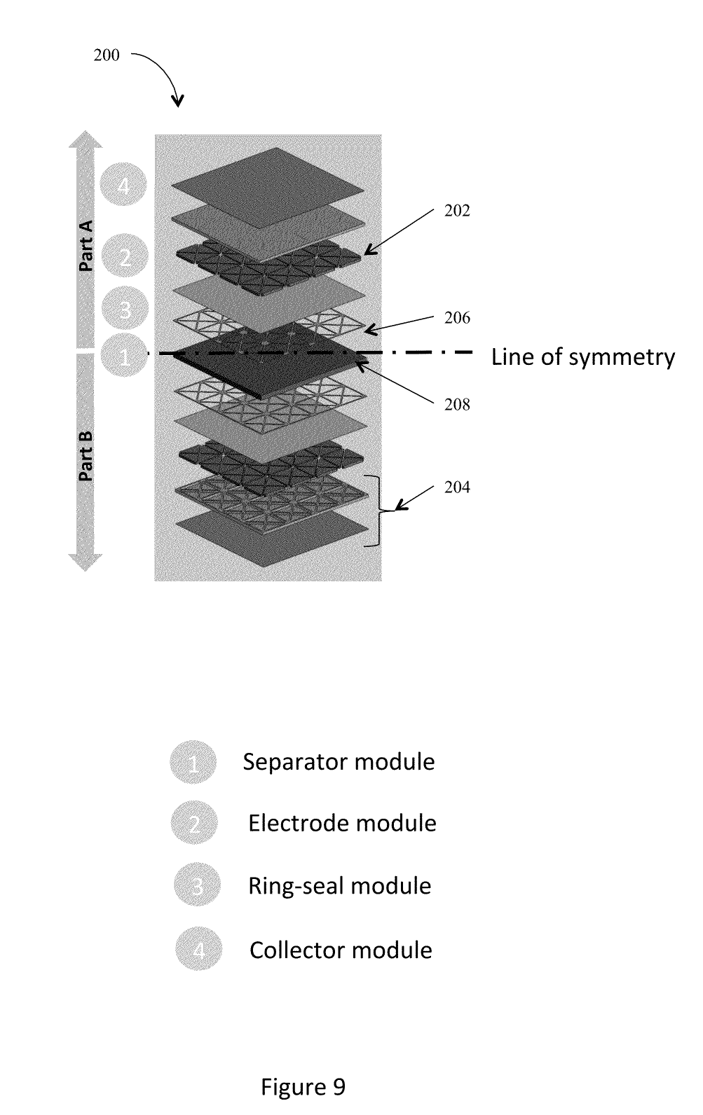

FIG. 9A is a cut-away view of an embodiment of Roll A of a forward sequence half-build collector design.

FIG. 9B is a cut-away view of an embodiment of a reverse sequence half-build collector design.

### BRIEF DESCRIPTION OF THE DRAWINGS

FIG. 1A is a side view of one embodiment of the invention.

FIG. 1B is a side view of a partially assembled portion of one embodiment of the invention.

FIG. 2 is a side view of the detail of one embodiment of the invention.

FIG. 3A is a cut-away view of one embodiment of the invention.

FIG. 3B is a side view of one embodiment of the invention.

FIG. 4A is a perspective view of a finished assembly of one embodiment of the invention.

FIG. 4B is a perspective view of a finished assembly of one embodiment of the invention.

FIG. 5A is a cut-away view of an example of an application of one embodiment of the invention.

FIG. 5B is a cut-away view of one embodiment of the invention including electronic components.

### DETAILED DESCRIPTION

### ETape Roll

In an aspect, an electronic tape (Etape™) is described herein. Etape™ is a flexible energy storing tape roll with or without an adhesive backing that can be formatted like any other tape product of similar nature. It can in fact be substituted for masking tape, duct tape or ribbon-like material. The difference is that it can be charged and discharged when properly interfaced to a power supply or load respectively. High voltages can be formatted by z-folding back onto a common surface to form a brick-like or prismatic device or by shingling multi-layered strips into an alternate pattern such that the underside to topside are interconnected to form large areas of power at high voltage in a fashion similar to roofing materials. In addition, the Etape can be cut to form or folded or adhered to many surface types. To make electrical contact, the tape can be inductively or direct connected to loads or power.

In an aspect, FIG. 1 an apparatus ETape role 100 for supplying power comprises massively arrayed flexible electronic cells (##) print formed into flexible electronic devices or energy segments (104) comprising an electrode 202 and a current collector 204, a separator 208, partitions that isolate each cell 206, and an interface (i.e. pin-outs) for attaching to at least one external electronic component. In an aspect, the current collector 204, partitions 206 and electrode 202 are preformed onto the first substrate and the separator 208 and foundation components 20# are preformed onto the second substrate.

In aspect, FIG. 1 shows the Etape comprises a protective seal or tape packaging 122 surrounding a portion of the flexible device, a conductive strip, a perforated cut 106 between each of the energy storing segment 104, an interconnected strip 108, a vinyl embedded device and an internal support rib or current bus. The energy storing segment 104 comprises the power tape technology, a containment chamber 126, and a current bus 120. The energy storing segments 104 may be connected in serial or in parallel and separated by a perforated cut 106. The Etape may or may not have adhesive backing.

The Etape allows for a dynamic patterning for receiving one or more components. This may be performed at a print shop thereby offering customizable fit to form. The patterns may include holes, slots and filled vias.

The energy source comprises a battery, supercapacitor, solar cells or any other source of power. Also, the energy source comprises a power plane and a ground plane.

E-Tape™ design characteristics: A versatile energy storing tape or ribbon that is dispersed as discrete segments from a roll containing the same. The design of the tape or ribbon is in a manner that enables the rapid prototyping of power supply requirements for virtually any application requiring power. The novel properties include its flexible format with a bending radius of 1-cm or less, robust mechanical properties that enable multiple flex or formable power, stackable in series for increased voltage or parallel for increased capacitance. The design includes a means of interfacing electronic components by means of standard pin-out and soldering.

Flexible PCB: at least one segment is dispensed from a roll and the pin-outs of the design are used to attach various electronic components to the flexible “printed circuit board.”

In this application, at least one segment is dispensed from a roll and the pin-outs of the design are used to attach various electronic components to the flexible “printed circuit board.”

### Electrode

In order to assure a compact structure and thereby minimize materials such as electrolyte while assuring maximum strength, and high energy and power densities within the porous materials, a highly compact electrode structure is desired. To do so, the printed particle's design, the quality of the ink dispersion, and the print and cure or set processes will determine the overall compaction and performance of the electrode film or sub-assembly. The print processes and the inks for said processes are in the field of high density electrode design and fabrication. Thus a ink formulation is used to make the electrode.

In an aspect, the electrode is formed by printing a film using indirect or direct printing methods. In indirect printing, the inks are typically of low viscosity and rely on solvent evaporation to drive the setting and compaction of the final film. For direct printing, the inks are typically highly viscose materials and slow drying. An alternative approach using what is termed 100% solid inks is comprised of active monomers that cure to remove reactive components while preserving the functional needs of the electrode is conceivable. Additionally, a preferred means of forming an electrode element is to pre-form the film on an intermediate drum or plate for processing and densification before transferring the film to the substrate or receiving layer or separator or current collector of a device. The electrode formation further comprises a means to transfer the free-form film to the build or substrate of device such as to cause transfer by pulsed irradiation through a translucent or transparent drum or plate serving as a transfer agent. Such processing is rapid, solvent free and easy adapted to controlled environments.

### Current Collector

Described herein is an aspect of a method of forming a highly flexible low density low cost current collector (LD3C) is by the printing of a doped film forming ink. To obtained the desired rheology and conduction properties within the final film, the inks are comprised of conductive fibrous and conductive platelets dispersed within a polymer forming matrix. Next, said inks are matched to the print forming process in order to avoid or minimize the film forming nature of the polymer forming materials. To do so, said film forming materials within the inks must be at a level that avoids a continuous non-conductive film formation over the conductive particles that must overlap or fuse to adjacent particles of similar nature. The ink formulation and matching of such formulations to a deposition processes in order to avoid filming over of the conductive constituents in order to preserve the conductive properties within cured or set films is

Described herein is a method of print forming isolated zones within an energy storage apparatus. The method comprises of using plasticized separator material and compatible current collector. A key requirement for achieving the desired mechanical properties and isolation of cells is the proper formation of a suitable non-porous foundation within the separator film component or sub-assembly and an equally non-porous bus that is intimately associated with the said foundation forming materials of the separator. The formulation of inks is used for initializing plasticization within the printed films in order to form a continuous seal between adjacent energy cells.

In an aspect, a current collector is fabricated using the following method. The method comprises of using an ink comprising conductive fibrous and conductive platelets, using a pulsed irradiation source, using a pulse transfer scheme, print forming the ink, and curing the ink using pulsed ultraviolet curing.

Referring now to FIG. 1, a method 100 of manufacturing a flexible printed circuit board with energy storing capabilities comprises the steps of printing a highly conductive, adhesion diffusion barrier on a smooth surface with a high expansion coefficient 102 using print formed generating inks. The highly conductive, adhesion diffusion barrier may, in one embodiment be made by dispersing nanoparticles of a high dielectric material within an RTIL and suitable binder materials. The layer is made by print forming a porous separator material that is porous to the RTIL electrolyte to a degree not more than 30% and preferably between 15-25%.

In one embodiment, the nanoparticles may be a titinate of TiO2 or BaTi2O3. In one embodiment a thermoplastic binder with a processing temperature between 100 C and 400 C may be used.

The substrate and deposition may then be cured or dried 104, as appropriate, depending on the materials used. The electrode is then print formed 106 and the assembly is dried at high temperature to drive the water off 108. The foundation layer including the ring seal pattern is then print formed 110. The assembly may then be partially cured with air drying, UV or chemical curing methods 112.

The separator and electrode may be interlocked through the establishment of one or more concentration gradients by a print forming technique. This interlocking creates a structurally tough electrode layer by utilizing the characteristics of spliced or fused super aggregates.

Referring now to FIG. 2, a method of manufacturing a second, subsequent or complementary layer 200 of a flexible printed circuit board with energy storage capabilities may be completed in a similar manner to the method 100 outlined above. Different desired characteristics can be attained through using different base and additive chemicals or materials.

In one embodiment, a reusable solid substrate 202 may act as a base. A release layer, such as PTFE, may be optionally incorporated. A porous separator coating 204 may be print formed over the substrate. A non-porous foundation 206 for ring seal patterning may be print formed to convert regions of porous substrate. The substrate may be then be dried or cured 208, as necessary. An adhesive bonding foundation may then be print formed 210 for the patterned ring seal. The assembly may then be partially cured with air drying, UV or chemical curing methods 212.

Referring now to FIG. 3, the partially cured plates 100, 200 may then be aligned and joined according to the foundation pattern 302. The assembly may then be cured with air drying, UV or chemical curing methods 304 and the ring seals formed 306. The substrate may then be removed 308 from the plate 200 resulting in a half-build device 310.

This same process may be repeated to manufacture additional half-build devices 312 for combining with the original device 310 or assembly (not shown).

Referring now to FIG. 4, a half-build device 310 and complementary half-build device 312, can be joined together and loaded with electrolytes 402. The assembly can then be sealed through seam formation at the rim and Ring Seal locations 404 resulting in a sealed, single-layer device 406.

Referring now to FIG. 5, which depicts a simplified representation of the flexible circuit board processing line 500. The processing line 500, commences with a material source roll 502 of a web or support substrate 504. In one embodiment of the invention, the web is a 5 micron PE web 504.

A conductive photo sensitive release material 506 is applied to the web 502. A metal composite 508 is deposited over the conductive release material 506 as the material progresses down the line 500. A barrier material 510 is infused over the circuit assembly and the circuit assembly is then air dried or cured, as necessary. In one embodiment of the invention, the curing is accomplished by a pulsed irradiation fusing drum. The result of this process line manufacture is designated Roll A, 514.

A subsequent pass through the line 500 can create a complementary Roll B, 516.

Roll A 514 and Roll B 156 may be joined 518 and processed further through the process of electrode deposition and fusing 520 and then separator deposition and curing or setting 522, as necessary. The combination of Roll A and Roll B 518 is processed further by infusing the ring seal pattern 524 and a final round of curing or air drying 526, as necessary. The resulting device is a half-build roll 528.

Referring now to FIG. 6, the step of Ring Seal Infusion 524 is shown in the gas polymerization phase. The Ring Seal 602 pattern allows the gas 604 to infuse through the substrate 606 to the electrode layer 608.

Following the curing or drying step 526, the polymerized gas material 610 is mechanically and electrically connected to the electrode layer 608.

Referring now to FIG. 7A, the process line 700 for the manufacturing includes the build 702 which passes under a patterned drum 708. The patterned drum 708 print forms the correct electrode or separator pattern on the build 702. A cleaning station 704 clears the excess print material from the patterned drum 708 after printing on the build 702. A charging roller 706 keeps the electrical charge of the patterned drum 708 at the appropriate level. The patterned drum 708 may, in one embodiment, include a pulsed irradiation source 710. A transfer drum 712 transfers the print material from the development station 714. A pulsed curing station 716 follows the print step.

The build 702 may be shuttled in a single direction or, for the development of thicker films and builds, may be bi-directional. The movement of the build 702 may be controlled with rollers, tracks, trays or some other means and is represented by element 718, generally.

Referring now to FIG. 7B, in one embodiment of the process line 730, the build 732 may be uni-directional; however, the print module 734 and the curing module 736 may be repeated serially on the process line 730. This multi-station approach will also allow for development of thick films or builds.

Referring now to FIG. 8, an embodiment of a the flexible printed circuit board 800 is displayed. The electrode and half-separator 802 supports the cap layer 804. The cap layer 804 provides interlocking means for adjacent layers or electronic components (not pictured) and can increase the z-axis profile of the build for different applications. The conductor layer 806 is built up on the z-axis, as well and provides further interlocking means for either adjacent layers or electronic components (not pictured). The final seal layer 808 is also interlocked and serves to increase the self-sealing properties of the flexible printed circuit board.

Referring now to FIG. 9A, in one forward sequenced, half-build embodiment of the invention, Roll A 900 is comprised of multiple layers. The support web or temporary sealing layer 902 may be in the 3-10 micron thickness range. The conductive release layer 904, which may be 0.1 to 3 microns thick, is print formed next and serves to release the build from the web 902 further in the process. The conductive release layer 904 separates the aluminum planar layer 906, which may be 0.1 to 3 microns thick, from the electrode fusion layer 908, also 0.1 to 3 microns thick. The aluminum planar layer 906 serves as an interlock between adjacent layers and provides some lateral toughness to the build. The electrode fusion layer 908 serves both as an interlock for the aluminum planar layer 906 and as a seal for the build.

Referring now to FIG. 9B, in one reverse sequenced, half-build embodiment 920 of the invention, the 50 micron half-build 922 serves as the support. The electrode fusion layer 924, which may be 0.1 to 3 microns thick, is print formed on top of the half-build 922. The electrode fusion layer 924 serves as a build seal and as an interlock between the half-build 922 and the aluminum planar layer 926. The aluminum planar layer 926 may be 0.1 to 3 microns thick and serves to strengthen the lateral toughness of the build and interlocks the adjacent layers. The last layer to be print formed on the build is the conductive photo sensitive fusing and sealing layer 928. The conductive photo sensitive fusing and sealing layer 928, which may be 0.1 to 3 microns thick, interlocks with the aluminum planar layer 926 and seals the build.

Referring now to FIG. 1A, a multi-layer substrate 100 consisting of, for example, of a conductive interfacial layer 102, deposited in a desired pattern and a non-conductive layer 104, separating the conductive interfacial layers 102. The conductive interfacial layer 102 provides for growth or build of the z-axis of the multi-layer substrate 100 as well as allowing for the interlocking of the layers of the multi-layer substrate 100.

A release layer 106 may be utilized to release the multi-layer substrate 100 from a manufacturing substrate (not shown). An attachment layer 108, also strengthens the interlocking of the layers and may increase the adhesion between the electrode (not shown) and multi-layer substrate 100.

The edges of the multi-layer substrate 100 may also be sealed with a sealant 110 which strengthens and electrically seals the multi-layer substrate 100.

Referring now to FIG. 1B, a side view of one embodiment of the invention is shown. The cap layer 114 is disposed upon the electrode and separation or half-separation layer 112. The conductor layer 116 is sandwiched between the cap layer 114 and the final seal layer 118. Each of these layers, the cap layer 114, the conductor layer 116 and the final seal layer 118 all may be print formed during manufacturing in one embodiment of the invention.

Referring now to FIG. 2 which depicts both the current collector plate 200 and the separator plate 220. The current collector plate 200 is assembled from the base substrate 202. In one embodiment of the invention, a pre-formed metal foil 204, may be used as a collector. A conductive adhesive diffusion layer 206 is printed upon the metal foil 204. The assembly may be dried or heated to cure.

Following the curing, the electrode pattern is printed and then dried at a high temperature to dry or evaporate off the water. The foundation with the ring seal pattern 208 is then printed on the assembly. The electrodes 210 will be separated by and/or surround the foundation ring seal pattern 208. The entire assembly may then be partially or totally cured, depending on the particular embodiment of the invention.

The separator plate 220 is initiated with a solid substrate 222. The solid substrate 222 may be coated with a release layer 224, for example PTFE. A porous separator layer 226 is then print formed on top of the release layer 224. The unprinted areas will become non-porous separators 228. The assembly may then be cured or dried, as necessary.

The two plates, current collector plate 200 and separator plate 220, may then be aligned and joined according to their foundation patterns. The new joined assembly (not pictured) can then be cured to form the ring seal. The solid substrate 222 may then be removed resulting in a half-build device.

Referring now to FIG. 3, a cut-away view of a multi-layer flexible substrate 300 capable of storing energy is depicted. The current collector 302, surrounds the super aggregator electrodes 304 which, in turn sandwiches the porous separator layer 306 and the non-porous foundation 308.

An example of a structural sheet 310 of an array of multi-layer flexible substrates 300 capable of storing energy is also shown. The characteristics of this manufacture allows for puncture-tolerant or fault-tolerant behavior that approaches a self-sealing or self-healing state due to the parallelism of the array. Damaged cells are merely bypassed and the remaining array continues to function.

Referring now to FIG. 4A which shows a multi-layer flexible substrate 400 with substrate 402 and array 404. In one embodiment, array 404 may include electrically isolated zones. Electronic components or control devices 406 may be embedded or electrically connected to the array 404.

Referring now to FIG. 4B, the electrically isolated zones of array 404 may include zones with differing electrical properties. These zones 410 may have different RC characteristics than the rest of the array 404. The zones 408 may also include a particular voltage within the zone.

Referring now to FIG. 5A, device assembly 500 is an example of one embodiment of the invention being utilized in a consumer electronic device. The device encasement 502 may be made of any rigid or semi-rigid material including, but not limited to plastics, woods or metals. The one or more embedded flexible power circuits 504 can conform itself to the interior of the device encasement 502. In one embodiment, a traditional printed circuit board 506 may be within the device assembly 500. One or more components 508 may be inserted into or connected to the printed circuit board 506. One side of the printed circuit board 506 may be designed as a power plane 510 and the other side may be designed as a ground plane 512. An internal battery 514 or supercapacitor may be connected, or integral, to the printed circuit board 506.

The one or more flexible power circuits 504 may be tapped into singly for the circuit voltage, or in tandem for twice, or the sum of, the circuit voltage.

Referring now to FIG. 5B, the stacked assembly 540 of the one or more flexible printed circuit boards 504 further illustrates the availability of increased power through multiple “stacked” boards. Here, two of the flexible printed circuit boards 504 are on opposite sides of substrate or support board 542. The substrate 542 may be a series of supporting ribs or may be a traditional circuit board material. Electronic components 544 are depicted as mounted on or through the support board 542 and passing through the flexible printed circuit board 504. The total power 546 available in this configuration is the sum of the voltages of each of the single flexible printed circuit boards 504.

A versatile energy storing tape that is dispersed as discrete segments from a roll containing the same. The design of the tape is in a manner that enables the rapid prototyping of power supply requirements for virtually any application requiring power. In one embodiment, properties include its flexible format with a bending radius of 1-cm of less, robust mechanical properties that enable multiple flex or formable power, and series stackable for higher voltages. The design includes a means of interfacing electronic components by means of standard pin-out and soldering.

As shown in FIGS. 1A-1C, energy storage sheet 10 may be composed of two halves or parts with at least a separator layer 12 in between. Each of the two halves or parts may include an electrode layer 14 and a current collector layer 16. Each electrode layer 14 may be in intimate contact with, and/or entangled with, separator layer 12. The material of each electrode layer 14 may be pinned between the grain boundary of current collector 16 and separator 12. Electrode layer 14 may be made by a separate electrode preparation process, partially shown in FIGS. 3A-3C and depicted in FIG. AA.

As shown in FIG. AA, to prepare the electrode solution, a nano-mix may be added to a gelable solution that would become a sol-gel. At step AA10, a nano-mix may consist of any nanoscale materials or blends. For example, polymers, metals, oxides of metals, ceramic or other type material may be used with the nano-mix. The nano-mix may be a blend of nano-materials such as nanowires, carbon nanotubes (CNT), including multi-walled nanotubes (MWNT), and fat, long-aligned CNT bundles that can resemble yarn when viewed with a scanning electron microscope (SEM). If carbon (e.g. graphite or perhaps, graphene, etc.) is used as the nano-material, the carbon density may be greater than 0.5-g/cc. For example, the carbon density may be between 0.5 and 2 g/cc. The nano material should preferably have high strength, low density, a high aspect ratio (length vs. diameter), and may be fusible with pulse radiation or other means. At step AA20, the gelable liquid that may be comprised of precursory materials for aerogel formation together with the nano mix may then be gelled and then dried into an aerogel in a similar manner to the way in which pure sol-gel is turned into an aerogel from a liquid solution. At step AA30, once in sol-gel form, the gelled system may be further dried in the similar manners to which sol-gel is dried into aerogel. The drying may be an air dry process or a super critical fluid CO₂ process that is known to those skilled in the art.

Once the drying is completed, a hardened porous material may result from the aerogel and nano mix blend. The porous properties of the hardened materials can be adjusted by varying the ratio of the constituents within the nano-blend and the properties of the starting sol-gel. Various pores are feasible within the hardened materials, such as pores ranging from macropores (greater than 50 nm), to mesopores (50 nm down to 2 nm), to micropores (under 2 nm). The hardened material at this stage may not be carbonized or fully conductive. While the nano-materials may be conductive, the hardened material may still include particles other than carbon most notably the aerogel component. At step AA40, the hardened porous material may then be pyrolyzed, for example, in order to produce a substance that is richer in carbon after the resulting volatile moieties of the aerogel are oxidized off during the pyrolysis process. The pyrolysis may result in a material that is shrunk from its original size and may involve a conditioning environment during or post-pyrolysis to induce unique properties to the nano-mix or aerogel components. Referring to FIGS. 3A-3C, a representation of a pyrolyzed material 34 is shown. The pyrolyzed material 34 is shown having the nano mix 36 interspersed throughout. The pyrolyzed material 34 may further be a highly porous material.

At step AA50, the pyrolyzed material 34 may then be turned into a powder, depicted by electrode particles 38, for example by grinding or milling the material. The grinding process may include a cryogenic ball milling process. However, other processes are contemplated such as room temperature milling. Each particle is designed to contain a mixture of macropores, mesopores and/or micropores in order to tune the mass transport properties and charge carrying capacity of the particles. As shown in FIGS. 3A-3C, once the powdered electrode particles 38 are created, the electrode particles 38 may have a high porosity electrode core and a matrix of conductive nano materials that protrude from the high porosity electrode core. The electrode particles 38 may be called “hairy particle,” where this matrix of long nano mix components sticks out like hairs around the carbon blend of materials that predominantly makes up the particle. The “hairy” electrode particle 38 may be an energy storing electrode that is capable of interlocking with neighboring particles and provides suitable nano-scale tethering to the layers above and below the electrode 38 when applied to the sheet 10. The electrode particle 38 may thus be capable of interlocking with another layer in any direction to allow high density and constant power with increasing thickness of an electrode layer that comprises a plurality of the electrode particles 38. The electrode particle 38 may have optimal mass transport of electrolyte between the particles while also containing high surface area microstructures, for example of the aerogel, within.

At step AA60, once the electrode particles 38 are created in powdered form, this powder may be turned into an ink by mixing the powder with a suitable rheological modifier such as hexane, DMSO, mineral spirits, alcohols or another liquid organic material or blend of materials. The powder may be combined with the coupling agents, rheological agents and dispersed with ultrasonic dispersion technique. The ink may be combined with or without a dispersing agent included, such as a surfactant or matching solubility parameters. The resulting electrode ink may provide a linear relationship between the printed electrode thickness, and energy and power density, and also contain the nano mix “hair particles” to help with, or facilitate, the bonding and anchoring of the electrode to the porous separator and current collector materials. Furthermore, the energy storing electrode may be preloaded with electrolyte prior to printing, and either before or after becoming an ink.

At step AA70, the electrode ink may be applied to create the electrode layer 14. The electrode layer 14 may be applied to the substrate 22 over only the porous separator film cells 32. The ink may thus be sprayed using an indirect print but a direct printing process such as gravure, flexographic, screen, or a transfer drum are easily accomplished too. The electrode layer 14 may be applied over the separator film 12 in more than one layer. The hairy nano material of the electrode layer 14 is configured to nanoscale interlock between adjacent particles and with the particles of the separator film 12 in such a way to assure a high percentage of the protruding nano materials being intercalated within the previous separator film 12 pores. Temperature and pressure treatment may be utilized in order to form a highly entangled interfacial zone between the separator film 12 and the electrode layer 14. For example, after each layer of the electrode is applied, the electrode layer 14 may be flash cured with a pulsed radiation light source. In a similar manner, the electrode materials could become incorporated within the gain boundaries of a printed current collector. While the process for applying the electrode layer 14 may be a wet process as described hereinabove, dry processes are also contemplated. For example, the electrode layer 14 may be electrostatically deposited onto a transfer drum then directly printed onto the separator film 12.

Referring now to FIG. BB, a more detailed, molecular view is shown of how the electrode layer 14 may be formed from hairy particles that are combined together to form super-aggregate groups. As shown, the primary aerogel particles (6 illustrated), each with “hairy” MWNT, CNT or nanowire protrusions, or hairs, are bound together to form the super-aggregate material. The process of forming the super-aggregate groups can be by phase segregation techniques within the sol-gel, as discussed above, to obtain a suspension of the sol-gel materials. Alternatively, they can form directly from hairy primary particles that are aggregated or fused as per the teachings in this section. As shown in FIG. CC, an electrode of the energy storage sheet is formed from a cluster of the super-aggregates. The conductivity by clustering of the super-aggregates can be accomplished, for example, by contact, splicing or fusing of the hairs protruding among different super-aggregates. If performed by splicing, then a splicing agent may be used. The electrode after clustering of the super-aggregates is illustrated in FIG. DD.

In certain embodiments, a process for making tough, low contact resistance high surface area electrode particles is disclosed. This process, and the materials made from it, can produce micron-dimensioned, high surface area thick-films with low internal resistance for high power, and mechanically tough electrodes. The internal toughness of the electrode material may be increased, while also reducing the interconnect CNT resistance, by photonic welding and/or spark plasma sintering of the protrusions of the electrode particles. Electrolyte loading may be used to help in the formation of micron-sized electrode hairy particles. The loaded particles may be formed by a blend of SCF liquid, electrolyte and CNTs in proportions such that the SCF volume fraction approximately equals the volume fraction lost during sintering and shrinkage of the particles. Additionally, or alternatively, the loaded particles may be formed by blending low boiling point liquids or sublimable solids with the electrolyte and CNTs in proportions such that the low boiling point liquids or sublimable solid volume fractions approximately equals the volume fraction during a controlled sintering and shrinkage of the close-packed particles. The process may include loading the electrode particles with electrolyte and assembling the particles into a chamber or cell in order to provide low contact resistance electrodes. The electrode may be formed with the loaded particles by print forming the electrode to form a green state build, which upon densification by sintering and shrinkage of the containment chamber or cell for the electrode, will release entrapped gasses through the open porous structure of the chamber or cell while filling voids within the shrinking chamber or cell with the electrolyte.

In certain embodiments, a process for building a nano-composite, high-permittivity separator is disclosed. In contrast to common belief, the separator for EDLC (electric double layer capacitor) devices can contribute to energy storage and promotes mechanically tough structural elements that store energy. The separator can form a tough continuous interface with embedded energy storing particles such as ceramics or conductive materials and the porous matrix surrounding said particles such as to reduce the propensity for dielectric breakdown. The separator can incorporate thermoplastic coated ceramic, crystalline polymers or conductive materials particles that can be sintered during processing to enable tunable pore formation within the said separator. A tunable porous separator can have pores that are torturous and have an effective length that is 3 to 5 times greater than the true thickness of the separator material. The porous separator may incorporate CNT or nano-fibrous materials that entangle with electrode forming materials on either side of the separator in such a manner that the mechanical strength between the two materials is improved significantly.

In certain embodiments, a process for building a layer-by-layer nano particle structure, which is porous, mechanically tough and demonstrates a suitable permittivity, is disclosed. The process may include a method of formulating a high solid content layer capable of demonstrating high dielectric properties. The high solid content layer may include nanoparticles of high dielectric materials are dispersed within an RTIL electrolyte and suitable binder materials in an amount sufficient to form a tight network of particles that is porous to the RTIL electrolyte to a degree not greater than 60% and more specifically 15-40%. The high dielectric materials might include TiO₂, BaTi₂O₃, and other similar materials. The suitable binders might include thermoplastic and thermoplastic treated crystalline materials with a processing temperature greater than 100-C but below 400-C.

In certain embodiments, printing of the micron or nano-sized particulate matter may be performed by known means to form a continuous thick layer of high permittivity and known pore structures. Additionally, two-sided printing may be performed by known means of thermoplastic encapsulated nano-crystalline materials where said thermoplastic materials forms a layer that enables entanglement of adjacent particles once the processing temperature is obtained. The two-sided printed process may be controlled in such a way where the thickness and type of thermoplastic coupled with the temperature and time for processing predetermines the resulting interstitial voids or pores between the particles once sintered. It may be possible to add CNT or fibrous materials to the separator particles, thereby enabling the formation of extended hair like structures on a micron to nanoscale during processing. Further processing may include embedding electrode particular materials between the separator particles by known printing means in order to form a tough mechanical bond between the separator particles and the electrode materials. The printing of the particles with electrolyte may be accomplished in place by known printing techniques. Finally, sintering the particles to form a density gradient of separator and electrode materials without a well-defined interface is performed.

The pore structures that naturally form within all printed separator materials disclosed may be formed and further regulated by common methods such as the use of porogens from the common class of chemicals known as blowing agents or from multi-phased systems such as, emulsions or thermodynamically stable microemulsions or microsuspensions. When used, such porogen materials are added to the polymer producing or polymer containing inks in amounts typically ranging from 0.1% to 5% by weight but more specifically 0.1 to 2%.

FIG. XX (Slides 1-3) illustrates a cross-sectional view of a printed (e.g., print-formed) pressure tight energy storage cell (or isolation capsule) that is massively repeatable throughout the plane of an energy storage sheet according to certain embodiments. As shown, the cell can include a thin-film porous separator layer together with a patterned, non-porous foundation boundary. The porous separator material may be between about Sum and about 100 um thick, with other thicknesses contemplated for various applications, and may have a mixed pore size distribution. The pattern of the foundation can be such that it defines a cell shape. The cell shape can be, for example, triangular. The substantially planar cell shape can be defined by the edges of the cell shape. In this way, the edges of the cell shape mostly coincide with the pattern of the foundation boundary, leaving the cell shape center mostly coinciding with the separator.

On each side of the separator, a thin-film, patterned electrode is printed. The pattern of the electrode is substantially a reverse image of the foundation pattern; that is, where there is foundation material, there mostly is not electrode material, and vice versa. As shown in the figure, the electrode material directly over both sides of the separator, without covering the foundation material. This type of exemplary exactness in not meant to limit the cell, but instead, is only for illustrative purposes. Each electrode may be printed or deposited using electrode material that includes hairy particles, which are capable of forming, and do form, interlocks among themselves. The hairy particles in the electrode material may be interconnected using a welding or fusing process. This type of electrode processing can provide added strength to the electrode layers, while preserving energy transport properties.

On the non-separator side of each electrode, thin-film collector layers are printed. The collector layers may include one or more sub-layers, which together make up the collector layers. The collector layers are printed to be in intimate contact with each electrode layer. Additionally, the collector layers are printed to be in intimate contact with exposed foundation boundary, if any. The collector layers may provide low resistance collection of current from the electrode layer, and be interlocked to the electrode layer for added strength and stability of the cell. A current bus or rib may be printed to correspond to the foundation in order to carry current in xy plane over large areas or to offset height differences between the electrode and the foundation if needed. The collector layers and the bus or rib if present facilitate the formation of a pressure-tight seal for the cell. The pressure-tight seal between cells may provide isolation between about 1 psi and 10 psi, with higher pressures possible if needed or desired in future applications.

The interface between the separator and electrode and between the electrode and the current collector may not be exact, with a clear distinction or transition from one layer to the next. For example, each interface may have a grainy boundary between the layers, with the electrode material being pinned between the two grainy boundary layer interfaces. Additionally, and as discussed elsewhere in this disclosure, the hairy particles in the electrode material may be interconnected using a welding or fusing process. Cell production may include synchronized, low-temperature processing and pulsed irradiation to obtain conductivity within the layers and to form the pressure-tight seal around the layered cell.

In certain embodiments, the cells can be combined or formed at their edges to form an energy storage sheet. In this configuration, the various layers of each cell are approximately in the same plane with each other (e.g., the separator layers of each cell are approximately in one plane, and so on). It may be possible to produce the sheet with multiple cells, such that the patterned foundation that defines each cell boundary is a shared cell edge between adjacent cells. When produced in a sheet, each cell is capable of energy storage in isolation of one or more of the other cells. Sheets formed in this manner are termed a massively paralleled cell design and may be stacked on their planar surfaces to form a stacked sheet, which may result in synergistic functional characteristics.

In certain embodiments the cells may be individually addressed electrically by printing patterned collector layers on at least one side of the sheet containing a plurality of electrodes in a single plane. In the addressable configuration, printed non-conductive ribs electrically isolate and form a pressure tight seal with the patterned collector layers.

### Alpha Option A Build

The alpha, option A build refers to a print formed energy storage sheet at the conclusion of a product development cycle. In addition, all three versions of the alpha build are 100% print forming process for obtaining an energy storing sheet that is flexible and embodies energy storage technologies while maintaining and meeting structural sheeting requirements.

### Build Process:

### Principle.

The alpha build, option A is a segmented print formed process that overcomes the limitations of sealing found within the V-6 version. To overcome the sealing issue between the electrode and current collector, the separator plus foundation component is preformed onto substrate or plate 1 while the current collector is preformed along with its current bus and electrode onto substrate or plate 2. Next, the mating of the two plates is accomplished after the device is loaded with electrolyte and made ready with a means for forming a permanent seal between the two components. The completed electrode component with its separator is then heat treated to affect sealing. Next, the adhesion to plate 2 by the current collector is reduced in order to allow plate removal without impacting the integrity of the electrode ensemble.

### Details:

Plate 1 with the porous separator and foundation is prepared as previously disclosed in v-6 reports and associated data. Plate 1 is set aside until the mating step. Plate 2, begins by the design and deposition of a temporary release layer (if needed) followed by the placement of a carbon veil under tension directly over the plate completely covering the work area of the build. Next, a direct print step is initiated to print form the current collector onto and predominately through the veil material. A suitable material is cellulose triacetate but other materials are suitable. This step is repeated two additional times to assure a pin-hole free build. For enhanced conductivity and lower ESR, the last coating step should be laced with a suitable film forming conductive polymer solution or metallic ink. One example is a mixture of PEDOT-PSS plus sorbitol plus a surfactant or other wetting agent. Next, a patterned indirect print process is executed to prepare the veil for a current bus. The current bus is then applied with at least one direct print step that overlays the indirect print pattern in order to draw the conductive veil near the plate surface while providing an insulating surface for subsequent processing. Next, a plasticizing material is applied by a patterned print within the electrode pocket formed between the current bus. Next, an electrode adjoining layer is print formed by direct print in order to make contact and transfer with the collector. The purpose and intent here is to enable an interlocking of the electrode with the current collector. Next, a heat treatment to effect bonding is initiated together with the print step or as a separate step. Next, the electrode is built by dry or wet print step(s) and calendared to make ready for mating. Next, a plasticizer materials is applied uniformly over the current bus and foundation patterned by a direct print process. Next, a sparse indirect print process is delivered to the active zone of the electrode and separator. Next, the two plates are mated and cured with heat. Finally, the current collector is separated from plate 2 by known means and the complete and sealed electrode ensemble is made ready for adjoining into a fully functional device by previously disclosed means.

### Alternatives:

The current collection obtained by a means for self-assembling z-axis conduction within the sealing materials before cure or immobilization of the sealing component. Use of known polling technologies inclusive of EMF type or facilitated diffusion by surface area driven forces. Said forces enable gradients driven by surface tension and vapor pressure differences within a multiphase system.

A continuous carbon fiber veil encapsulated within a sealing material such as cellulose triacetate is also a considered and demonstrated z-axis conductor. In order to lower the ESR component, a continuous coating of a conductive polymer or alternatively a conductive metal ink is applied to the inside (facing electrode) surface of the z-axis conductive layer. Suitable materials include PEDOT-PSS with sorbitol and a surfactant as rheology modifiers.

The electrode can be fused to the veil and conductive polymer film within the skeleton using pulsed radiation that is commercially available. Such fusing of the carboneous components has been demonstrated in this effort and reported in the literature. The resulting lowering of resistance and associated increase in strength are of particular interest to this work.
1. A integrated energy storing sheet by print formed processing.
2. A current collecting element formed into a self-sealing component comprised of collector, sealer, and electrode elements.
3. The process for making an ensemble as related to said 1 and 2.
4. A means and process of lowering ESR by interlocking electrode and current collector components.
5. A means and process for enhancing the internal strength of the electrode and current collector ensemble.

### Alpha Option B Build Overview

The alpha, option B build refers to a commercial ready print formed energy storage sheet at the conclusion of a development cycle. As an alpha version, it incorporates the teachings of the previous versions in order to meet technological or manufacturability requirements. In addition, all three versions of the alpha build are 100% print forming process for obtaining an energy storing sheet that is flexible and embodies energy storage technologies while maintaining and meeting structural sheeting requirements.

### Build Process:

### Principle.

The alpha build, option B is a single sided, print formed process that overcomes the mentioned V-6 limitations and the alignment issues of the two plates associated with option A. To provide adequate sealing while overcoming the alignment issues during the mating of the two plates an indirect printed surface preparation step is inserted into the processing. The purpose of this layer is to prepare the electrode surface for receiving solvent loaded separator materials. This is accomplished by printing onto the top of the veil/electrode first with a dry separator material and then with a wet semi-porous separator material. The completed absorbent layer over the electrode component is then dried and printed onto with a suitable separator material that will form a suitably sized porous structure. Next, a foundation layer is print formed by previously discussed means and the structure is completed by known means.

### Details:

A receiver plate begins by the design and deposition of a temporary release layer (if needed) followed by the placement of a carbon veil under tension directly over the plate completely covering the work area of the build. Next, a direct print step is initiated to print form the current collector onto and predominately through the veil material. A suitable material is cellulose triacetate but other materials are suitable. This step is repeated two additional times to assure a pin-hole free build. For enhanced conductivity and lower ESR, the last coating step should be laced with a suitable film forming conductive polymer solution or metallic ink. One example is a mixture of PEDOT-PSS plus sorbitol plus a surfactant or other wetting agent. Next, a patterned indirect print process is executed to prepare the veil for a current bus. The current bus is then applied with at least one direct print step that overlays the indirect print pattern in order to draw the conductive veil near the plate surface while providing an insulating surface for subsequent processing. Next, an electrode adjoining layer is print formed by indirect printing assuring adequate packing and contact and with all components to the collector. The intent being to improve conductivity at the interface to the electrode and to enhance the strength between the two materials. The electrode mixture may include a binding agent or fusing agent where the purpose and intent here is to enable an interlocking of the electrode with the current collector. Next, a heat treatment to effect bonding is initiated together with the print step or as a separate step. This step may include or substitute a pulsed radiation treatment of the build. Next, the electrode is built by dry or wet print step(s) and calendared to make ready for application of the separator. Next, a plasticizer materials is applied uniformly over the current bus and foundation patterned by a direct print process. Next, a sparse indirect print process is delivered to the active zone of the electrode and separator. Next, the two plates are mated and cured with heat. Finally, the current collector is separated from plate 2 by known means and the complete and sealed electrode ensemble is made ready for adjoining into a fully functional device by previously disclosed means.

### Alternatives:

The current collection obtained by a means for self-assembling z-axis conduction within the sealing materials before cure or immobilization of the sealing component. Use of known polling technologies inclusive of EMF type or facilitated diffusion by surface area driven forces. Said forces enable gradients driven by surface tension and vapor pressure differences within a multiphase system.

A continuous carbon fiber veil encapsulated within a sealing material such as cellulose triacetate is also a considered and demonstrated z-axis conductor. In order to lower the ESR component, a continuous coating of a conductive polymer or alternatively a conductive metal ink is applied to the inside (facing electrode) surface of the z-axis conductive layer. Suitable materials include PEDOT-PSS with sorbitol and a surfactant as rheology modifiers.

The electrode can be fused to the veil and conductive polymer film within the skeleton using pulsed radiation that is commercially available. Such fusing of the carboneous components has been demonstrated in this effort and reported in the literature. The resulting lowering of resistance and associated increase in strength are of particular interest to this work.

### Example Ink Formulations For Electrode Mix

### 5/10/2 Solvent Mix

| | |
|---|---|
| Mineral Spirits | 100 ml |
| Hexane | 200 ml |
| Dioxane | 40 ml |

Combine mineral spirits, hexane and dioxane in 16 oz bottle. Shake bottle vigorously to mix solvents.

Electrode Mixes—Formulation w/Mineral Spirits

### Activation:

1. Fill a 2 oz jar to ^{˜}1.5 oz mark with Activated Carbon, mark jar and cap,
2. Fill another 2 oz jar to ^{˜}1.5 oz mark with MWCNT (Elicarb/Tom Swann), mark jar and cap,
3. Bake for 2 hrs of oven under vacuum and at 160° C.,
4. After time is up close off vacuum and slowly vent oven with N2 to Atmosphere, cap bottles.

### Part A (Binder Stock):

1. 30 ml jar
   a. 600 mg PEDOT/Sorbitol solution for Electrode mix,
   b. Add 9 ml of hexane,
   c. Add 1 ml of IPA,
   d. SHAKE . . . ,
   e. Dilute with 5/10/2 solvent mix close to the 30 mL line on the jar,
   f. Sonicate 3-5 min,

### Part B (Electrode Stock):

1. Weigh out on weigh paper,
   a. 0.4 g Activated Carbon,
   b. 0.4 g MWNT (Elicarb/Tom Swann),
2. Add above to clean mortar and press till well mixed,
2. Divide and transfer to two-30 ml jars (this will provide a mix jar for each of the two electrode areas being sprayed),

### Prep of Printing Ink:

1. Take first bottle of Part B and fill to 10 ml mark with Part A
   a. Sonicate Part B just before adding to Part A,
2. Refill to 20 ml mark w/Part A, sonicate and shake for 3 min,
3. Refill to 28 ml level and sonicate and shake for 3 additional minutes; make sure there are no lumps. If additional solvent is required use 5:10:2 solvent mix,
4. Follow spray instructions on SOP for Alum Foil CC w/Electrode Material.

### PEDOT/Sorbitol Solution as Binder for ELECTRODE Mix (Std)

Solution for Addition into Electrode Mix for Adhesion/Binder Properties
2 g PEDOT:PSS (Aldrich 655201—25 g; 2.2-2.6% in H₂O; high conductivity grade)
0.004 g Sorbitol
10 g methanol

### PEDOT/2× Sorbitol Solution for ELECTRODE Mix

Solution for Addition into Electrode Mix for Adhesion/Binder Properties
2 g PEDOT:PSS (Aldrich 655201 —25 g; 2.2-2.6% in H₂O; high conductivity grade)
0.008 g Sorbitol
10 g methanol

### PEDOT/4× Sorbitol Solution for ELECTRODE Mix

Solution for Addition into Electrode Mix for Adhesion/Binder Properties
2 g PEDOT:PSS (Aldrich 655201 —25 g; 2.2-2.6% in H₂O; high conductivity grade)
0.016 g Sorbitol
10 g methanol

### PEDOT/Sorbitol Solution (MeOH Formulation) for Adhesive Layer on Current Collector

1 g PEDOT:PSS (Aldrich 655201 —25 g; 2.2-2.6% in H₂O; high conductivity grade)
1 g Methanol (MeOH)
0.2 g Sorbitol
20 g MeOH

### Examples of Ink Formulations for Separator (CelluloseTriAcetate; CTA)

### 9% CTA Solution (for Non Porous Foundation Layer Printing)

| | |
|---|---|
| Methylene Chloride (MeCl2) | 200 g → 150 ml |
| Methanol (MeOH) | 30 g → 38 ml |
| Cellulose Triacetate (CTA) | 22.8 g |

3% CTA Solution (for Porous Separator Printing with Ultrasonic Spray)

| | | |
|---|---|---|
| Chloroform (CHCl3) | 300 | ml |
| Methanol (MeOH) | 80 | ml |
| Acetone | 40 | ml |
| Cellulose Triacetate (CTA) | 16.78 | g |

50%/50% Dioxane/DI H2O Solution (for Mixing w/3% Porous Separator Ink for Printing with Ultrasonic Spray)

| | |
|---|---|
| Dioxane | 15 ml |
| DI H2O | 15 ml |

### Examples of Ink Formulation for Current Collector (C.C.):

### C.C. Formula #1 (Sprayable Thru Airgun)

5 g DuPont 5018 UV-curable dielectric
1 g Carbon Black
50 mg Multiwall Carbon Nanotubes
26 g Methanol (MeOH)

### C.C. Formula #2 (Drawdown Formulation)

0.71 g Milled carbon fibers
2.14 g DuPont 5018 UV-curable dielectric
0.001 g Multiwall Carbon Nanotubes

### Separator and Electrode Printing Protocols

### Separator Printing Protocol:

### Parameters

Machines
   Syringe pump rate: 2.0 mL/min
   Ultrasound: 3.4 Watts
   Air deflector pressure: approx. 4.5 psi
   Aspirator pressure: 15-20 Bar
   Temperature: 50° C.
Physical measurements of Sonotek assembly
   Distance from centerline of spray nozzle tip to air deflector: 3.25″
   Distance from centerline of spray nozzle tip to plate: 3.125″

### Plate Preparation

A light coating of PTFE should be sprayed onto the full Al flashing plate at a distance of approx. 12″.

### Ink Preparation

10:2 ink
   Mix 20.0 mL of 3% CTA with 4.0 mL of 50:50 dioxane-H₂O in a 30 mL jar. Sonicate and shake well.
10:0.5 ink
   Mix 20.0 mL of 3% CTA with 1.0 mL of 50:50 dioxane-H₂O in a 30 mL jar. Sonicate and shake well.

### Preparing to Screen Print Foundation Layer

Secure the Al flashing plate
   Foundation Layer (nCTA) Screening Technique
Pour a line of 9% CTA on top of the silk-screen above the start of the separator pattern. Only enough of the CTA to cover the entire pattern consistently should be used to ensure a good silk-screen.
Take the applicator (blue) and place it just above the line of CTA. Dab the applicator into the CTA and place it at a 45° angle to the silk-screen. Pull with consistent speed and pressure until reaching the bottom of the silk-screen.
Carefully remove the Al flashing plate and separator with foundation printed from the silk-screen board.

### Preparing to Spray Porous Layer (10:2)

Secure the Al flashing plate
   Turn on the heating plate and ensure that it is set at 50° C. Place the Al flashing plate on top of the copper sheet approx. 0.5″ from the left and rear edges. Ensure that the Al flashing plate is flat against the copper plate. Adjust as necessary.
   The starting position (front to rear) prior to each spray unless otherwise noted of the front edge of the red corner of the copper plate is 14.5″.
   Move copper plate to “Home” position.
Priming the line and starting the pump
   Attach the 10:2 syringe and prime the line
   Turn on the ultrasound, air deflector, and aspirator. Check that the variable parameters are at correct values (see Parameters-Machines). In addition, turn on the LED light behind the spray assembly to allow visible detection of spray. Finally, turn on the syringe pump.

### Porous Layer Spray Technique (10:2)

Once steady, consistent flow is coming from the spray nozzle tip, move the plate back and forth using the manual switch (incrementing by 0.5″) until the plate reaches the 8.0″ marker. Increment by 0.25″ and repeat 4 times.
After all four runs are complete, turn off all equipment and allow plate to dry.

### Preparing to Spray Porous Layer (10:0.5)

Check to make sure the Al flashing plate is still secure and flush to the copper plate. Adjust as necessary.
Follow Preparing to Spray porous layer (10:2)—Priming the line and starting the pump using the syringe of 10:0.5 instead of the syringe of 10:2.
   pCTA Spray Technique (10:0.5)
Once steady, consistent flow is coming from the spray nozzle tip, switch the direction of the copper plate to “Away” and switch the direction of the copper plate to “Home” when the left side of the plate reaches the first “Away” arrow. Once the right side of the plate reaches the first “Home” arrow, repeat above procedure (switch again to “Away” and finally again to “Home”). This should be a total of four passes.
Repeat above process until the plate reaches the 8.0″ marker. Follow subsequent directions from Spray Technique-10:2.
Repeat entire Spray Technique-10:0.5 above.

### Notes

Approximate thickness of final separator can range from 10-40 μm depending on the number of runs chosen.

Leakage Resistance vs. Process Conditions

| Separator Spray Mix | Rp (kΩ) |
|---|---|
| 10:0 @ 50 C. with Thickness ^{~}70 μx | 2.6 |
| 10:2 & 10:0.5 @ 50 C. with Thickness ^{~}80μ | 3.1 |
| 10:1 @ 50 C. with Thickness ^{~}100μ | 3.9 |
| 10:2 @ 50 C. with Thickness ^{~}200μ | 10.8 |
| 10:2 @ 70 C. with Thickness ^{~}200μ | 13.3 |

SOP for Aluminum Foil Current Collector (C. C.) with Electrode Material (Jun. 29, 2011) V2 Ken Lenseth
Attach Aluminum Foil Current Collector (C. C.) onto Al Flashing Carrier:
Spray PEDOT/Sorbitol onto Alum foil (for good adhesion of the electrode onto the Current Collector):
160 C hot plate
Aluminum foil on Al flashing carrier (C. C.)
Mask placed on foil
Prepare PEDOT/Sorbitol for Alum foil C.C.
Airgun w Compressed air source & regulator
   1. Lay C. C. (Al foil on Al flashing) onto 160 C hot plate, then place aluminum foil mask
   2. Spray 3 slightly overlapping swipes of PEDOT/Sorbitol (1 layer) across the mask—let dry completely (1 min), then lay down 5 layers in repeat fashion.
   3. At the end of the last layer, let the final drying stage be 5 min @ 160 C.

### Electrode Deposition by Spray

Al foil C. C. on Al flashing carrier, with PEDOT/Sorbitol spray
Place Electrode Stencil on C.C.
Electrode mix of choice at desired loading level (total area sprayed is estimated to be about 100 cm2); current formulation is Aerogel/MWCNT/PEDOT/sorb in 90/10 hexane/IPA
Sonicate

### Assemble C. C. Foil & Stencil for Spraying:

1. Place Al foil C. C. flat on Al flashing carrier (with PEDOT/Sorbitol spray)

### Spraying of Electrode Mix:

2. Prep electrode mix as above.
3. Divide into 2 bottles (30 mL) one for each electrode area.
   a. Take first bottle and fill to 10 ml mark with 5:10:2 (5 ml mineral spirits: 10 ml hexane: 2 ml dioxane) solvent mix, refill to 20 ml mark, sonicate and shake for 3 min, make sure there are no lumps. Attach bottle to airbrush, adjust air pressure to ^{˜}20 psi static, 15 psi dynamic, turn on N2 for bubbler action (about ⅛ to ¼ turn open) and adjust nozzle for spray pattern, this is ^{˜}w/suction nozzle at just above mid-point of air nozzle (approx. width of line of squares when held 4¼″away).
   b. Turn on hot plate to 250° C. and set timer for 7 minutes.
   c. Spray 3 passes then lower assembly one set of dowel pins and repeat. Take assembly off dowels and place upside down on hot plate set at 250° C., start timer set for 7 mins.
   d. Repeat above with 3 passes each layer for both 9½″ and 9⅞″ spray height positions. Drying between each coating layer on hot plate.
   e. After your 2^{nd} set of 3:3 passes for each layer, refill bottle to 20 ml level, sonicate and shake for 2 minutes.
   f. Repeat above steps for 2 passes each layer at both spray height positions with drying step in-between layers.
   g. Repeat spray steps for 2 passes each layer for both spray height positions with drying step in-between layers.
   h. At this point you should have used all the EM material in bottle w/small residual left.
   i. Shut off compressed air, N2 and clean gun w/acetone while waiting for last dry cycle.

### Activation of Electrode:

1. NOTE: The EM material was pre-activated prior to its formulation.

### Tape Roll and Electronic Tape.

A1. An apparatus for supplying power, the apparatus comprising:
a flexible electronic comprising an electrode and a current collector; and
an interface for attaching to at least one external electronic component.
   A2. The apparatus of claim A1, further comprising a means to enable dynamic patterning for receiving one or more components.
   A4. The apparatus of claim A1, wherein the energy source comprises a power plane, a ground plane and a battery.
   A5. The apparatus of claim A1, wherein the interface comprises one or more pin-outs.
   A7. The apparatus of claim A1, wherein the segments comprising printed cutouts.
   A8. The apparatus of claim A1, wherein the flexible ribbon further comprises a separator, and partition component.
   A9. The apparatus of claim A1, wherein the flexible ribbon further comprises a first ribbon and a second ribbon.
   A10. The apparatus of claims A1, wherein the current collector and electrode are performed onto the first conductive substrate and the separator and foundation components are preformed onto the second conductive substrate.
   A10.1 The apparatus of claim A1, wherein the electrode and current collector are interlocked using a first scheme.
   A 10.2 The apparatus of claim A1, wherein the current collector comprises highly flexible self-sealing components, conductive fibrous and conductive platelets.
   A11. An apparatus for storing energy, the apparatus comprising:
   a flexible device comprising plurality of energy storing segments dispersed across the flexible device;
   a protective seal surrounding a portion of the flexible device; and
   a conductive strip.
   A12. The apparatus of claim A11, further comprising a vinyl embedded device and an internal support rib.
   A13. The apparatus of claim A11, wherein the flexible device comprises a adhesive backing
   A14. The apparatus of claim A11, the energy storing segments are connected in parallel.
   A15. The apparatus of claim A11, wherein the energy storing segments are connected in a series, each segment folded back onto itself in a z-fold or z-shape. A16. The apparatus of claim A11, wherein the energy storing segments comprises a power tape technology.
   A17. The apparatus of claim A11, wherein the energy storing segments further comprises a containment chamber and a current bus.
   A18. The apparatus of claim A11, wherein the energy storing segments comprises a current collector, electrode, and a separator layer.
   A19. A flexible apparatus for storing energy, the apparatus comprising:
   a flexible electrode;
   a flexible current collector, wherein inks which comprise conductive fibrous and conductive platelets are used to form the current collector.
   The method of making ETape
   B1. A method of making a printed electronic tape, the method comprising:
assembling components, the printed components comprising a current collector, electrode, separator and partitions;
loading the electrolyte; and
applying heat and pressure for sealing and seam formation between the components.
   B2. The method of claim B1, assembling comprises of using pulsed irradiation to transfer the electrode materials to at least one of the components.
   B3. The method of claim B1, further comprising applying an adhesive substance.
   B4. The method of claim B1, wherein the assembling components further comprises assembling a current bus.
   B4. The method of claim B1, wherein the printed components further comprises printing a current bus.
   C1. A method of making a current collector, the method comprising:
   printing a doped film forming ink, wherein the ink comprises a conductive fibrous and conductive platelets which are dispersed within a polymer forming matrix;
   matching the surface area to droplet volume ratio to avoid a continuous non-conductive film formation over conductive particles that must overlap or fuse to adjacent particles.
   C2. A method of free-form fabrication of a current collector, the method comprising:
   printing using conductive ink; and
   pulsed ultra-violet curing the ink.
   C3. A method of making a current collector, the method comprising:
   using an ink comprising conductive fibrous and conductive platelets;
   using a pulsed irradiation source to cure;
   C3. A method of making a current collector, the method comprising:
   using an ink comprising conductive fibrous and conductive platelets;
   forming a preformed porous film on a translucent or transparent intermediate drum or plate;
   setting or drying porous film onto said drum or plate;
   using a pulse irradiation transfer scheme;
   using a pulsed irradiation source to cure into a continuous film.
   D1. A method of print forming partitions to form isolated zones within an energy storage apparatus, the method comprising:
   using plasticizing agent, plasticized separator material, and compatible current collector;
   forming a non-porous foundation within the separator film component;
   forming a thick-film seal between current collector and printed plasticized separator material; and initializing plasticization between the previously printed films in order to form a continuous seal between adjacent energy cells.

1. A flexible printed circuit board with energy storing capabilities comprising:
a one or more flexible multi-layer substrates composed of a parallel array of a one or more isolated energy storage element arrays separated by a common current bus.

2. The flexible printed circuit board of claim 1 wherein, the one or more flexible multi-layer substrates composed of a parallel array of a one or more isolated energy storage element arrays separated by a common current bus is conformed as an energy storage structural sheet.

3. The flexible printed circuit board of claim 2 wherein, the one or more flexible multi-layer substrates composed of a parallel array of a one or more isolated energy storage element arrays separated by a common current bus further comprises a means of producing high voltages within the energy storing structural sheet.

4. The flexible printed circuit board of claim 1 wherein, the parallel array of isolated energy storage element array has an energy storage density greater than 5 Wh/kg.

5. The flexible printed circuit board of claim 1 wherein, the one or more flexible multi-layer substrate has a toughness modulus greater than 10 kPa at 10% strain.

6. The flexible printed circuit board of claim 1 wherein, the one or more flexible multi-layer substrate has a toughness modulus of at least 70 kPa at 10% strain.

7. The flexible printed circuit board of claim 1 wherein, the parallel array of isolated energy storage element array further comprises a parallel array of hybrid-supercapacitors.

8. The flexible printed circuit board of claim 1 wherein, the one or more flexible multi-layer substrate further comprises two or more multi-layer substrates.

9. The flexible printed circuit board of claim 8 wherein, a power output of the two or more multi-layer substrates may be added sequentially to the others.

10. The flexible printed circuit board of claim 1 wherein, the parallel array of isolated energy storage element arrays provides a puncture-tolerant circuit.

11. The flexible printed circuit board of claim 1 wherein, the parallel array of isolated energy storage element arrays provides a fault-tolerant circuit.

12. The flexible printed circuit board of claim 1 wherein, the parallel array of isolated energy storage element arrays provides a circuit with enhanced reliability.

13. The flexible printed circuit board of claim 1 wherein, the parallel array of isolated energy storage element arrays may be partially removed.

14. The flexible circuit board of claim 1 wherein, the parallel array of isolated energy storage element arrays is further comprised of super aggregates.

15. The flexible circuit board of claim 1 wherein, the super aggregates create a means to provide optimal mass transport and energy storing capacity of the flexible circuit board.

16. The flexible printed circuit board of claim 1 further comprising an electrically isolated zone in the parallel array of a one or more isolated energy storage element arrays.

17. The flexible printed circuit board of claim 16 wherein the electrically isolated zone further comprises an active electronic component.

18. The flexible printed circuit board of claim 16 wherein the electrically isolated zone further comprises an electronic control element.

19. The method of making a flexible printed circuit board with energy storing capabilities comprising:

providing a one or more flexible multi-layer substrates composed of a parallel array of a one or more isolated energy storage element arrays separated by a common current bus.

20. The method of making the flexible printed circuit board of claim 19 wherein the step of providing the one or more parallel array of a one or more isolated energy storage element arrays further comprises the step of providing a one or more isolated energy storage element arrays which has an energy storage density greater than 5 Wh/kg.

21. The method of making the flexible printed circuit board of claim 19 wherein the step of providing the one or more flexible multi-layer substrates further comprises providing a one or more flexible multi-layer substrate which has a toughness modulus greater than 10 kPa at 10% strain.

22. The method of making the flexible printed circuit board of claim 19 wherein the step of providing the one or more flexible multi-layer substrates further comprises providing a one or more flexible multi-layer substrate which has a toughness modulus of at least 70 kPa at 10% strain.

23. The method of making the flexible printed circuit board of claim 19 wherein the step of providing the one or more parallel array of a one or more isolated energy storage element arrays further comprises the step of providing a parallel array of hybrid-supercapacitors.

24. The method of making the flexible printed circuit board of claim 19 wherein the step of providing the one or more flexible multi-layer substrates further comprises providing two multi-layer substrates.

25. The method of making the flexible printed circuit board of claim 19 wherein the step of providing the parallel array of isolated energy storage element arrays further comprises providing a fault-tolerant circuit.

26. The method of making the flexible printed circuit board of claim 19 wherein the step of providing the parallel array of isolated energy storage element arrays further comprises providing a puncture-tolerant circuit.

27. The method of making the flexible printed circuit board of claim 19 wherein the step of providing the parallel array of isolated energy storage element arrays further comprises providing a circuit with enhanced reliability.

28. The method of making the flexible printed circuit board of claim 19 wherein the step of providing the one or more parallel array of a one or more isolated energy storage element arrays further comprises providing an electrically isolated zone in the parallel array of a one or more isolated energy storage element arrays.

29. The method of making the flexible printed circuit board of claim 28 wherein the step of providing an electrically isolated zone in the parallel array of the one or more isolated energy arrays further comprises providing an active electronic component in the parallel array of the one or more isolated energy arrays.

30. The method of making the flexible printed circuit board of claim 28 wherein the step of providing an electrically isolated zone in the parallel array of the one or more isolated energy arrays further comprises providing an electronic control element in the parallel array of the one or more isolated energy arrays.

31. A power storage device comprising:
a one or more flexible multi-layer substrates composed of a parallel array of a one or more isolated energy storage element arrays separated by a common current bus.

32. The power storage device of claim 30 wherein the power storage device is a power amplification element.

33. The power storage device of claim 30 wherein the power storage device is a backup storage element.

34. The power storage device of claim 30 wherein the power storage device is a power supply element.

35. The power storage device of claim 31 further comprising:
a chipset connection means, wherein the power storage device can be mounted on a rigid or semi-rigid printed circuit board.

36. The power storage device of claim 35 wherein the power storage device is a power amplification element.

37. The power storage device of claim 35 wherein the power storage device is a backup storage element.

38. The power storage device of claim 35 wherein the power storage device is a power supply element.

39. The power storage device of claim 31 further comprising:
a planar surface mount connection means, wherein the power storage device can be mounted on a rigid or semi-rigid printed circuit board.

40. The power storage device of claim 39 wherein the power storage device is a power amplification element.

41. The power storage device of claim 39 wherein the power storage device is a backup storage element.

42. The power storage device of claim 39 wherein the power storage device is a power supply element.

43. The power storage device of claim 31 further comprising:
a means for embedding and connecting in the z-axis, wherein the power storage device can be mounted between two rigid or semi-rigid printed circuit boards.

44. The power storage device of claim 43 wherein the power storage device is a power amplification element.

45. The power storage device of claim 43 wherein the power storage device is a backup storage element.

46. The power storage device of claim 43 wherein the power storage device is a power supply element.

47. The power storage device of claim 31 further comprising:
a planar surface mount connection means, wherein the power storage device can be mounted on a flexible circuit board.

48. The power storage device of claim 47 wherein the power storage device is a power amplification element.

49. The power storage device of claim 47 wherein the power storage device is a backup storage element.

50. The power storage device of claim 47 wherein the power storage device is a power supply element.

1.) A method of manufacturing a flexible printed circuit board with energy storing capabilities comprising:
providing a smooth surface with a high expansion coefficient;
print forming a porous separator material with a suitable permittivity, pore structure and thickness;
print forming a patterned non-porous separator region;
curing the flexible printed circuit board;
print forming an electrode layer mechanically directly to the separator material;
depositing conductive nano-material such that the nano-material permeates the electrode layer;
applying a cross-linkable material to the conductive nano-material;
applying a fusible, conductive nano-material within the pores formed by the cross-linkable material and the conductive nano-material to form a continuous conductive thread; and
curing the final assembled flexible printed circuit board.

1. The method of manufacturing the flexible printed circuit board of claim 1, wherein the step of print forming a porous separator material with a suitable permittivity, pore structure and thickness further comprises the step of print forming with a means for pulsed patterned transfer.

2. The method of manufacturing the flexible printed circuit board of claim 1, wherein the step of print forming a porous separator material with a suitable permittivity, pore structure and thickness further comprises the step of dispersing nanoparticles of a high dielectric material within an RTIL and suitable binder materials.

3. The method of manufacturing the flexible printed circuit board of claim 3, wherein the step of print forming a porous separator material with a suitable permittivity, pore structure and thickness further comprises the step of print forming a porous separator material that is porous to the RTIL electrolyte to a degree not more than 30%.

4. The method of manufacturing the flexible printed circuit board of claim 3, wherein the step of print forming a porous separator material with a suitable permittivity, pore structure and thickness further comprises the step of print forming a porous separator material that is porous to the RTIL electrolyte to a degree between 15-25%.

5. The method of manufacturing the flexible printed circuit board of claim 3, wherein the step of depositing nano-material of a high dielectric material within an RTIL and suitable binder materials further comprises the step of depositing nano-material of a titinate of TiO2 or BaTi2O3 within an RTIL and suitable binder.

6. The method of manufacturing the flexible printed circuit board of claim 3, wherein the step of depositing nano-material of a high dielectric material within an RTIL and suitable binder materials further comprises the step of depositing nano-material of a high dielectric material within an RTIL and a thermoplastic binder with a processing temperature between 100 C and 400 C.

7. The method of manufacturing the flexible printed circuit board of claim 1, wherein the step of print forming a porous separator material with a suitable permittivity, pore structure and thickness further comprises the step of making porous media for energy storage applications using print formed generating inks

8. The method of manufacturing the flexible printed circuit board of claim 1, wherein the step of depositing conductive nano-material such that the nano-material permeates the electrode layer further comprises the step of utilizing a means to interlock the nano-material and the electrode layer through the establishment of one or more concentration gradients by print forming technique.

9. The method of manufacturing the flexible printed circuit board of claim 9, wherein the step of utilizing a means to interlock the nano-material and the electrode layer through the establishment of one or more concentration gradients by print forming technique further comprises the step of interlocking functional components to the flexible printed circuit board by one or more print formed concentration gradients.

10. The method of manufacturing the flexible printed circuit board of claim 1, wherein the step of applying a fusible, conductive nano-material within the pores formed by the cross-linkable material and the conductive nano-material to form a continuous conductive thread further comprises providing the means to form a continuous conductive thread.

11. The method of manufacturing the flexible printed circuit board of claim 1, wherein the step of applying a fusible, conductive nano-material within the pores formed by the cross-linkable material and the conductive nano-material to form a continuous conductive thread further comprises applying super aggregates within the pores formed by the cross-linkable material to form a continuous conductive thread.

12. The method of manufacturing the flexible printed circuit board of claim 1, wherein the step of print forming an electrode layer mechanically directly to the separator material further comprises providing a means for print forming a structurally tough electrode layer.

13. The method of manufacturing the flexible printed circuit board of claim 13, wherein the step of print forming a structurally tough electrode layer further comprises providing the step of forming a structurally tough electrode layer by splicing super aggregates.

14. The method of manufacturing the flexible printed circuit board of claim 13, wherein the step of print forming a structurally tough electrode layer further comprises providing the step of forming a structurally tough electrode layer by fusing super aggregates.

15. The method of manufacturing the flexible printed circuit board of claim 1,

wherein the step of curing the flexible printed circuit board further comprises the step of using a means for pulsed curing of the flexible printed circuit board.

16. The method of manufacturing the flexible printed circuit board of claim 1, further comprising the step of providing the means to build up the desired characteristics of the flexible printed circuit board.

17. The method of manufacturing the flexible printed circuit board of claim 1, further comprising the step of the iterative repetition of the individual step of print forming and curing to build up the desired characteristics of the flexible printed circuit board.

18. The method of manufacturing the flexible printed circuit board of claim 1, further comprising the step of the iterative repetition of the entire process to build up the desired characteristics of the flexible printed circuit board.

19. The method of manufacturing the flexible printed circuit board of claim 1, further comprising the step of reversing build process direction to build up the desired characteristics of the flexible printed circuit board.

20. The method of manufacturing the flexible printed circuit board of claim 20, wherein the step of reversing build process direction to build up the desired characteristics of the flexible printed circuit board further comprises:
the step of print forming an electrode fusion layer on a half-build substrate;
the step of providing an aluminum planar conductor disposed upon the electrode fusion layer; and
the step of fusing and sealing a photo sensitive conductive layer upon the aluminum planar conductor.

21. A method of manufacturing a flexible printed circuit board with a current collector side and a separator side comprising:
processing and aligning the current collector and separator sides sequentially;
joining the two sides as a first half-device;
providing a second half-device;
mating the sides of the first half-device with a second half-device;
subjecting the two half-devices to electrolyte loading;
seaming the two half-devices at one or more ring seals and the external rim of the device.

22. The method of manufacturing the flexible printed circuit board of claim 22, wherein the step of seaming the two half-devices at one or more ring seals further comprises the step of forming the one or more ring seals to isolate ion transport within each energy storing element from its nearest neighbors.

23. The method of manufacturing the flexible printed circuit board of claim 22, wherein the step of seaming the two half-devices at one or more ring seals further comprises the step of forming the one or more ring seals to isolate ion transport within each energy storing cell from its nearest neighbors.

24. The method of manufacturing the flexible printed circuit board of claim 22, wherein the step of processing and aligning the current collector and separator sides sequentially further compromises the means of forming a highly flexible current collector by print forming asymmetric conductors.

25. The method of manufacturing the flexible printed circuit board of claim 22, wherein the step of processing and aligning the current collector and separator sides sequentially further compromises the step of aligning two current collector sides.

26. The method of manufacturing the flexible printed circuit board of claim 22, wherein the step of processing and aligning the current collector and separator sides sequentially further compromises the step of aligning two separator sides.

27. A flexible printed circuit board with energy storing capabilities manufactured according to the method of claim 1, comprising:
a smooth surface with a high expansion coefficient;
a print-formed porous separator material with a suitable permittivity, pore structure and thickness;
a print formed patterned non-porous separator region;
a print formed electrode layer mechanically directly to the separator material;
a conductive nano-material deposited such that the nano-material permeates the electrode layer;
a cross-linkable material applied to the conductive nano-material; and
a fusible, conductive nano-material applied within the pores formed by the cross-linkable material and the conductive nano-material to form a continuous conductive thread.

28. The flexible printed circuit board of claim 28 wherein deposited conductive nano-material constitutes a current collector.

29. The flexible printed circuit board of claim 29 wherein the current collector is a self-sealing current collector.

30. The flexible printed circuit board of claim 29 wherein the current collector is a low density current collector.

1. A method of manufacture for an electrode ink used to make an electrode layer of an energy storage sheet, comprising:
preparing a nano-mix;
preparing a sol-gel mixture using the nano-mix;
drying the sol-gel mixture to form a hardened material;
pyrolyzing the hardened material to form a pyrolyzed material;
turning the pyrolyzed material into a powder; and
preparing electrode ink using the powder.
2a. The method of claim 1, wherein preparing the nano-mix comprises:
blending one or more nano-materials, the nano-materials including polymers, metals, oxides of metals, silicon, ceramic and carboneous materials,
   2b. The method of claim 1, wherein preparing the nano-mix comprises:
blending one or more materials, the materials including polymers, metals, oxides of metals, silicon, ceramic and nano-materials,
wherein the nano-materials includes carbon nanotubes (CNT), multi-walled nanotubes (MWNT), and fat, long-aligned CNT bundles.
   3. The method of claim 2, wherein the carbon nanotubes have a carbon density of between about 0.5 g/cc and about 2 g/cc.
   4. The method of claim 1, wherein the preparing the sol-gel mixture comprises combining precursory materials for aerogel formation and the nano-mix.
   5. The method of claim 1, wherein turning the pyrolyzed material into a powder comprises grinding the pyrolyzed material using a cryogenic ball milling process.
   6. The method of claim 1, wherein preparing the electrode ink comprises mixing the powder with one or more coupling agents and one or more rheological agents.
   7. The method of claim 6, wherein preparing the electrode ink further comprises combining in one or more dispersing agents.
   8. An electrode ink used to make an electrode layer of an energy storage sheet, comprising:
   means for preparing a nano-mix;
   means for preparing a sol-gel mixture using the nano-mix;
   means for drying the sol-gel mixture to form a hardened material;
   means for pyrolyzing the hardened material to form a pyrolyzed material;
   means for turning the pyrolyzed material into a powder; and
   means for preparing electrode ink using the powder.
   9. The electrode ink of claim 8, wherein the means for preparing the nano-mix comprises:
means for blending one or more materials, the materials including polymers, metals, silicon, oxides of metals, ceramic and nano-materials,
wherein the nano-materials includes carbon nanotubes (CNT), multi-walled nanotubes (MWNT), and fat, long-aligned CNT bundles.
   10. The electrode ink of claim 9, wherein the electrodes have a carbon density of between about 0.5 g/cc and about 1.5 g/cc.
   11. The electrode ink of claim 8, wherein the conductive powder is dispersed with one or more coupling agents and one or more rheological agents.
   12. The electrode ink of claim 11, wherein the means for preparing the electrode ink further comprises means for combining in one or more dispersing agents.
   1. A seamlessly integrated energy storing sheet by print formed processing.
   2. A current collecting element formed into a self-sealing component comprised of collector, sealer, and electrode elements.
   3. The process for making an ensemble as related to said 1 and 2.
   4. A means and process of lowering ESR by interlocking electrode and current collector components.
   5. A means and process for enhancing the internal strength of the electrode and current collector ensemble.
      1. An apparatus for energy storage, comprising:
      an energy storage cell, the cell including:
   a printed, thin-film, porous separator having a thickness and a substantially planar shape, the shape being defined by shape edges;
   a printed, thin-film, patterned, non-porous foundation boundary along the edges of the separator;
   a plurality of printed, thin-film, patterned electrodes, at least one electrode in intimate contact with a first planar surface of the separator and at least one other electrode in intimate contact with a second planar surface of the separator; and
   a plurality of printed, thin-film collector layers, at least one collector layer in intimate contact with an outer planar surface of the at least one electrode and a first planar surface of the foundation boundary, both on the same side of the cell, and at least one other collector layer in intimate contact with an outer planar surface of the at least one other electrode and a second planar surface of the foundation boundary, both on the other side of the cell,
   wherein the plurality of collector layers facilitates a pressure-tight seal for the cell.

69
1b The apparatus of claim 1, wherein a plurality of conductive current buses or non-conductive ribs are printed to coincide with the underlying foundation boundary on both sides of the planer foundation.
1b The apparatus of claim 1, wherein a plurality of non-conductive ribs are printed to coincide with the underlying foundation boundary on both sides of the planer foundation and wherein the said collector layers on at least one side of the sheet are patterned over the electrodes in a manner that they are discontinuous over the plane of the sheet.
   2. The apparatus of claim 1, wherein a plurality of energy storage cells is formed together along at least one respective shape edge to produce an energy storage sheet.
   3. The apparatus of claim 2, wherein each cell is capable of energy storage in isolation of at least one of the remaining plurality of cells.
   4. The apparatus of claim 2, wherein at least two of the plurality of cells share the foundation boundary along a shared edge.
   5. The apparatus of claim 2, wherein a plurality of energy storage sheets are combined on planar surfaces to form a stack of energy storage sheets.
   6. A method of producing an energy storage device, comprising:
printing at least one thin-film, porous separator and at least one patterned, thin-film, non-porous foundation boundary, wherein the pattern defines a substantially planar shape, the shape being defined by the foundation boundary at edges of the shape;
printing a plurality of patterned, thin-film electrodes, at least one electrode in intimate contact with a first planar surface of the separator and at least one other electrode in intimate contact with a second planar surface of the separator; and
printing a plurality of thin-film collector layers, at least one collector layer in intimate contact with an outer planar surface of the at least one electrode and a first planar surface of the foundation boundary, both on the same side of the cell, and at least one other collector layer in intimate contact with an outer planar surface of the at least one other electrode and a second planar surface of the foundation boundary, both on the other side of the cell.
   7. An apparatus for energy storage, comprising:
means for printing at least one thin-film, porous separator and at least one patterned, thin-film, non-porous foundation boundary, wherein the pattern defines a substantially planar shape, the shape being defined by the foundation boundary at edges of the shape;
means for printing a plurality of patterned, thin-film electrodes, at least one electrode in intimate contact with a first planar surface of the separator and at least one other electrode in intimate contact with a second planar surface of the separator; and
means for printing a plurality of thin-film collector layers, at least one collector layer in intimate contact with an outer planar surface of the at least one electrode and a first planar surface of the foundation boundary, both on the same side of the cell, and at least one other collector layer in intimate contact with an outer planar surface of the at least one other electrode and a second planar surface of the foundation boundary, both on the other side of the cell.
   1. A print formed separator with and without a non-porous foundation (for strength)
   2. A print formed free-standing electrode from fused particles with and without a non-porous rib (addressable electrode) or bus (connected electrodes) for strength or as inserted with ( )

### Electrode—Method of Making

X1. A method of making an electrode, the method comprising:
printing a film, the printing comprising direct or indirect printing;
densification; and
activation by heating.
   X1. A method of making an electrode, the method comprising:
printing a film, the printing comprising direct and indirect printing;
pre-forming the film on an device for processing and densification; and
transferring the film to a receiver;
   X2. The method of claim X1, wherein indirect printing comprises using low viscosity inks and using solvent evaporation to drive the setting and compaction of the film.
   X3. The method of claim X1, wherein direct printing comprises using high viscosity inks and using a slow drying scheme for form the film.
   X4. The method of claim X1, wherein transferring comprises pulsed irradiation through a translucent device which serves as transfer agent.
   X5. The method of claim X1, wherein printing comprises of forming a film that is highly conductive by using solid ink.
   X6. The method of claim X1, wherein printing comprises of micro-emulsions comprising salt for fabrication of porous separators with tunable pore size control.
   X7. The method of claim X1, wherein printing the film comprises of using ink comprising phase separation pore forming agent for free forming fabrication.
   X8. The method of claim X1, wherein printing the film comprises of using ink comprising sub-limable pore forming agent for free forming fabrication.
   1. A method for producing an energy storage device, comprising:
printing a first and second current collector plate on respective first and second current collector plate substrates;
printing a first and second separator plate on respective first and second separator plate substrates;
mating the first current collector plate and the first separator plate to form a first sheet sub-assembly;
mating the second current collector plate and the second separator plate to form a second sheet sub-assembly; and
mating the first sheet sub-assembly and the second sheet sub-assembly to form the energy storage device.
   2. The method of claim 1, wherein printing each of the first and second current collector plates comprises:
   printing a collector sub-assembly on a first substrate;
   printing a patterned electrode layer on the collector sub-assembly; and
   printing a foundation boundary.
   3. The method of claim 2, wherein:
   the collector sub-assembly includes:
   4. The method of claim 1, wherein printing each of the first and second separator plates comprises print-forming a separator sub-assembly on a second substrate.
   5. The method of claim 4, wherein printing the separator sub-assembly comprises:
   6. The method of claim 1, wherein mating each of the current collector plates and the respective separator plates comprises:
   A flexible integrated power tape, adapted for use in electronics devices, comprising: at least one energy segment element operatively coupled to an interconnect strip member, wherein the interconnect strip member is adapted to carry electrical current.
   An energy storing tape, comprising: an energy segment element electrically coupled to an interconnect strip member, wherein the interconnect strip member is adapted to carry electrical current.
   An energy storage tape aggregate, comprising: a plurality of energy segment elements electrically coupled to an interconnect strip member, wherein the interconnect strip member is adapted to carry electrical current, wherein the plurality of energy segment elements is tunably overlapped such that higher overall voltages are scaled proportional to such overlap.
   A folded energy storage tape aggregate, adapted for capacitive tuning, comprising: a plurality of successive layers comprising: a plurality of energy segment elements electrically coupled to an interconnect strip member, wherein the interconnect strip member is adapted to carry electrical current; wherein the plurality of successive layers are folded
   An energy storing sheet, adapted for print form processing, comprising: a current collecting element formed into a self-sealing element comprising: a current collector member operatively coupled to a sealer element, and; an electrode element.
   A method for manufacturing an energy storing sheet, comprising: a means for interlocking and electrode element with a current collector component; means for providing a high internal strength factor of the electrode element; means for providing a high internal strength factor of the current collector component.
   An energy storing power patch, comprising: a flexible material member having a scalable patch area; a tunable dimensional element wherein the tunable dimensional element is adapted to scale capacitance proportional to the scalable patch area.
   1. A flexible integrated power tape or “powered printed circuit board” for electronics applications
   “Flexible PCB technology . . . to attach various electronic components to the flexible “printed circuit board”.” dynamic patterning
   The coupling of the etape design, the PCB and the option C inclusive of the simplified processing. The “flexible PCB” is a close hit for the integrated control/power vision of the market we are headed into. It is also a direct hit for the Etape like lining to the encasement of the server. The idea is to make a flexible power tape or strip that can have components mounted directly into the tape or strip tapping then power within. As such, the component of an integrated PCB with power and components is realized.
      A flexible printed circuit board, comprising:
   a interface element, having a receptacle disposed therein, adapted to accept a connector element, wherein the interface element is malleable.
   1. Dynamic patterning by a “flexible PCB w/attached electronic components, wherein in one embodiment option C is employed
   2. Packaging efficiency improvements by embedded power containing sheeting
   The energy density (volumetric and gravimetric) is improved when the technology can be embedded. The packaging efficiency gain is expected to be in excess of 30% and possibly closer to 50%. As such, the final sealing toward external gases and moisture are shared between the OEM and PBC.
   in one embodiment packaging materials are 30% of the total weight content of the device, approximately 25% improvement in total energy density is possible by combining multiple device layers in one package.
   3. Embedded energy for electronics, composite materials and other energy storage devices
   flexible PCB concept to embedding technologies (coupling the composite disclosure for option B and the flexible PCB concept for option C)
   4. An energy storing powerpatch or chip having a flexible format and tunable dimensional characteristics (in one embodiment option A build)
   To overcome the sealing issue between the electrode and current collector, the separator plus foundation component is preformed onto substrate or plate 1 while the current collector is preformed (in one embodiment, a preformed foil is employed) along with its current bus and electrode onto substrate or plate 2. Next, the mating of the two plates is accomplished after the device is loaded with electrolyte and made ready with a means for forming a permanent seal between the two components. The completed electrode component with its separator is then heat treated to affect sealing.”
   5. An energy storing tape for rapid prototyping, power anywhere and space based power applications
   Etape™ is a flexible energy storing tape roll with or without an adhesive backing that can be formatted like any other tape product of similar nature. It can in fact be substituted for masking tape, duct tape or scotch tape. The difference is that it can be charged and discharged when properly interfaced to a power supply or load respectively. High voltages can be formatted by z-folding back onto a common surface to form a brick or prismatic device or by shingling multi-layered strips into an alternate pattern such that the underside to topside are interconnected to form large areas of power in a fashion similar to roofing materials. In addition, the Etape can be cut to form or folded or adhered to many surface types. To make electrical contact, the tape can be inductively or direct connected to loads or power.
   In one embodiment 1) design for enabling stretchable, 2) a tape that has energy
   1. a means of interfacing electronic components by means of standard pin-out and soldering.”
      A flexible integrated power tape, adapted for use in electronics devices, comprising: at least one energy segment element operatively coupled to an interconnect strip member, wherein the interconnect strip member is adapted to carry electrical current.
      An energy storing tape, comprising: an energy segment element electrically coupled to an interconnect strip member, wherein the interconnect strip member is adapted to carry electrical current.
   6. CAD based dynamic patterning at the print shop offering customizable fit to form inclusive of holes, slots and filled vias.
   Similar to cut-to-form but more extensive requirements based on an actual device mounted on PCB board or within PCB board etc.
   7. The design and fabrication of stretchable Etape based power and energy for rapid prototyping
   Rhombus design, ink formulations for separator and electrode and collector are known but weak.
   Use rhombus design and describe in words the flexible separator design to match up
   8. A means of transferring electrode materials to separator or current collector materials using pulsed irradiation.
   This transfer process is and has been reduced to practice. Figure to be added
   9. A structural energy storing sheet suitable for incorporation into carbon composites, aircraft wings and fuselage, automotive paneling, tents etc.
   10. A storage sheet tolerant to nails and punctures
   Describe with reference to electrolyte isolation in cells and add chemical isolation . . . use previous drawings of powerpatch to reference structure . . . reactivity relationships within materials used for the
      electrodes and current collecting for a default-tolerance technology that is capably of rapidly recovering
      from nail punctures during installation using a to-be . . . discovered recovery algorithm and electronics.
      During installation, the sheeting will be attached by an adhesive over which siding or roofing materials with be attached by standard practice (e.g., nails). Once installed, the sheeting
      will be connected via a fail-safe electronics interface. Within the fail-safe design the following
      sequence will occur when the box is turned “on”. First, a system check to. assure no shorts
      exists. If shorts (pin-hole or other) are indicated then a self . . . annealing process will be activated.
      Said recovery from pin-holes or nail punctures could take 24- to 72-hrs but would not require
      human interaction. Once all shorts are removed, a partial charging I discharging sequence will
      occur to confirm the sheeting is fully operational before a full charging ramp begins. It is
      expected that the healing process will generate a volume increase within the cells impacted and
      this expansion will serve in-part as the recovery process. It is also assumed that a 15% to 20%
      openness wm be available within the film to enable electrolyte expansion into the open structures during high temperature or voltage operation.
      electrolyte technology for >3.2V at 60 C for 30,000 cycles (stable ˜20 C to noc for limited cydes)
      To be successful, a very low˜vapor pressure electrolyte will be developed that is: 1), stable over the temperature range indicated, 2}, compatible with the entire material set, and 3),
      can operate at 4V (60 e) preferred, 3.6V (GOe) acceptable.
      Note: This activity will require dose collaboration with all other tracks in-order to assure

### Compatibility

Ultra low profile for surface mounted applications in consumer electronics or for embedding within
active components. A fault tolerant design uses massively parallel, but isolated, storage cells that
enable uninterrupted power even if a loss of some cells occurs or when the product is punctured.
The stiff but flexible PowerPatch enables a conformable power source
A fault tolerance energy storage cell apparatus, adapted to continue functioning to provide electrical power when punctured, comprising:
a plurality of isolated energy storage cell members, mechanically connected, having an aggregate voltage, wherein each of the plurality of isolated energy storage cell members is adapted to contain an electrolyte therein, wherein when one of the plurality of isolated energy storage cell members is punctured, only electrolyte contained therein will cause a fault;
a fault detection algorithm, rendered as a software program, adapted for storage in a memory storage medium, wherein the fault detection algorithm is further adapted to detect an aggregate voltage change in the plurality of isolated energy storage cell members due to puncturing of at least one of the plurality of isolated energy storage cell members, wherein the fault detection algorithm changes the aggregate voltage to provide a continuous power source.
   A fault tolerant supercapacitor, comprising:
a plurality of isolated energy storage cell members, mechanically connected, having an aggregate voltage, wherein each of the plurality of isolated energy storage cell members is adapted to contain an electrolyte therein, wherein when one of the plurality of isolated energy storage cell members is punctured, only electrolyte contained therein will cause a fault; a fault detection algorithm, rendered as a software program, adapted for storage in a memory storage medium, wherein the fault detection algorithm is further adapted to detect an aggregate voltage change in the plurality of isolated energy storage cell members due to puncturing of at least one of the plurality of isolated energy storage cell members, wherein the fault detection algorithm changes the aggregate voltage to provide a continuous power source.
   Examples of error detection and correction algorithms employed for fault tolerant detection
   Further information: Error detection and correction

### BCH Codes

Berlekamp-Massey algorithm
Peterson-Gorenstein-Zierler algorithm
Reed-Solomon error correction
BCJR algorithm: decoding of error correcting codes defined on trellises (principally convolutional codes)
Forward error correction
Gray code
Hamming codes
Hamming (7,4): a Hamming code that encodes 4 bits of data into 7 bits by adding 3 parity bits
Hamming distance: sum number of positions which are different
Hamming weight (population count): find the number of 1 bits in a binary word
Redundancy checks

### Adler-32

Cyclic redundancy check
Fletcher's checksum
Longitudinal redundancy check (LRC)
Luhn algorithm: a method of validating identification numbers
Luhn mod N algorithm: extension of Luhn to non-numeric characters
Parity: simple/fast error detection technique
Verhoeff algorithm
A puncture tolerant supercapaticor, comprising:
a plurality of isolated energy storage cell members, mechanically connected, having an aggregate voltage, wherein each of the plurality of isolated energy storage cell members is adapted to contain an electrolyte therein, wherein when one of the plurality of isolated energy storage cell members is punctured, only electrolyte contained therein will cause a fault;
a fault detection algorithm, rendered as a software program, adapted for storage in a memory storage medium, wherein the fault detection algorithm is further adapted to detect an aggregate voltage change in the plurality of isolated energy storage cell members due to puncturing of at least one of the plurality of isolated energy storage cell members, wherein the fault detection algorithm changes the aggregate voltage to provide a continuous power source.
   A puncture tolerant electrolytic double layer capacitor, comprising:
a plurality of isolated energy storage cell members, mechanically connected, having an aggregate voltage, wherein each of the plurality of isolated energy storage cell members is adapted to contain an electrolyte therein, wherein when one of the plurality of isolated energy storage cell members is punctured, only electrolyte contained therein will cause a fault;
a fault detection algorithm, rendered as a software program, adapted for storage in a memory storage medium, wherein the fault detection algorithm is further adapted to detect an aggregate voltage change in the plurality of isolated energy storage cell members due to puncturing of at least one of the plurality of isolated energy storage cell members, wherein the fault detection algorithm changes the aggregate voltage to provide a continuous power source.

### Grid Level—Building Integrated Storage:

Integrating structural energy storing sheets within replaceable ceilings of high rise office buildings or the underlayment to roofs for more traditional residential buildings, the PowerWrapper™ platform technology, as a flexible energy storage sheeting, provides the potential for GWatt levels or more of storage capacity for every 10 million buildings so outfitted. Most importantly, a building materials cost model enables transformational change in how energy storage is envisioned and scaled within the grid. A long-life capacitance sheet that is robust, fault tolerant and easily incorporated into everyday building materials such as roofing underlayment, moisture barrier house wrap, or interior wall paper is envisioned. Control and interface electronics are expected to be imbedded into the sheet, for charge discharge and power conditioning across the massively parallel array of cells.
A structural energy storing sheet, adapted for use in a building structure, comprising:
A structural energy storing sheet, adapted for roofing:
A structural energy storing sheet, adapted to be disposed in a ceiling cavity, comprising:
a separator,
an electrode,
a collector.
Distributed Grid level storage (silo storage)
Parts have been demonstrated (separator, electrode and collector) at least for limited strained situations. More needs to be done but we can draft claim language here.
Add drawing
   Building Integration Market PowerWrapper Deployment
   Compatible with PowerWrapper's sheet format due to production and installation methods, as well as high surface area opportunities cm structures
   Deployable on rooftops, walls, floors, ceilings: windows and walkovers
   Integration occurs naturally within installation process of building construction
   Costs can be amortized over life of structure or mortgage (benefits accrue for 15+ years)
   Concerns: High costs, installation costs (labor) and process, strict safety standards (grounding, etc.), performance compatibility (fault tolerance for nailed installation: etc.)
      A flexible energy storage sheeting apparatus, comprising:
a separator,
an electrode,
a collector.
   An integrated structural energy storing sheet apparatus, adapted for providing electrical power comprising:
a separator,
an electrode,
a collector.
12. Highly distributed energy storage for secured grid level applications (roofing, siding, and ceiling and flooring)
puncture tolerance, interconnection for high voltage by shingling. Large scale adoption of EDLC, control electronics.
A puncture tolerant sheet apparatus,
   A highly distributed energy storage apparatus, adapted for secured grid level applications, comprising:
an integrated structural energy storing sheet apparatus, adapted for providing electrical power comprising:
a separator,
an electrode,
a collector.
   Model structural sheeting within residential and buildings everywhere inclusive of interconnectivity to the gridl designs that allow fail safe mechanisms such as GF and circuit breaker
   design.
   A network of homes and buildings within a reasonably sized community will be modeled to fully assess the grid level implications of have a terminus based energy storage
   system. Refer to discussion on fault tolerant materials track 3 for additional details. The basic
   idea is to charge sheets as 33 to 44V parallel elements and discharge these surfaces as 240-V to
   330-V (??) serial elements. Each element is an eleven layered device connected serially internally. Thermal modeling for cycling assessment is also part of this effort.
   To produce 300 Wh rolls, 10-m long rolls each having a 15- to 30-em width. It IS expected that we will
   need 300 to 600 rolls
13. The design and fabrication of tunable cloth-like flexibility in high energy sheeting by the use of z-axis oriented conductive filaments as current collectors (see FIG. 3)
The structural sheet energy storing sheet's mechanical properties are dominated by materials and their composites, and the processes to make the sheets, These properties are also dependent on the design, density and dimensions of the ring seal/bus that serve to form the independent isolated cells within the sheet. A particularly useful innovation is the use of asymmetric free-forming fabrication to communicate out of plane current conduction or “z-axis” conductivity. In so doing, filaments of various aspect ratios and various cross sectional area interconnect the open electrode to the application interface through a self-sealing composite that contains these filaments. Taken together the conductive filaments and non-conductive self-sealing filler form a sealed current collector to the sheets. By tuning the cross sectional area, the special density and the aspect ratios, these conductive fingerlings can manage any power requirements of the sheet while also keeping the chemical reactivity and overall gravimetric density of the device low. In one embodiment, the use of fingerling type collectors to provide cloth like properties into the sheet. Without the fingerlings highly flexible cloth like properties are not feasible.
A tunable energy storing sheeting apparatus, comprising:
   a plurality of current collectors, comprising:
      a plurality of z-axis oriented electrically conductive filaments V-6 build details that reduced the design into practice. A typical build includes print forming an alternating open layer of non-conductive and conductive inks that are fusible and self-seal within a multilayered fabrication process. Initially these inks provide a swollen layer that upon curing or setting form a continuous sealed film within a few layers composed of alternating print plus set cycles. A design goal of such a fabrication is to interlock the porous electrode particles into the collector such that low ohmic contact and optimal mechanical strength obtained within the interfacial region of the two materials or films. “self-assembling z-axis conduction within the sealing materials before cure or immobilization of the sealing component. Use of known polling technologies inclusive of EMF type or facilitated diffusion by surface area driven forces. Said forces enable gradients driven by surface tension and vapor pressure differences within a multiphase system.”
14. A seamlessly integrated electrode to collector using a high conductivity conductive interfacial material as binder and interlocking agent for improved power and mechanical properties
A integrated electrode to collector apparatus, comprising:
   a high conductivity conductive interfacial binder material;
   an interlocking agent element.
1. “Suitable materials include PEDOT-PSS with sorbitol and a surfactant as rheology modifiers.”
2. “The electrode can be fused to the veil and conductive polymer film within the skeleton using pulsed radiation that is commercially available. Such fusing of the carboneous components has been demonstrated in this effort and reported in the literature. The resulting lowering of resistance and associated increase in strength are of particular interest to this work.”
3. “A means and process for enhancing the internal strength of the electrode and current collector ensemble.”
15. An ink and method of print forming said ink to form low density, low cost carboneous current collector (see FIGS. 4A and 4B). use “option C” limits
We have demonstrated conductive films but not suitable for builds. More work on ink formulation has been completed. In one embodiment, a method for printing film employs drawdown.
Claim could still be drafted based on our work for interlocking of electrode and collector by this means and UV curing of conductive films (thin-films) with step and repeat
16. And an ink formulation for highly conductive carboneous films (option C limits)
Yet another means for forming a highly flexible low density low cost current collector is by the printing of a doped film forming ink. To obtained the desired rheology and conduction properties within the final film, said inks are comprised of conductive fibrous and conductive platelets dispersed within a polymer forming matrix. Next, said inks are matched to the print forming process in order to avoid or minimize the film forming nature of the polymer forming materials. To do so, said film forming materials within the inks must be a level that avoids a continuous non-conductive film formation over the conductive particles that must overlap or fuse to adjacent particles of similar nature. In one embodiment, the ink formulation and matching of such formulations to a deposition processes in order to avoid filming over of the hairs in order to preserve the conductive properties within cured or set films is employed.
Schematic of process for early and technical goals of option C build
17. Electrophotographic based free-formed fabrication of electrodes for energy storage (see figure)
In one embodiment, a process coupled with the “popcorn” releasing or transfer listed below. an electrode deposited by this technology
Multiple means of fabricating a suitably porous electrode are known. Among them are indirect and direct printing of said materials. In indirect printing, the inks are typically of low viscosity and rely on solvent evaporation to drive the setting and compaction of the final film. For direct printing, the inks are typically highly viscose materials and slow drying. One preferred means of forming an electrode element is to pre-form the film on an intermediate drum or plate for processing and densification before transferring the film by a known means to the substrate or receiving layer or separator or current collector of a device. An innovation that broadens the scope of these means to transfer the free-form film to the build, substrate of device is to cause transfer by pulsed irradiation through a translucent or transparent drum or plate serving as a transfer agent. Such processing, is rapid, solvent free and easy adapted to controlled environments.
Schematic of such a process
18. Pulsed UV processing of separator, electrode materials to effect pore formation and the fusing of adjacent particulate materials
Pulsed irradiation for effecting mechanical properties within non-porous and porous materials and to form regions within such printed films is
“ . . . heat treatment to effect bonding is initiated together with the print step or as a separate step. This step may include or substitute a pulsed radiation treatment of the build.”
Add FIG.
19. Pulsed UV curing and fusing of current collector inks and electrode particulate materials
Option C build sequence and results showing embedded particles within UV curable 100% solid inks
   Computing soft shut down applications—PowerChip (multi-layered stacked device packaged as rigid, modular with interconnects and attaches with flex connector to memory module card.
   A soft shut-down apparatus, adapted for use in a digital memory module member, comprising:
a multi-layer stacked module element, having a plurality of interconnection interface members;
a flex connector element.
   A high area electrode apparatus, comprising:
an open electrode, providing a linear correlation between thickness and energy storing capacity
   A high area electrode apparatus, comprising:
a wide dynamic range,
   Could have active or passive balancing circuitry built in, along with charge discharge circuits. Soft shut down application in hybrid memory cards, solid state drives, SD memory cards, RAID Cards in data and telecom servers—packaged with casing of SolidStateDrives (SSDs) or into SD cards as thin layer that is part of casing and does not take up space on circuit board. Packaging innovations for SSD or SD card applications of interest. Modular device design for hybrid memory module applications. See attached document.
   Competitive advantage is the ability to make devices that can distribute volume occupied by cylindrical devices and achieve thin devices that can fit the required footprint and limited space on the memory card or within server framework. Protect product by blocking others (key patented claims) from making patternable thin high voltage devices:
from making similar devices as a parallel array of isolated cells with current collector and ring seal forming sealed package
from making multi-layered stacked devices with embedded other circuit components, parallel or series arrangements between layers, with a single hermetic packaging achieved
   Parallel array of isolated cells within each device layer. Ring seal that isolates each cell in the array and also provides seal for each device layer. Electrode and separator design could be implemented in this device as technology becomes commercially viable. Packaging could be shared with frame of server but likely to be a stand alone device in its current design.

### GEN2 PowerWrapper Device—Applications:

Inside a cell phone as sheet that wraps into the battery or supercapacitor compartment floor, around battery, supercapacitor or as layer lining inside of case. Conformable, high power sheet that has all interlocks formed, most elements of patent claims embodied. First version is standalone component as a supercapacitor that attaches to circuitry or battery or supercapacitor to enhance performance. Other application is as part of the packaging of a medical patch for physiological monitoring—our device could be the adhesive part of the strip and needs to be flexible and stretchable to some extent. Device will be patterned during print or end packaging process.

### Applications for GEN3 PowerWrapper Device:

Embedded in circuit board as patterned device between power and ground planes. This will likely be licensed to the PCB manufacturer who will put it into their manufacturing process and deliver an end product with our technology embedded. Patterning with vias, packaging between ground and power planes of PCB card etc innovations are part of the functionality important for this device.
Electronic devices markets. High power as lining of case, power plane for digital and analog electronics in circuit boards, digital cameras for battery or supercapacitor enhancement, fast charge capable in tablet PCs, smartphones. Soft shut down local power in computing environments, UPS replacement in PCs with local power down. Power tools (enhancement of performance and productivity); wireless sensors, storage for energy harvesting devices. Fast recharge applications for battery or supercapacitor replacement. Complimentary to thin film batteries that need high power in smart cards, other applications. Flexible solar panel applications.

### Transportation:

Transportation applications for regenerative braking close to site with space and weight reductions; replace structural parts with our multifunctional materials—load bearing and energy storage.

### Military and Medical Applications

Enhance portability of devices by being part of structure, hybrid battery and supercapacitor devices can be smaller and weight less with enhanced performance. Integrated energy storage for solar tent and solar blankets, sensors, diagnostic tools, handheld devices—replace batteries for fast recharge applications.

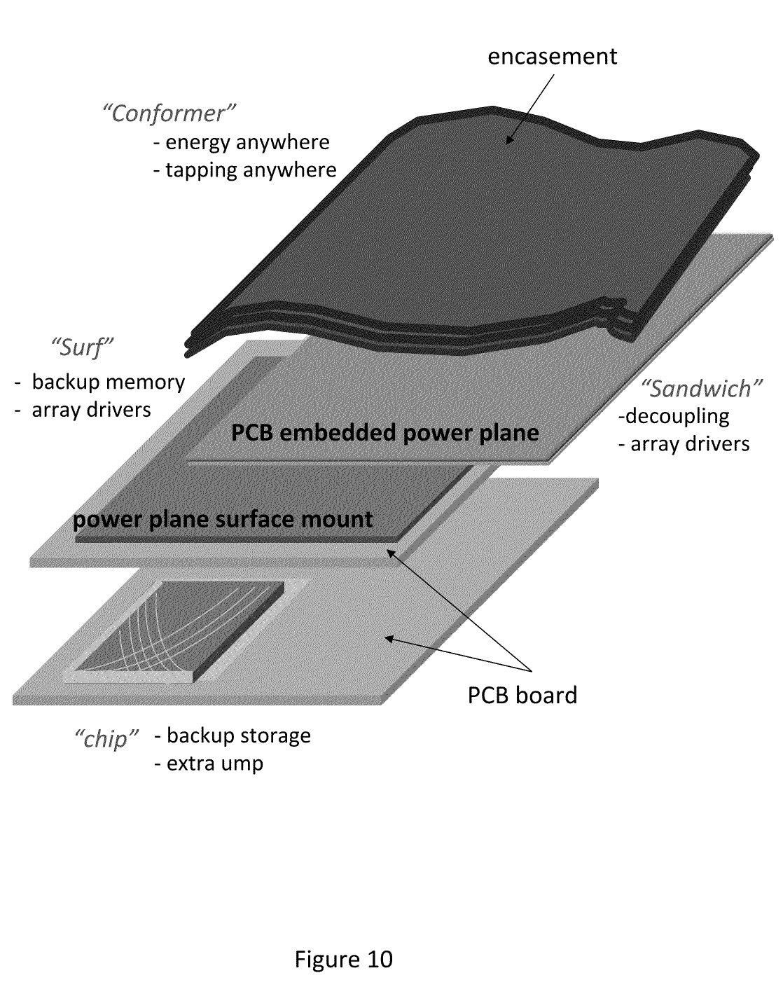

### Old Slide 5, New FIG. 10

As shown in FIG. 10, according to certain embodiments, the PowerWrapper™ technology (e.g., energy storage sheet) can be used in virtually any consumer electronics application. For example, it can be used in one or more of the following ways, alone or in combination in a particular consumer electronics application. It can be used as a “chip” on a PCB board, and used with backup storage and/or extra UMP. It can be used as a surface mounted power plane on a PCB board or flexible PCB, and used with backup memory and/or array drivers. It can be used as an embedded power plane on a PCB board or flexible PCB, and used for decoupling and with backup memory and/or array drivers. It can be used as a conformal power plane on a flexible PCB, possibly with an encasement, and used to provide energy anywhere with tapping anywhere. Certain embodiments may include a process of manufacture using an Aluminum foil for a preformed conductor, high power chip that may be surface or overlay mounted.

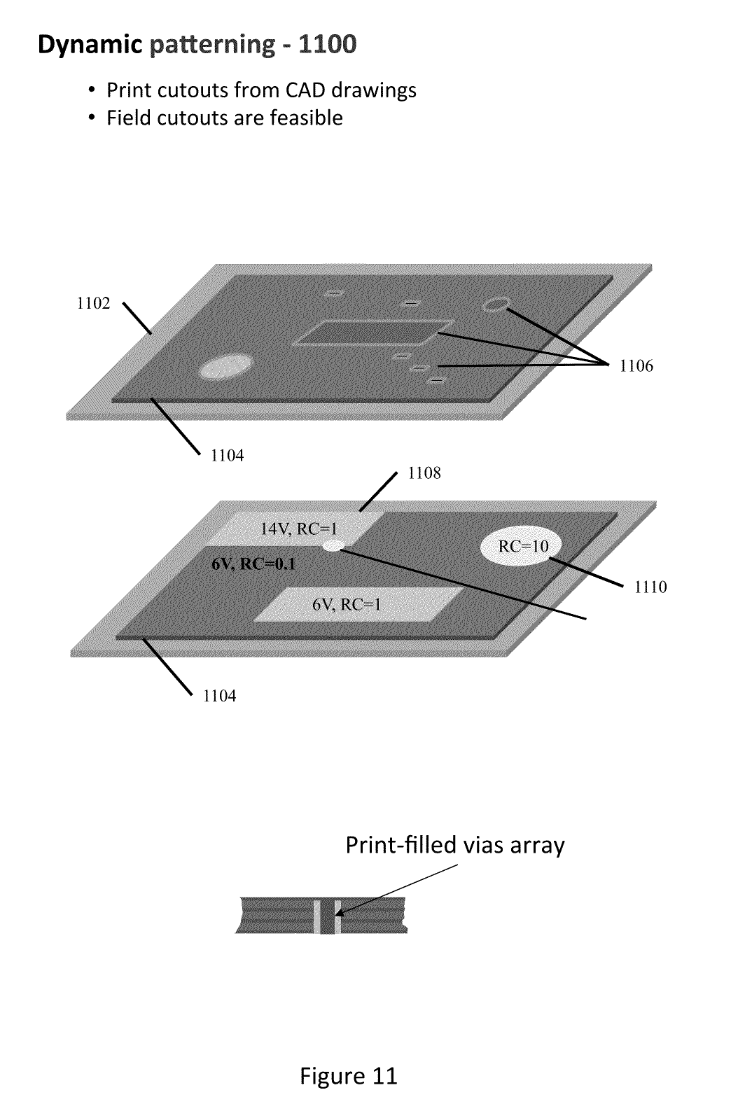

### Old Slide 6, New FIG. 11

As shown in FIG. 11, elements illustrated may be used in flexible PCB application with electronic components. In certain embodiments, the internal device could have ribbing or be replaced with a classical board material.

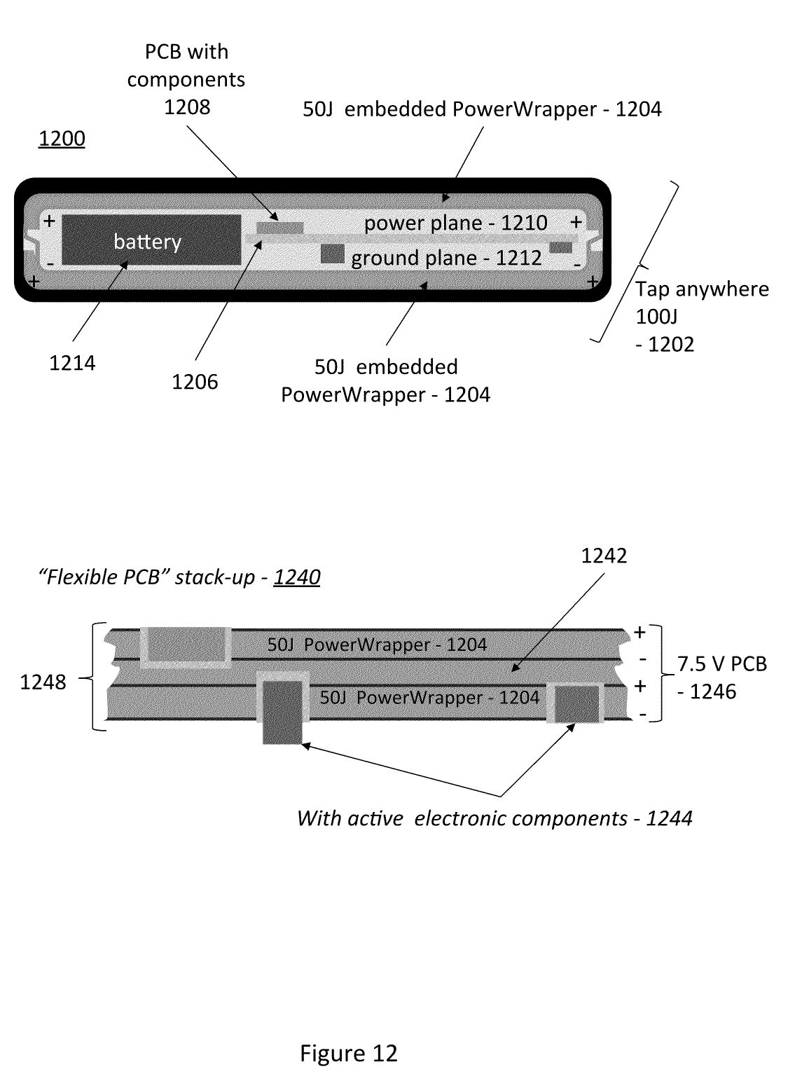

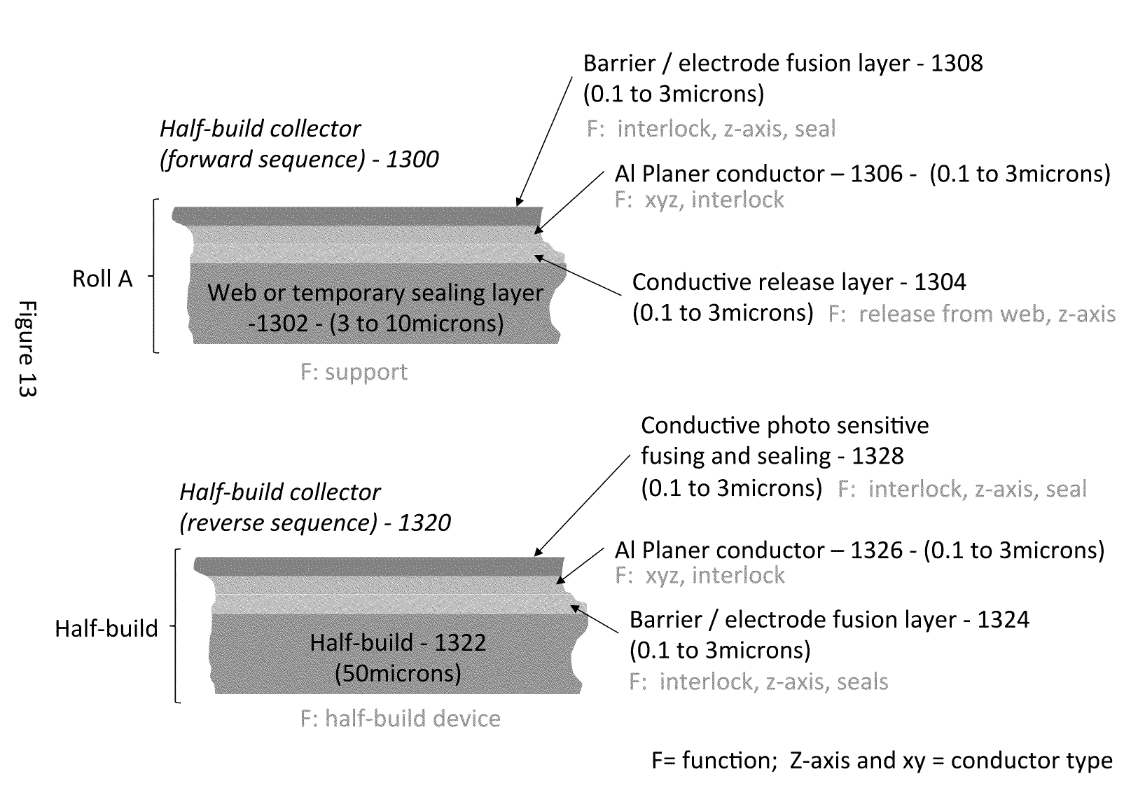

### Old Slide 7, New FIG. 12

As shown in FIG. 12, according to certain embodiments, technologies disclosed herein may be used as integrated large area power planes, including but not limited to e-tape and flexible PCB application. Certain processes and application where power is integrated into the plastic encasement of the consumer electronics may be used. Certain elements illustrated may be used in flexible PCB application with electronic components. In certain embodiments, the internal device could have ribbing or be replaced with a classical board material

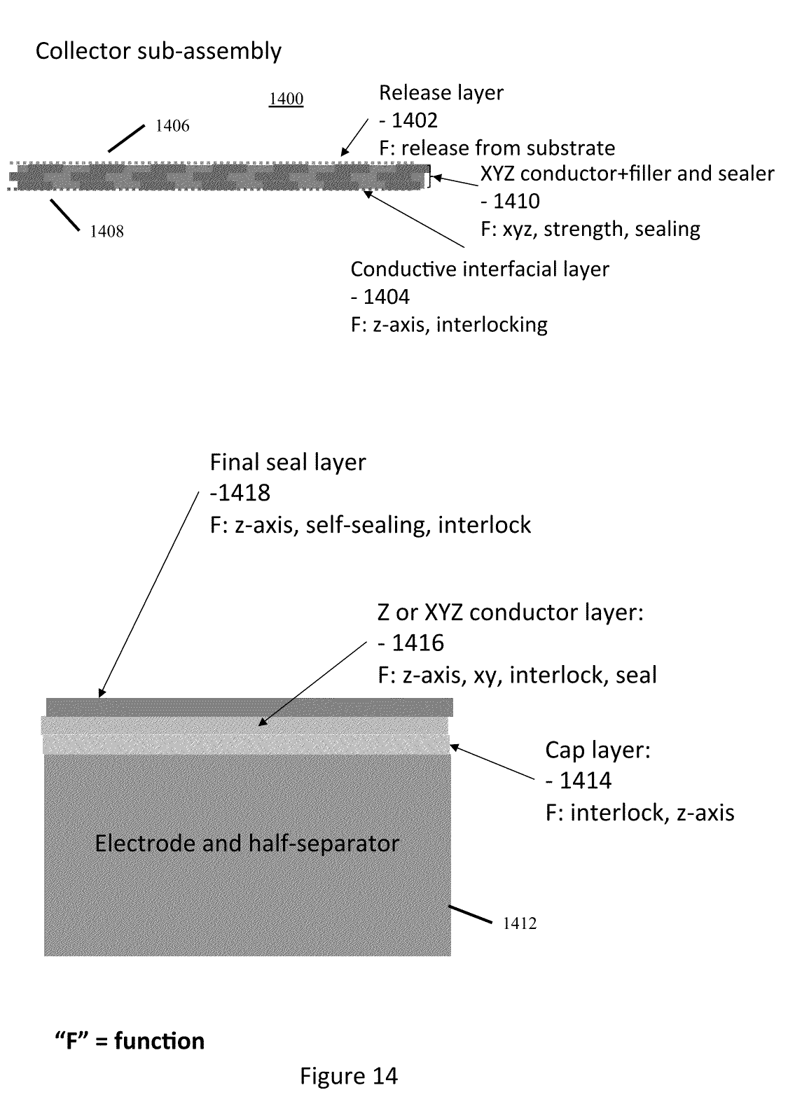

### Old Slide 10, New FIG. 14

As shown in FIG. 14, according to certain embodiments, it may be possible to print form three function layers, or a composite of functions with one or two layers, as part of the collector design.

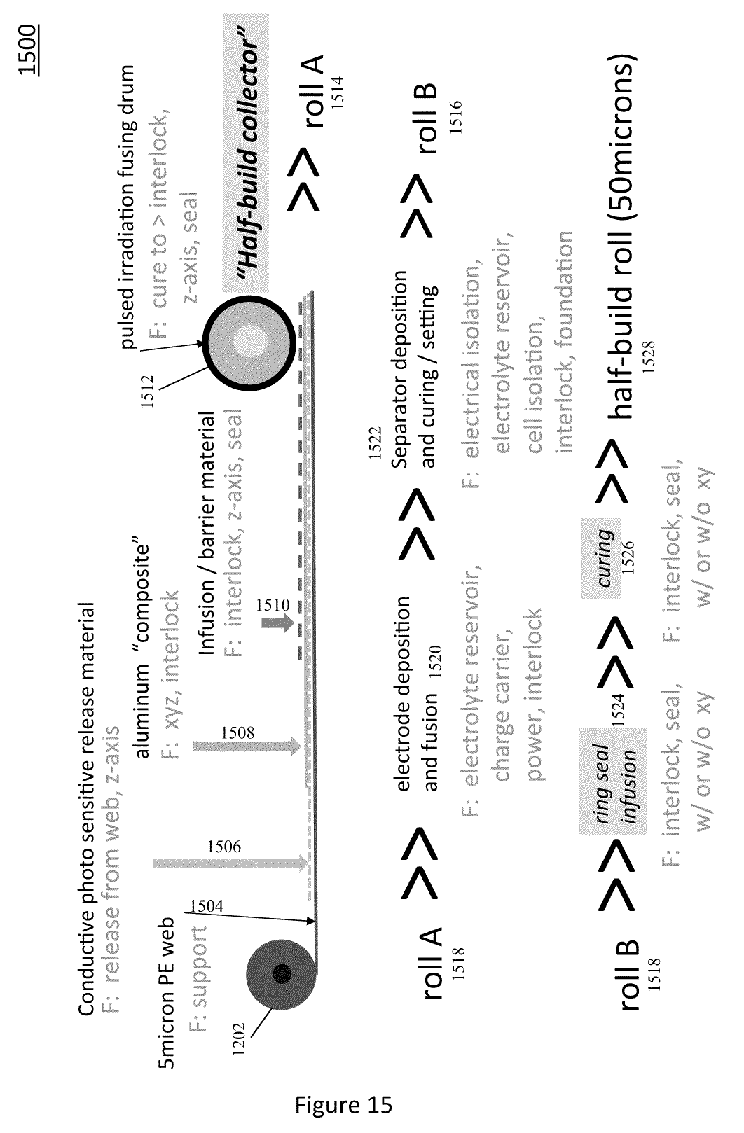

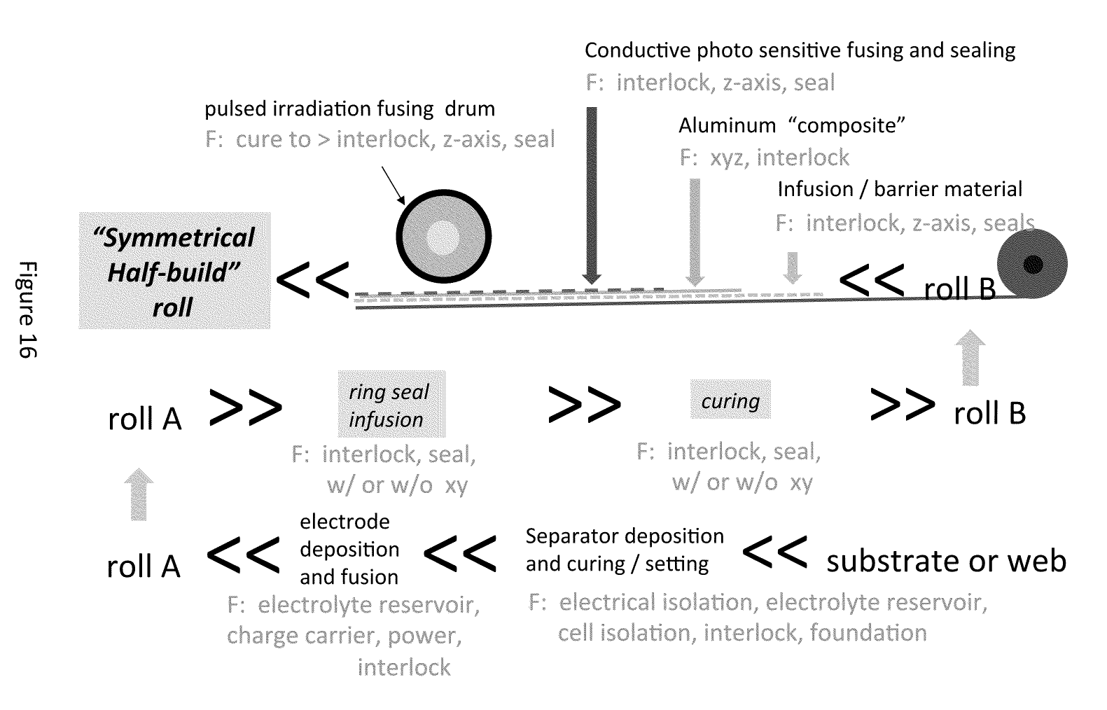

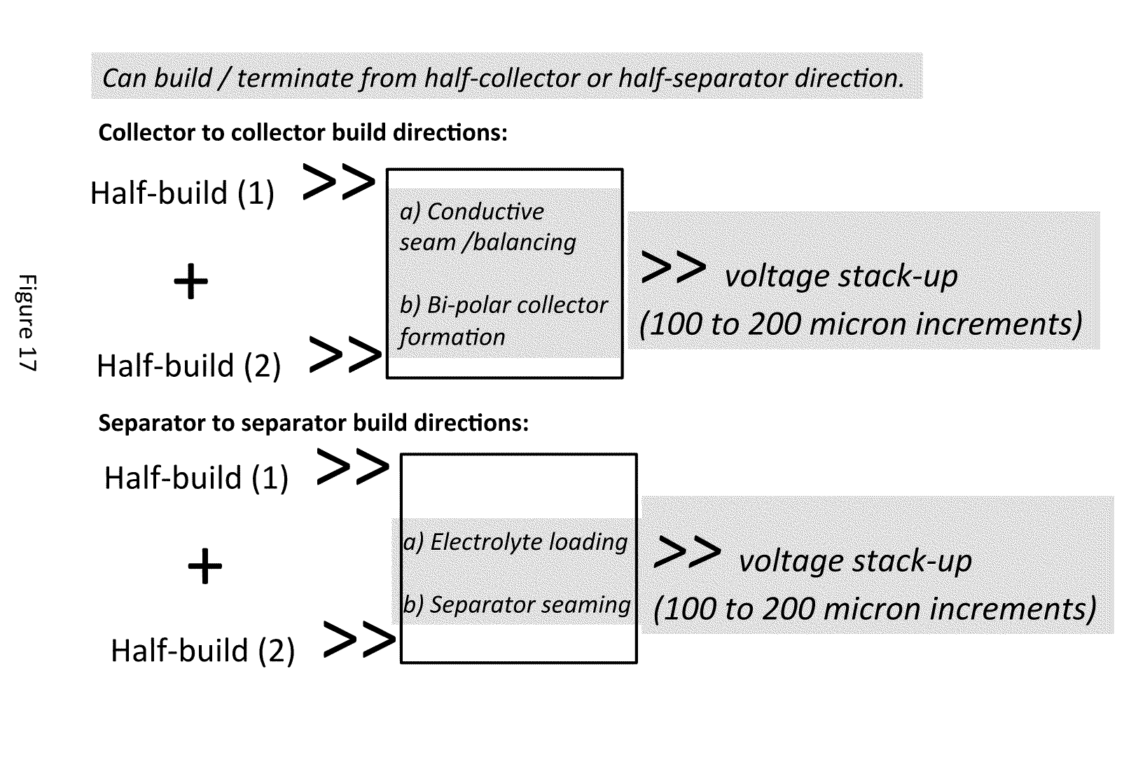

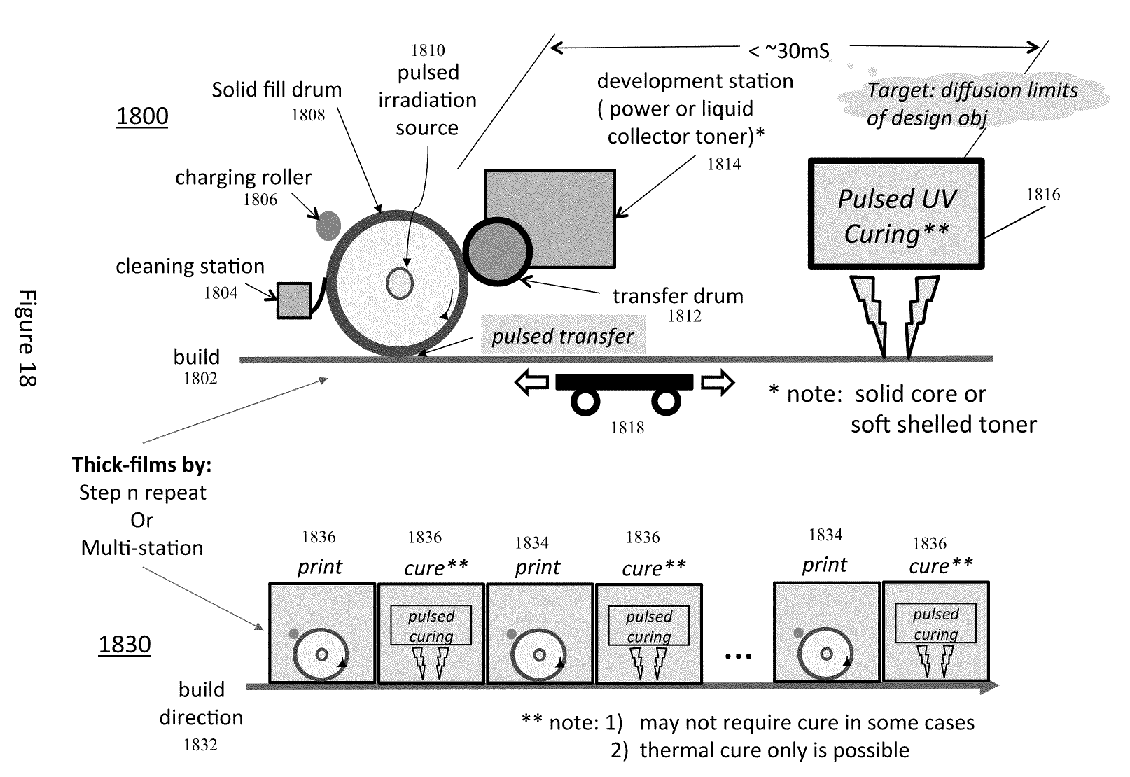

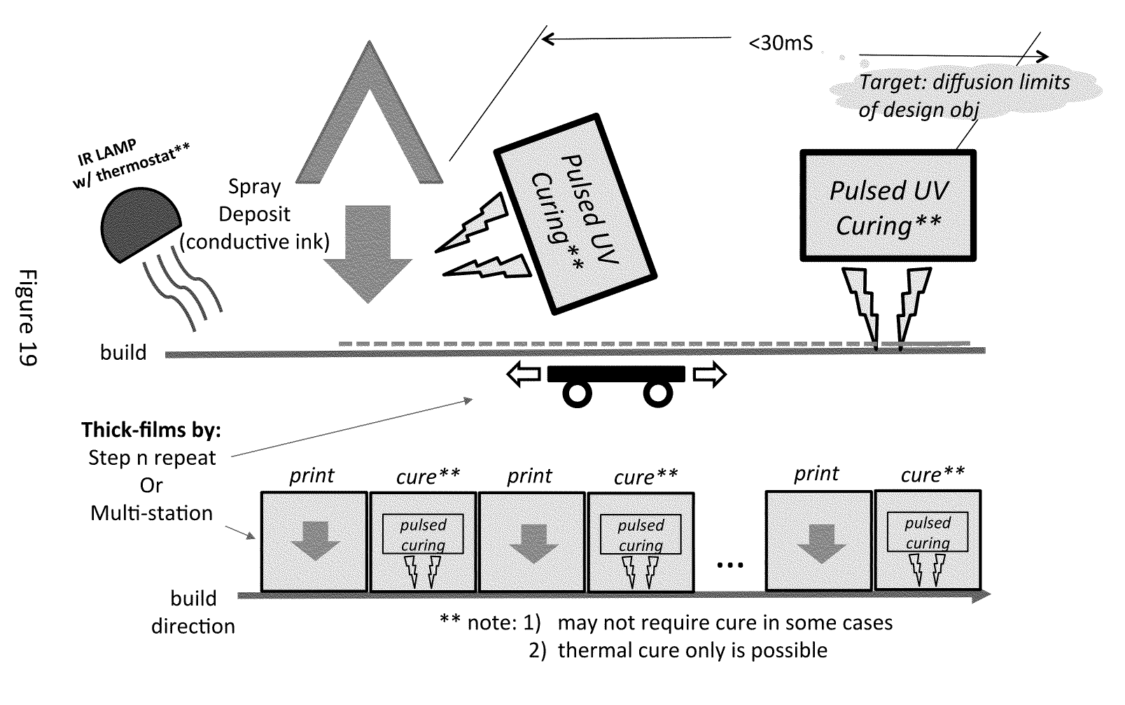

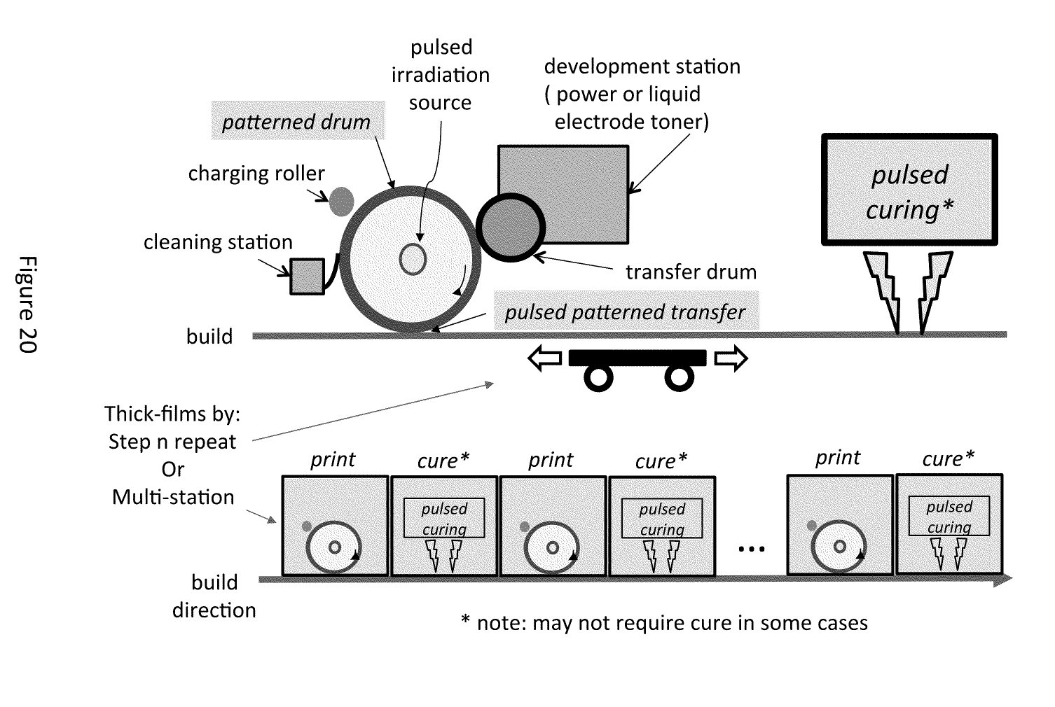

### Old Slide 12, New FIG. 15

FIG. 15 illustrates an exemplary PowerWrapper™ processing line according to certain embodiments.

### Old Slide 13, New FIG. 16

FIG. 16 illustrates an exemplary PowerWrapper™ reverse processing line according to certain embodiments.

### Old Slide 14, New FIG. 17

FIG. 17 illustrates exemplary collector and separator build-ups according to certain embodiments.

### Old Slide 16, New FIG. 18

FIG. 18 illustrates an exemplary current collector free-form fabrication process according to certain embodiments.

### Old Slide 17, New FIG. 19

FIG. 19 illustrates an exemplary current collector free-form fabrication process according to certain embodiments.

### Old Slide 18, New FIG. 20

FIG. 20 illustrates an exemplary electrode free-form fabrication process according to certain embodiments.

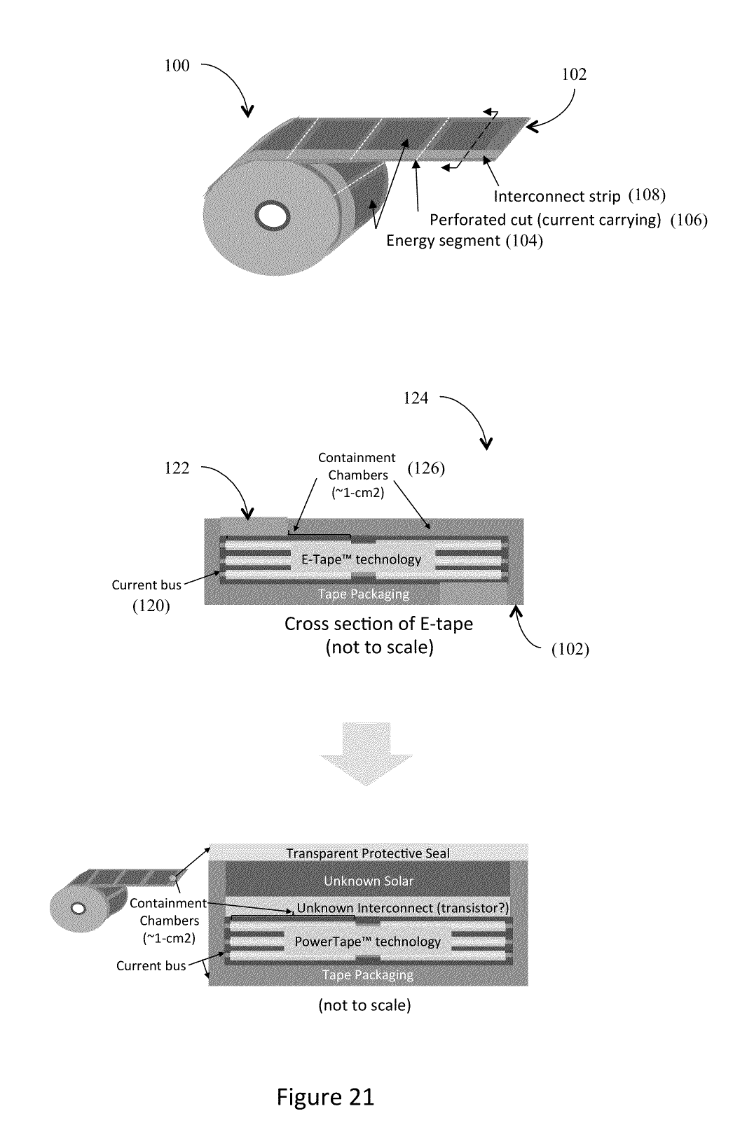

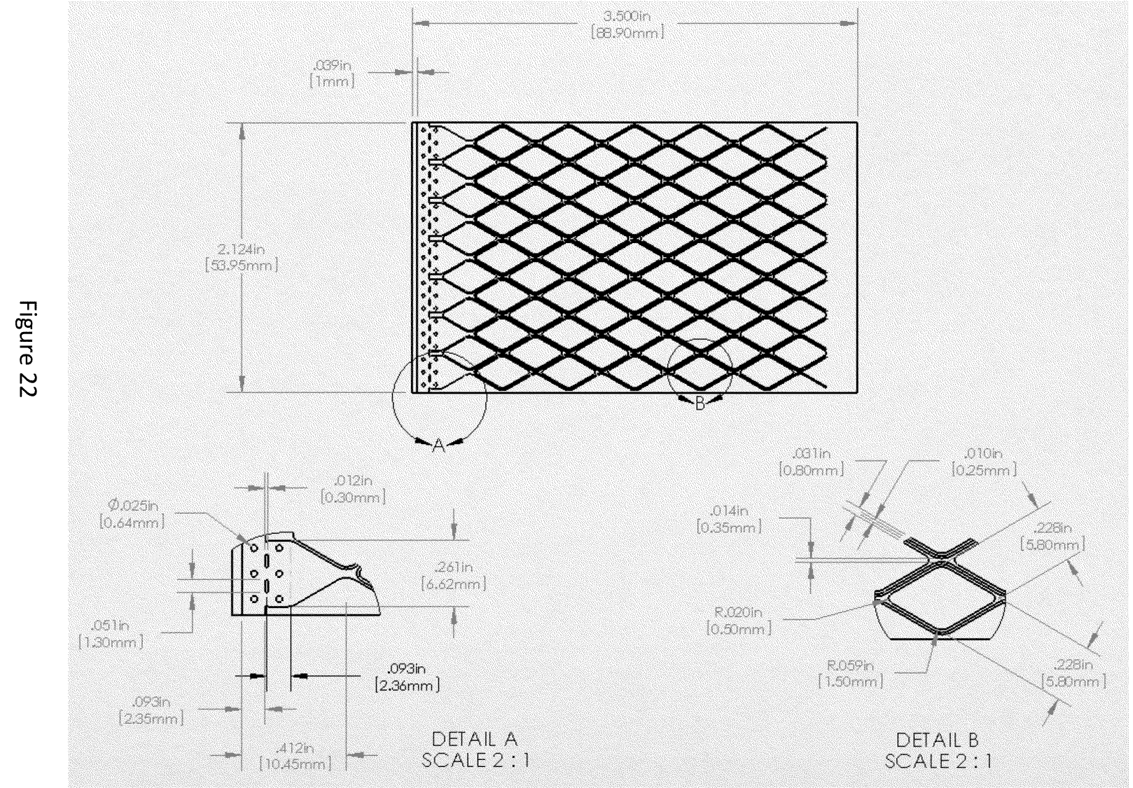

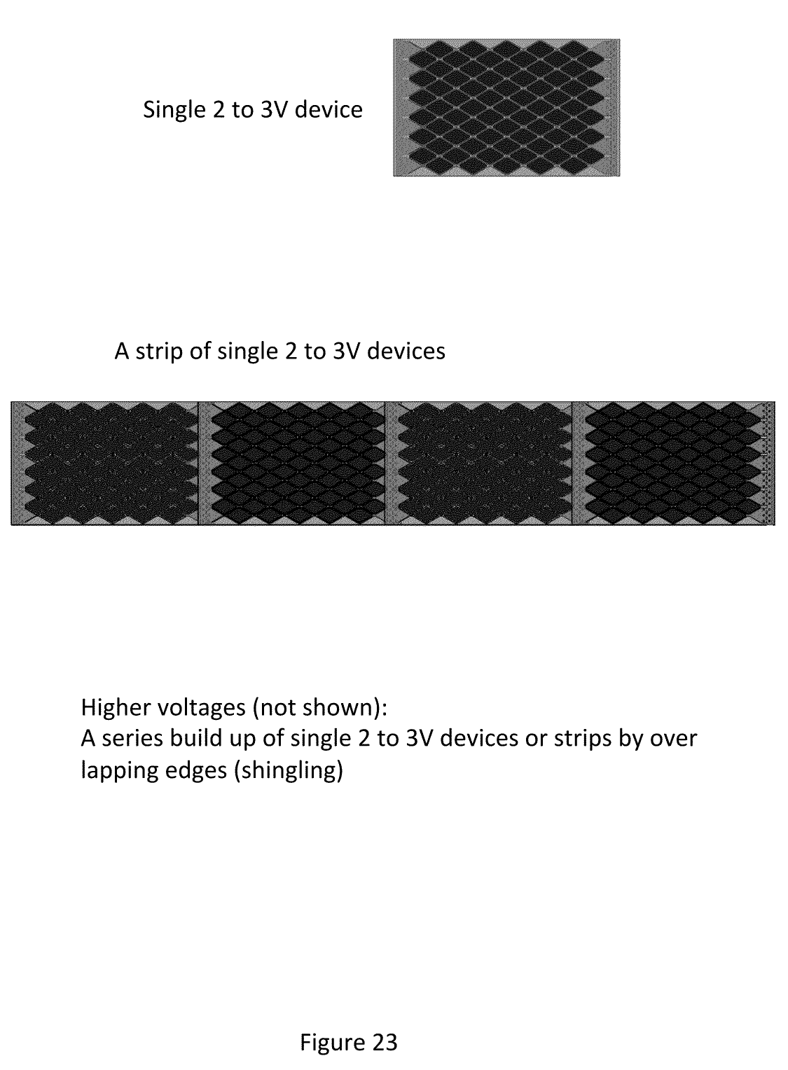

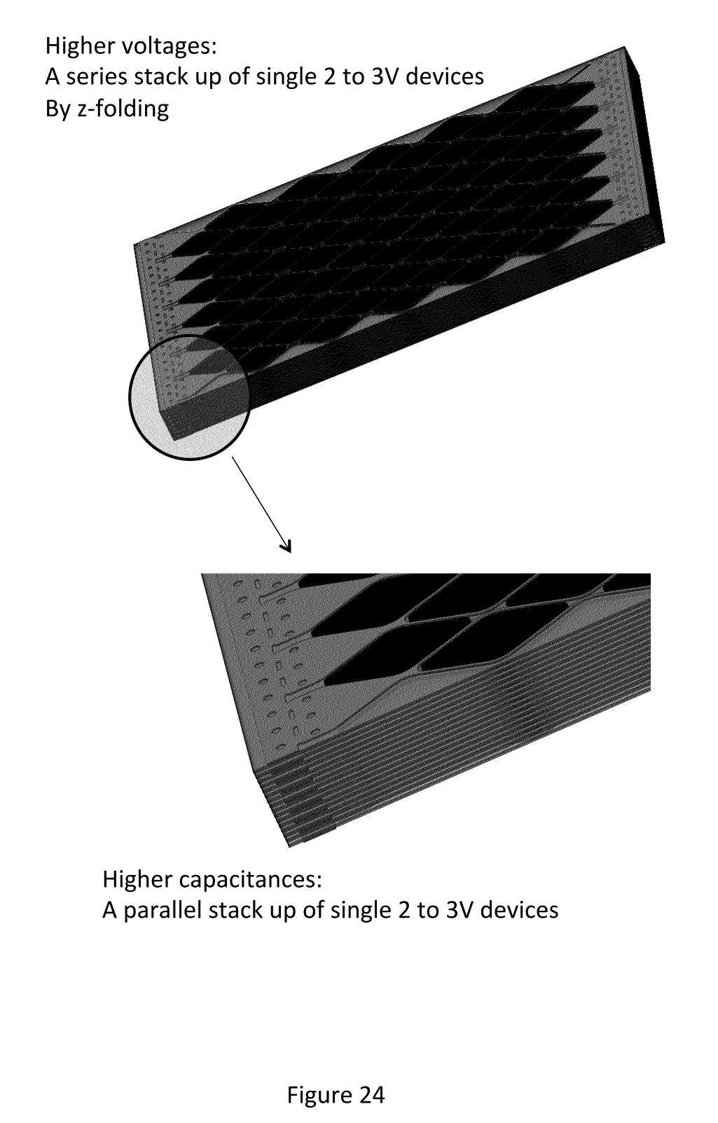

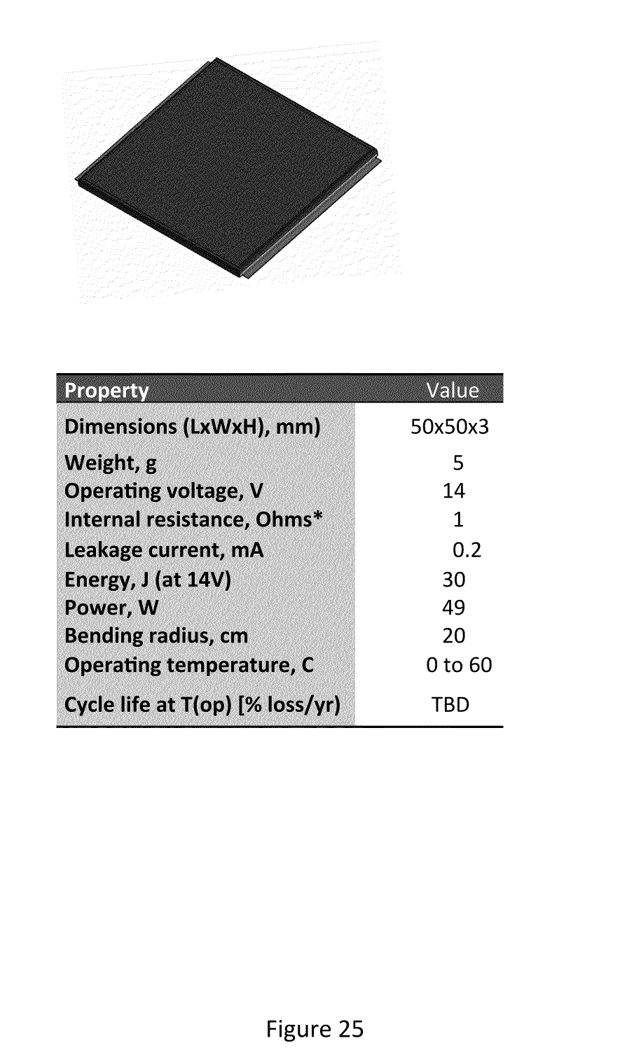

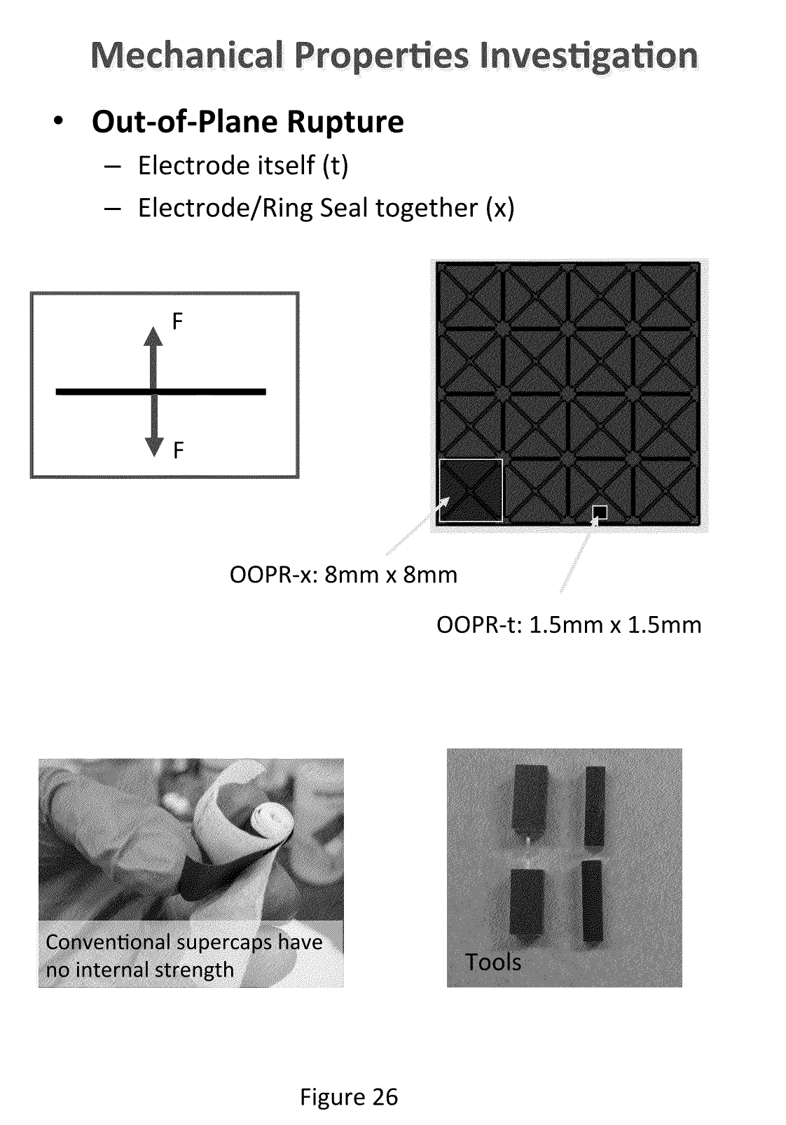

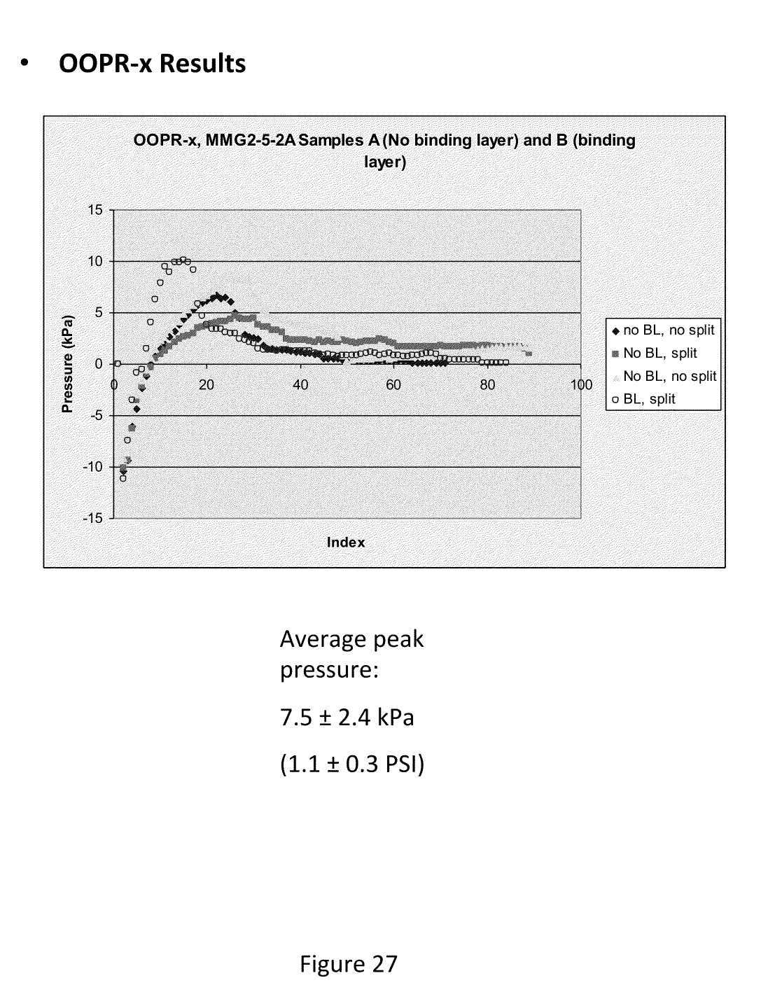

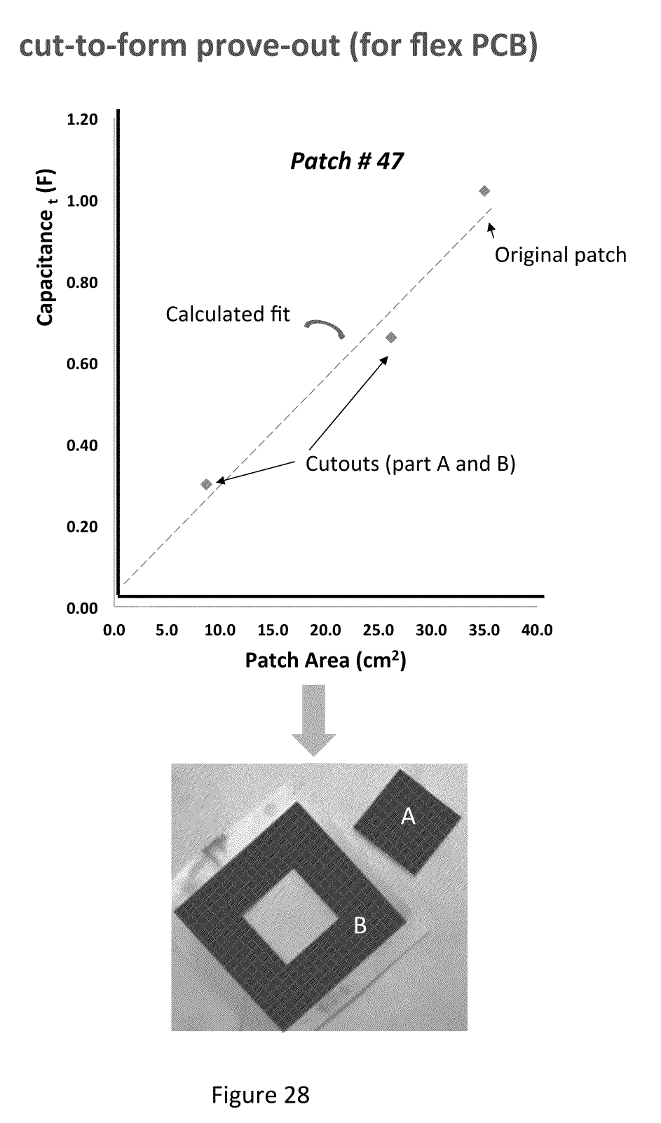

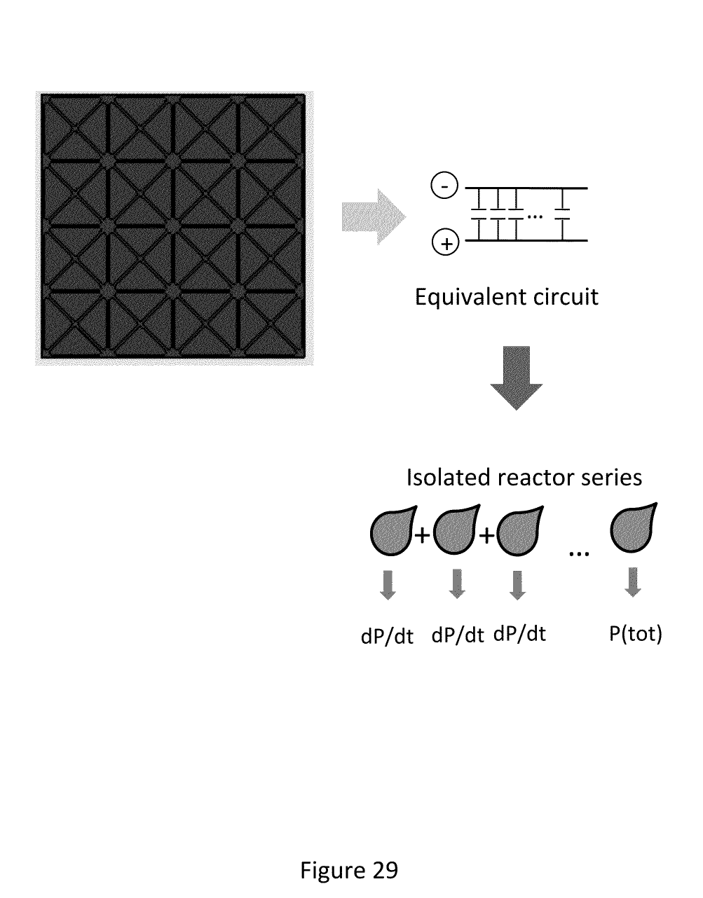

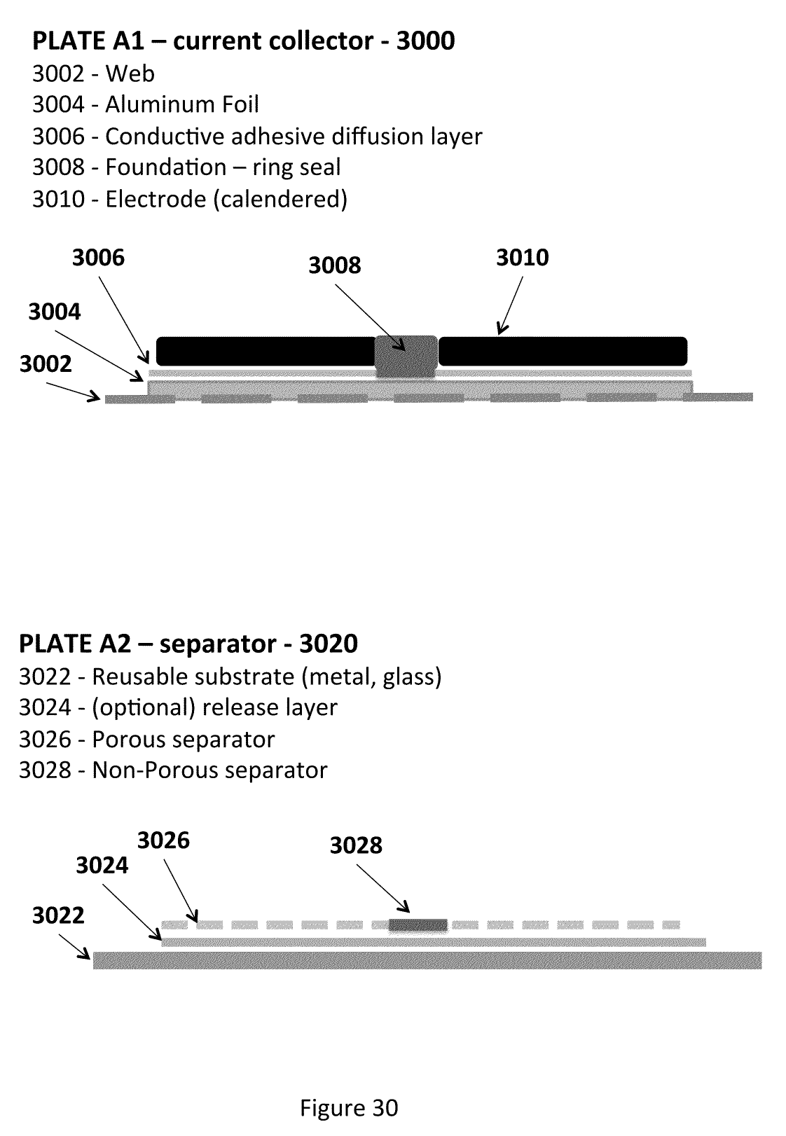

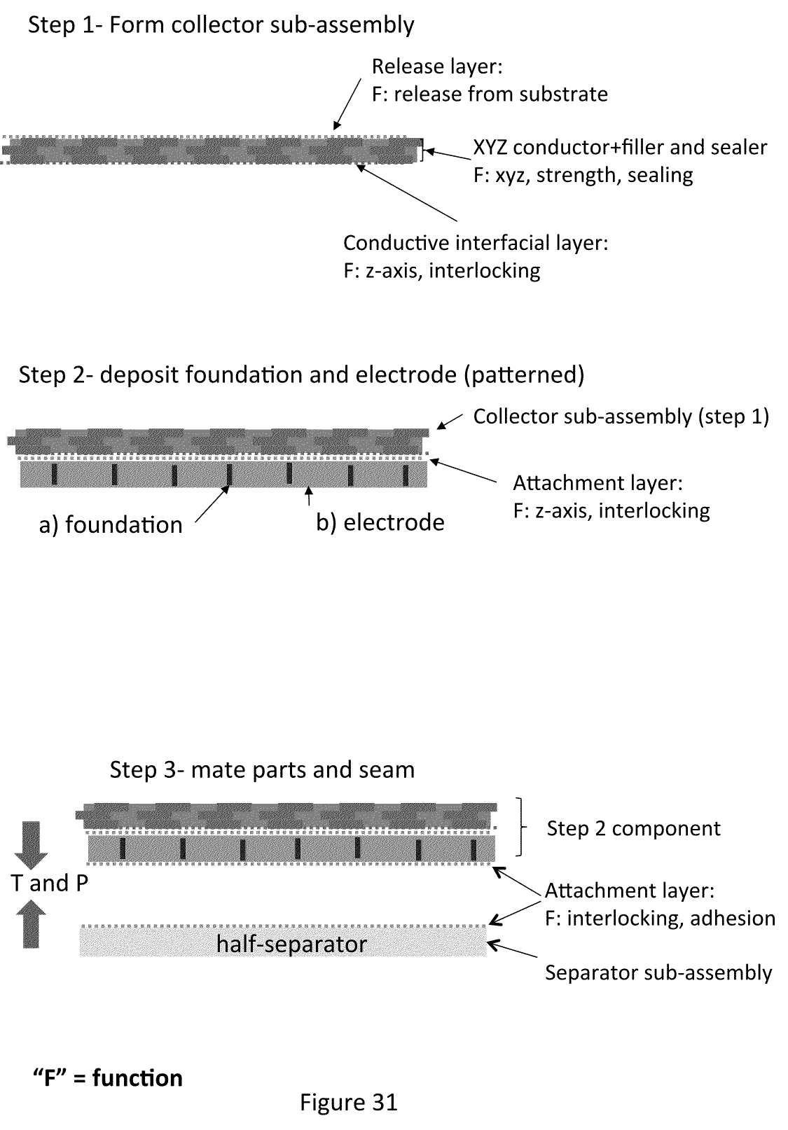

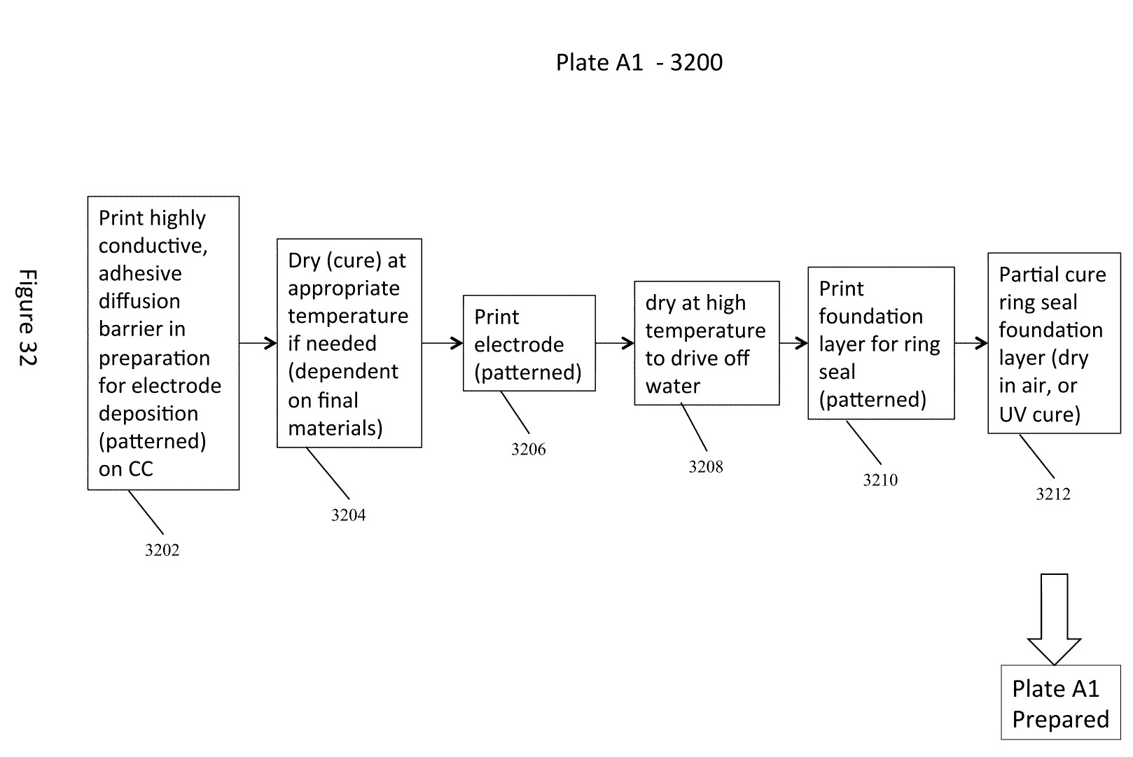

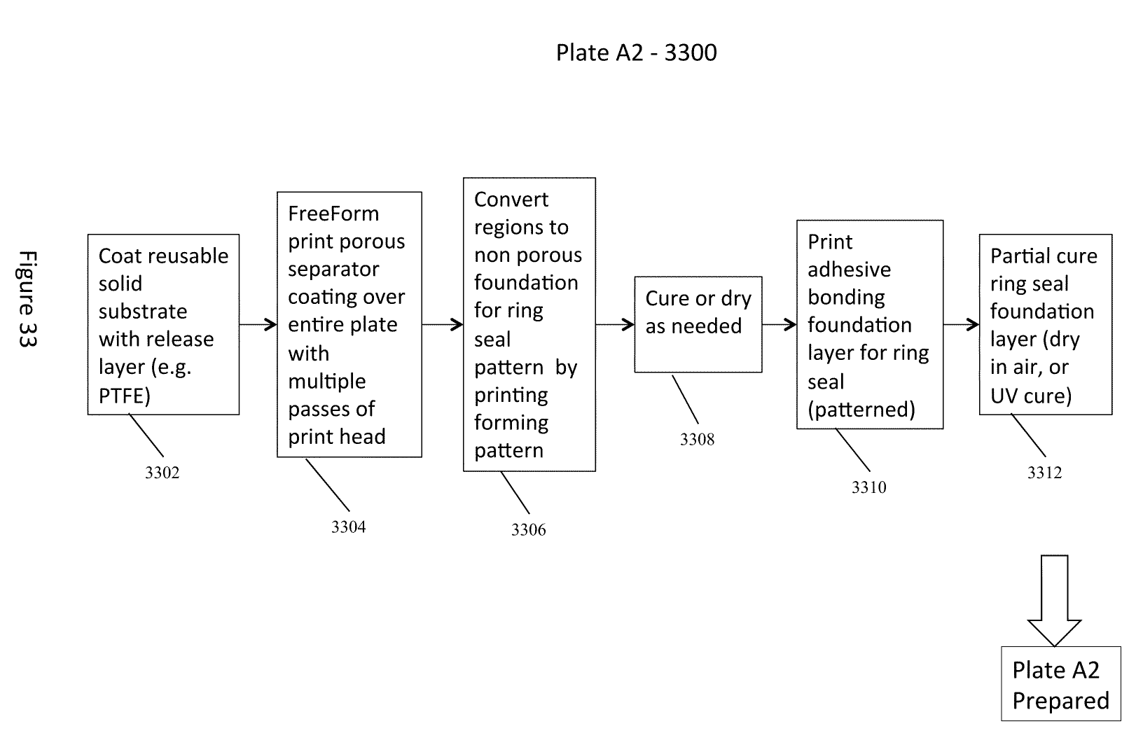

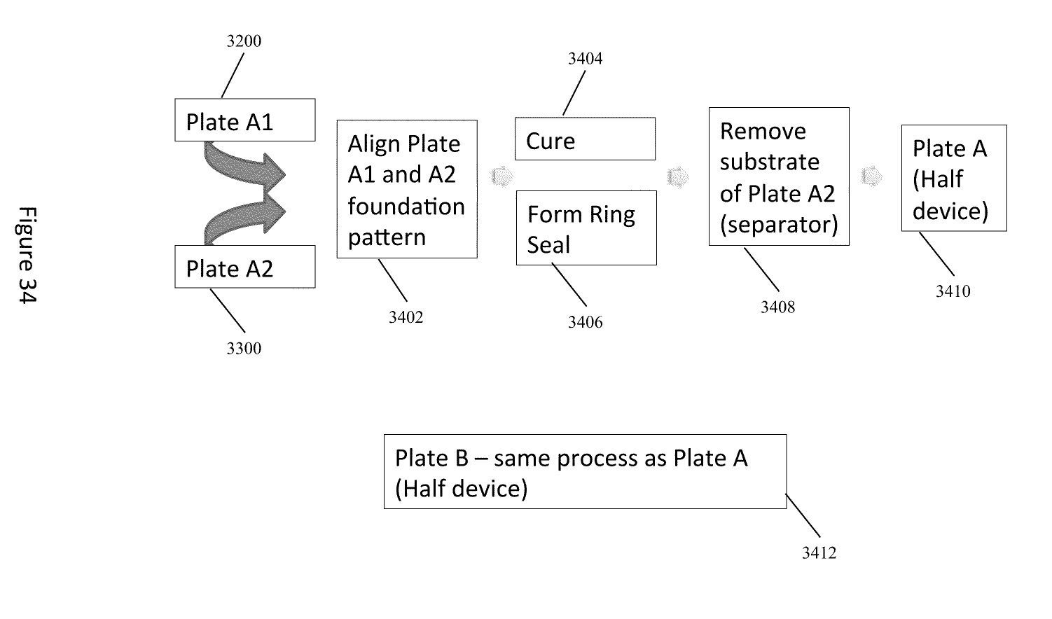

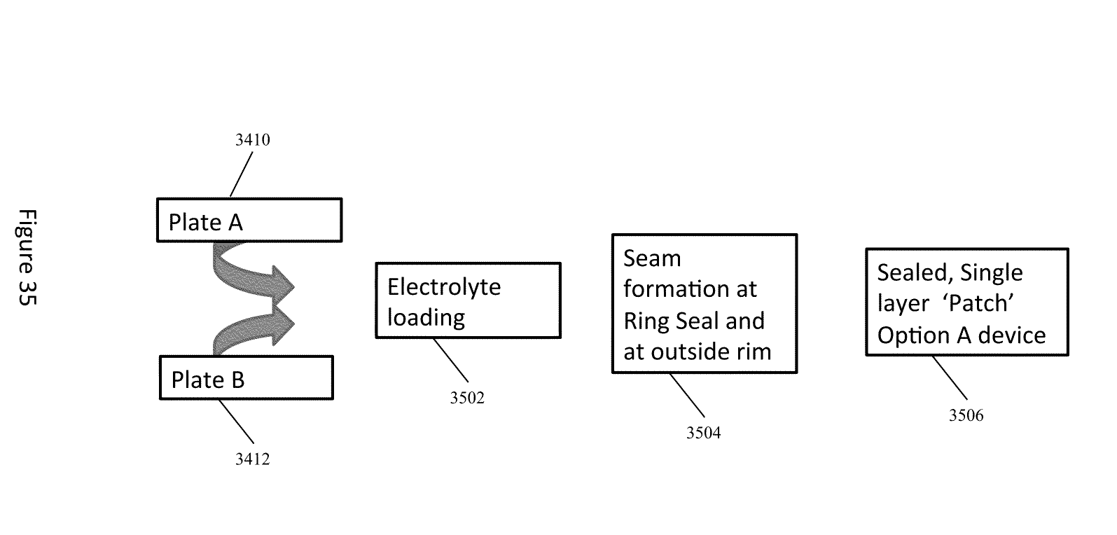

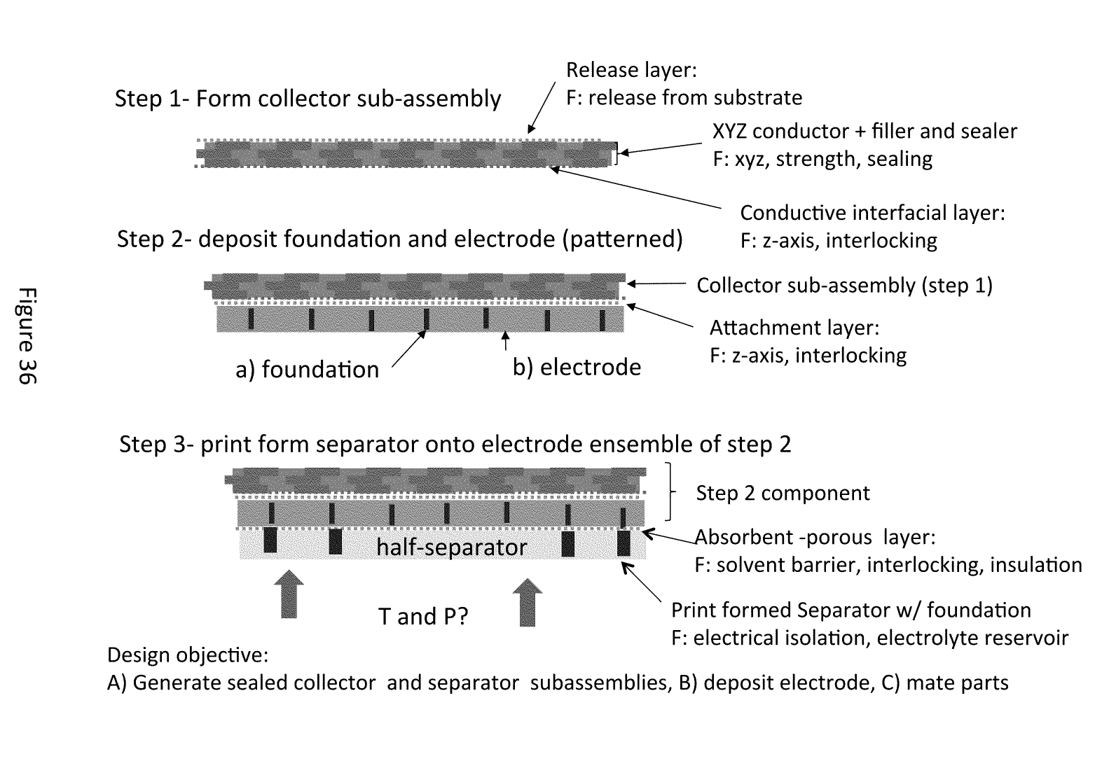

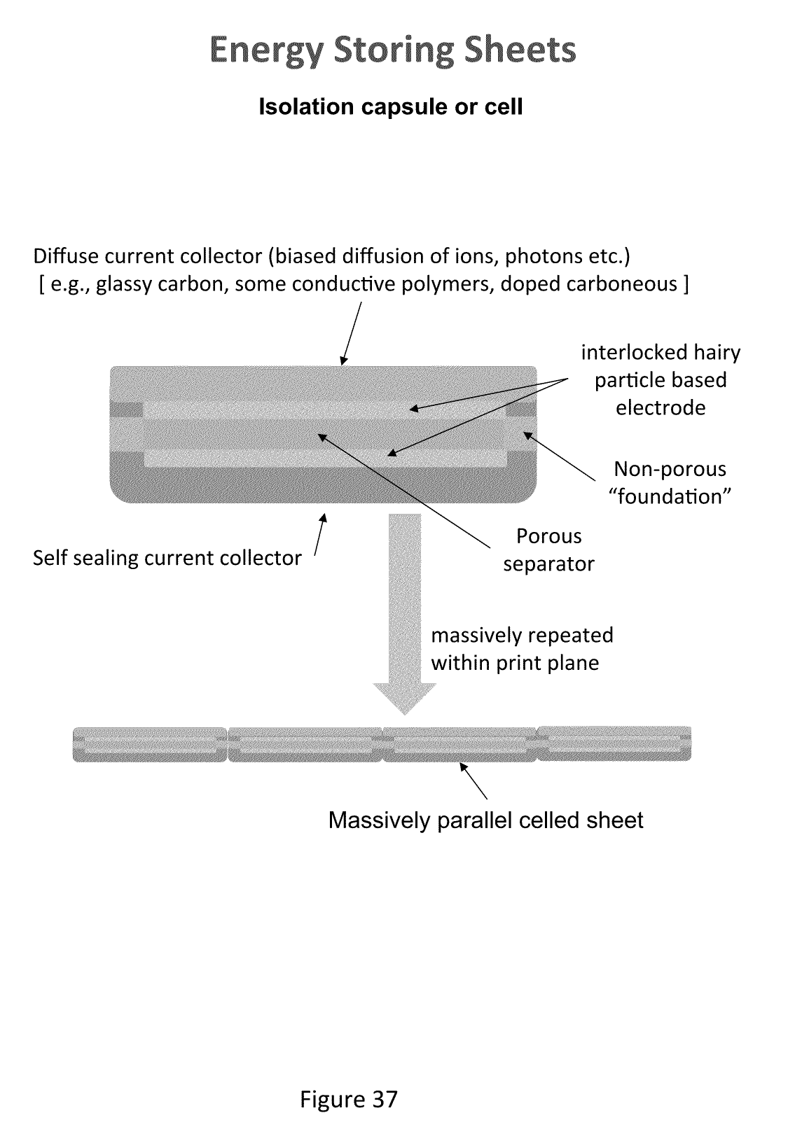

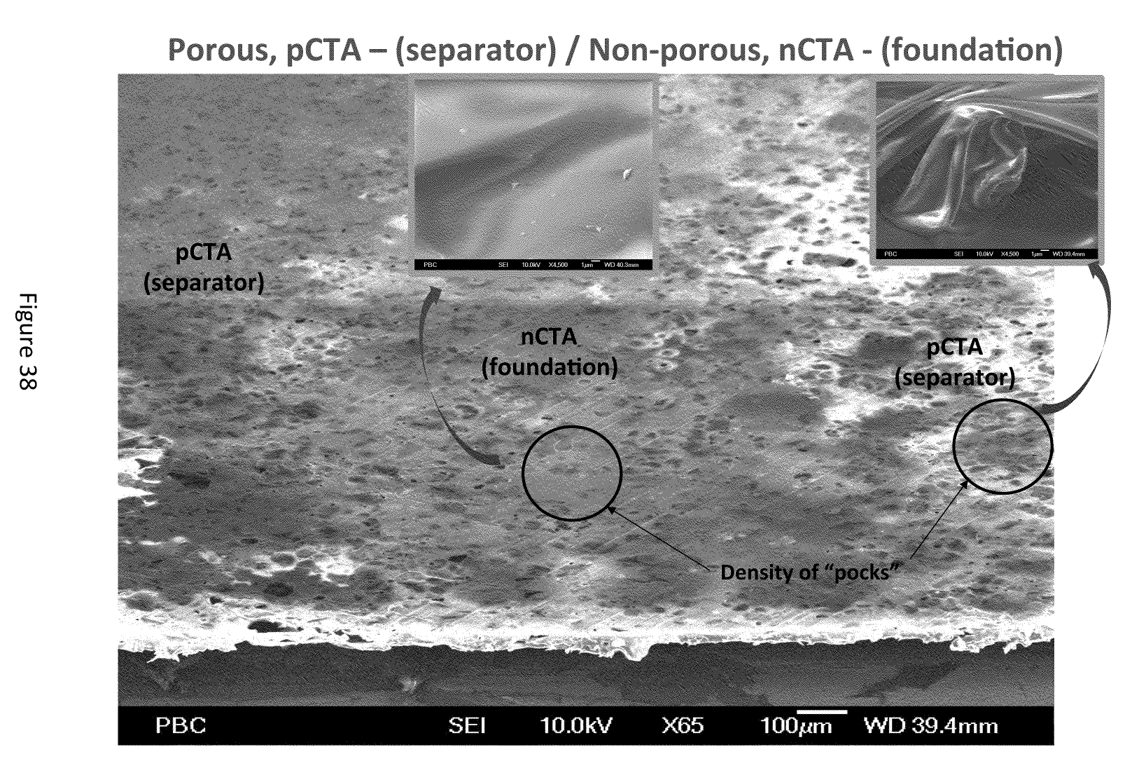

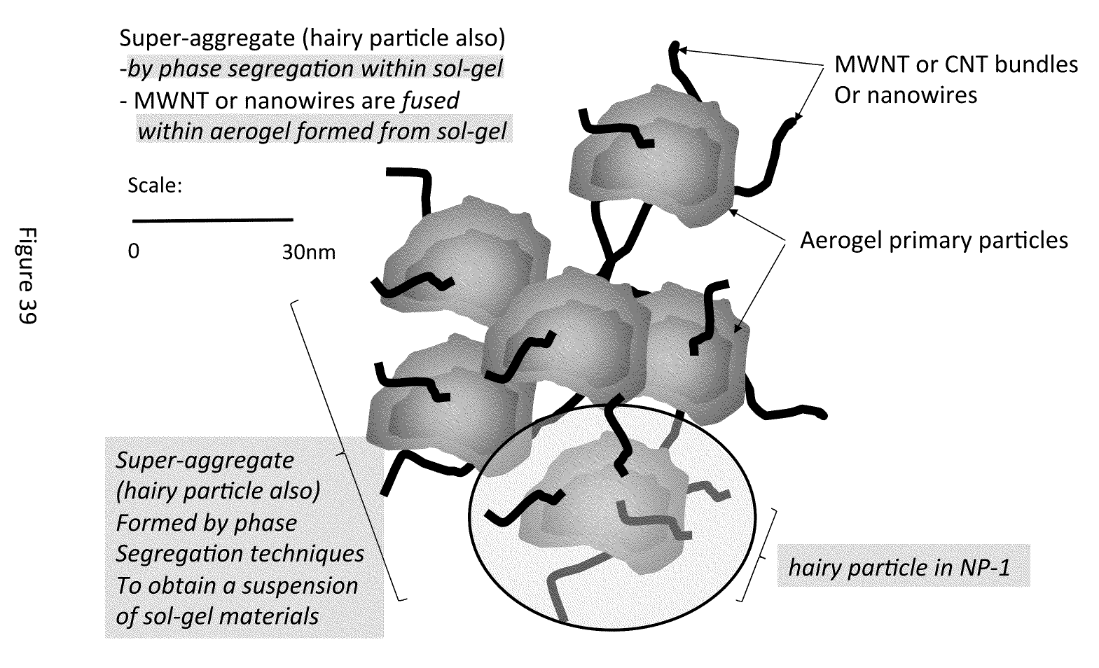

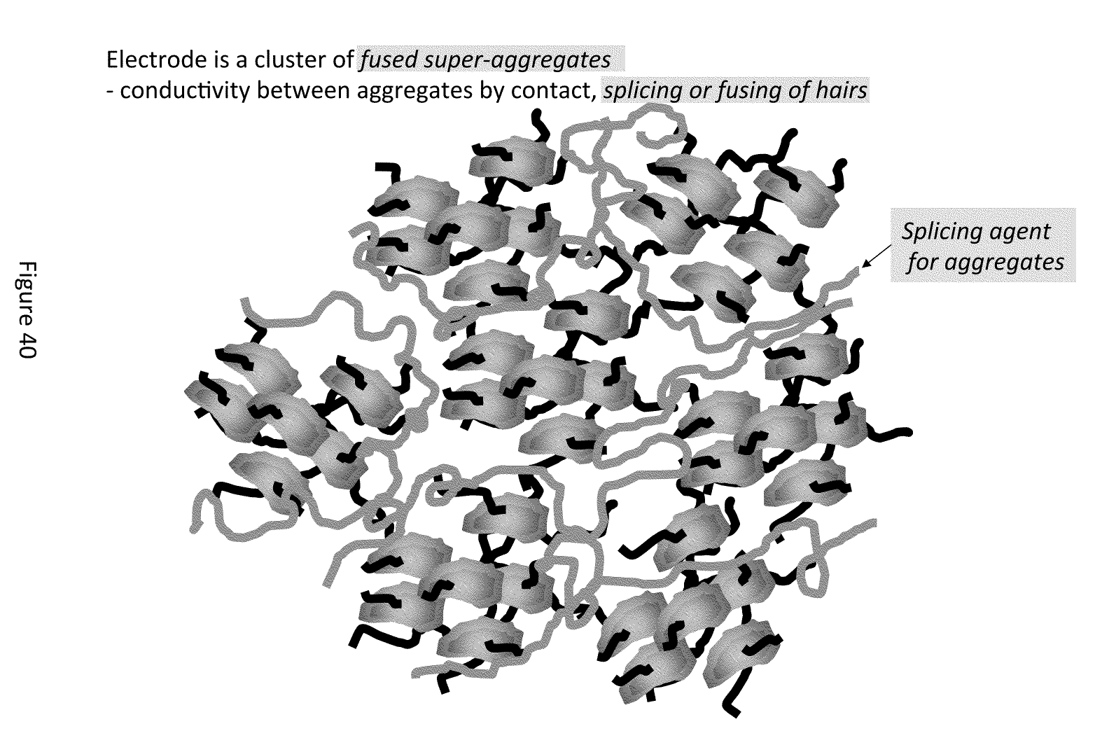

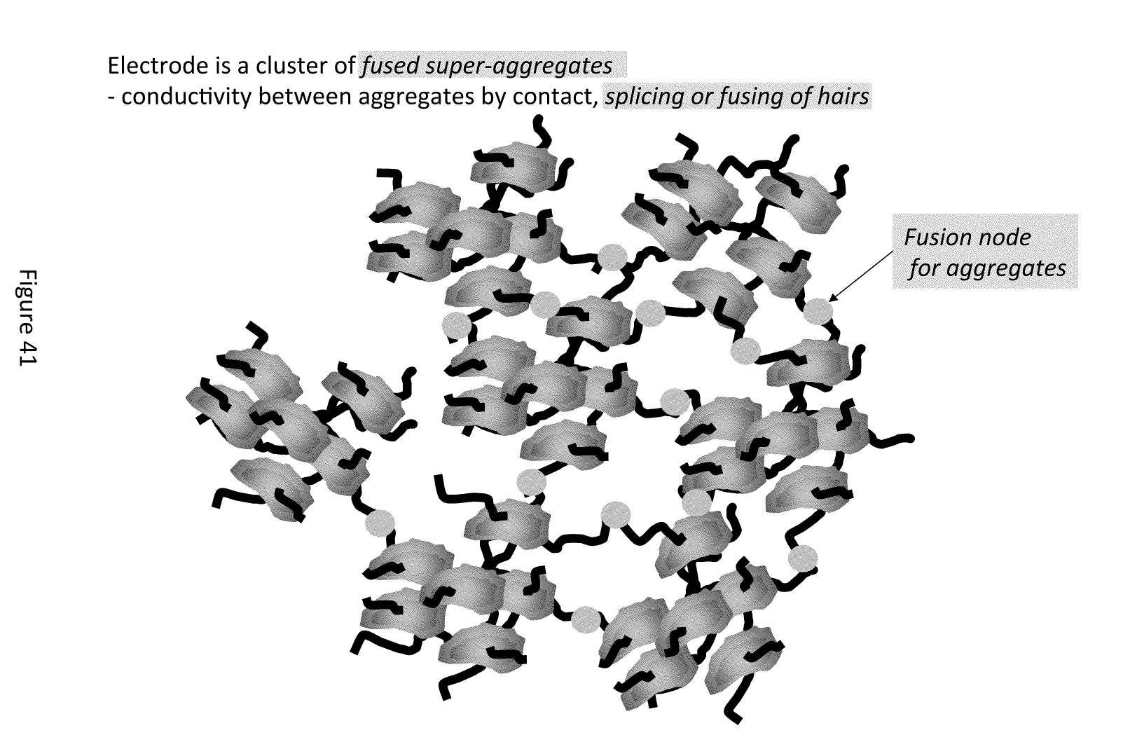

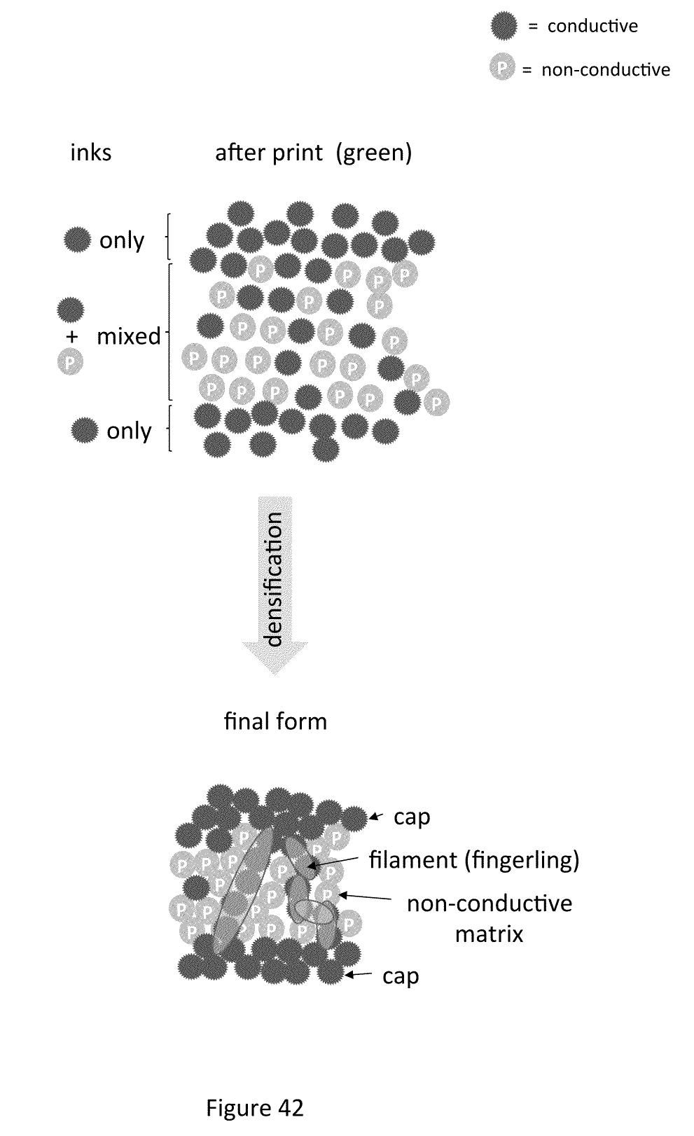

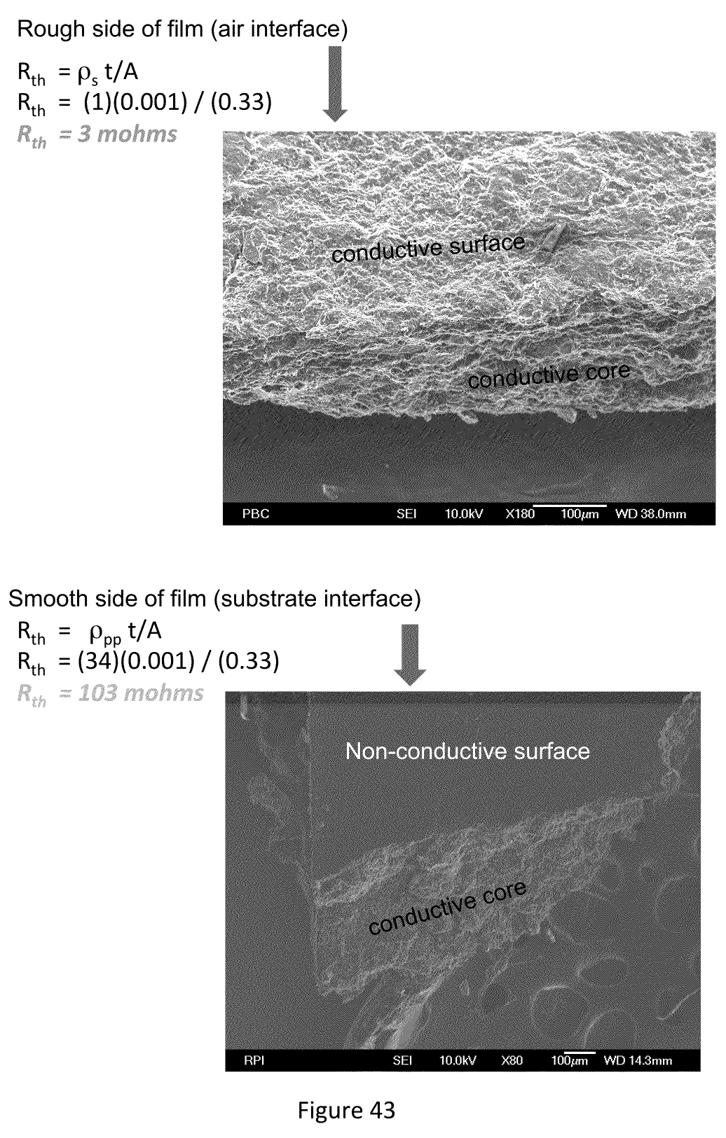

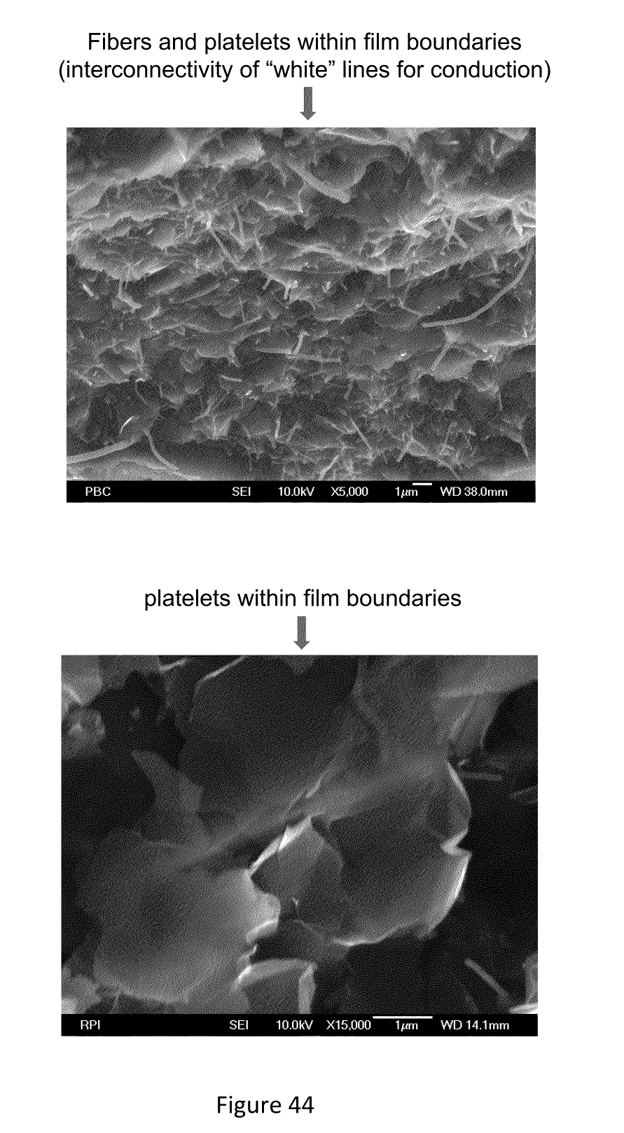

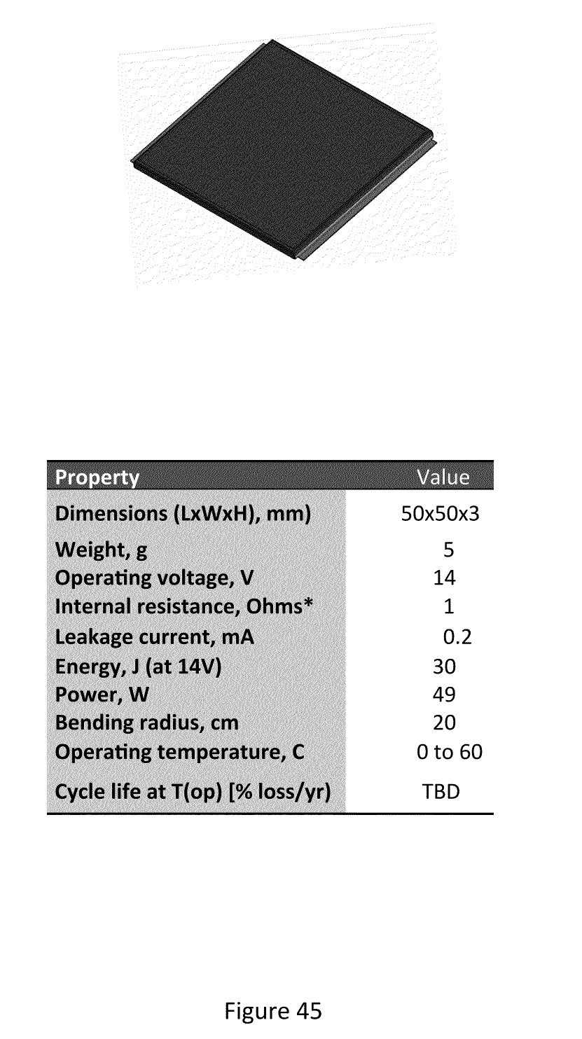

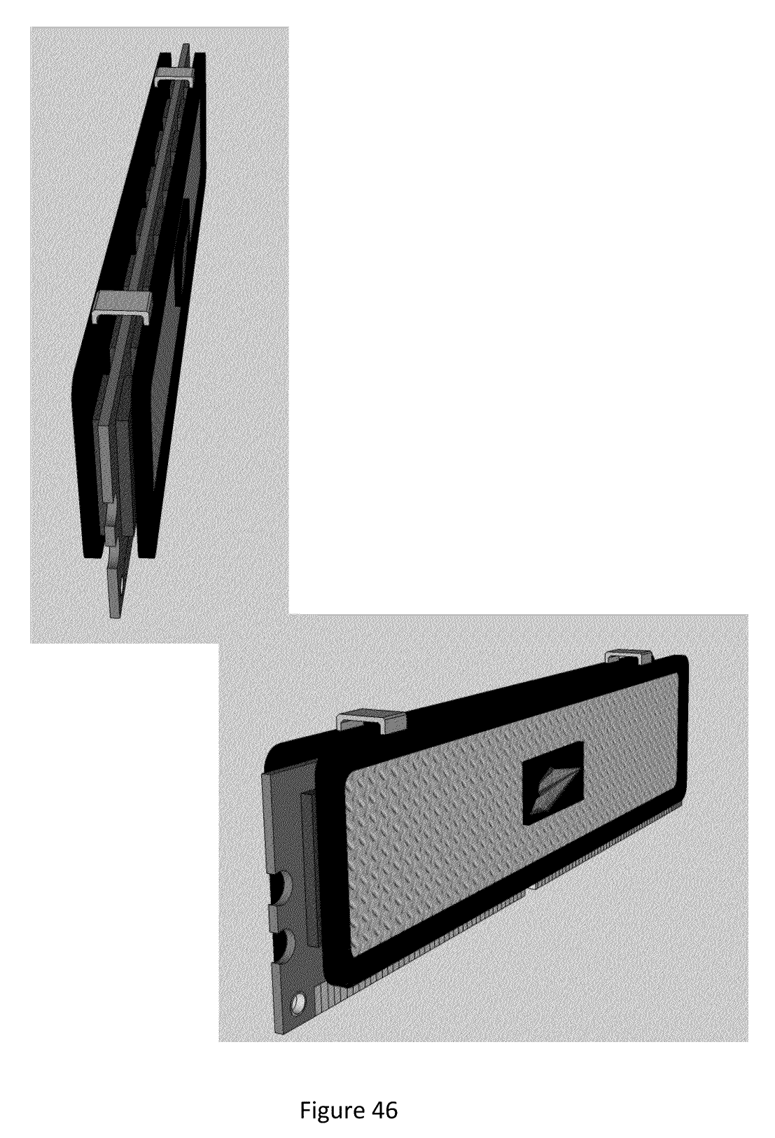

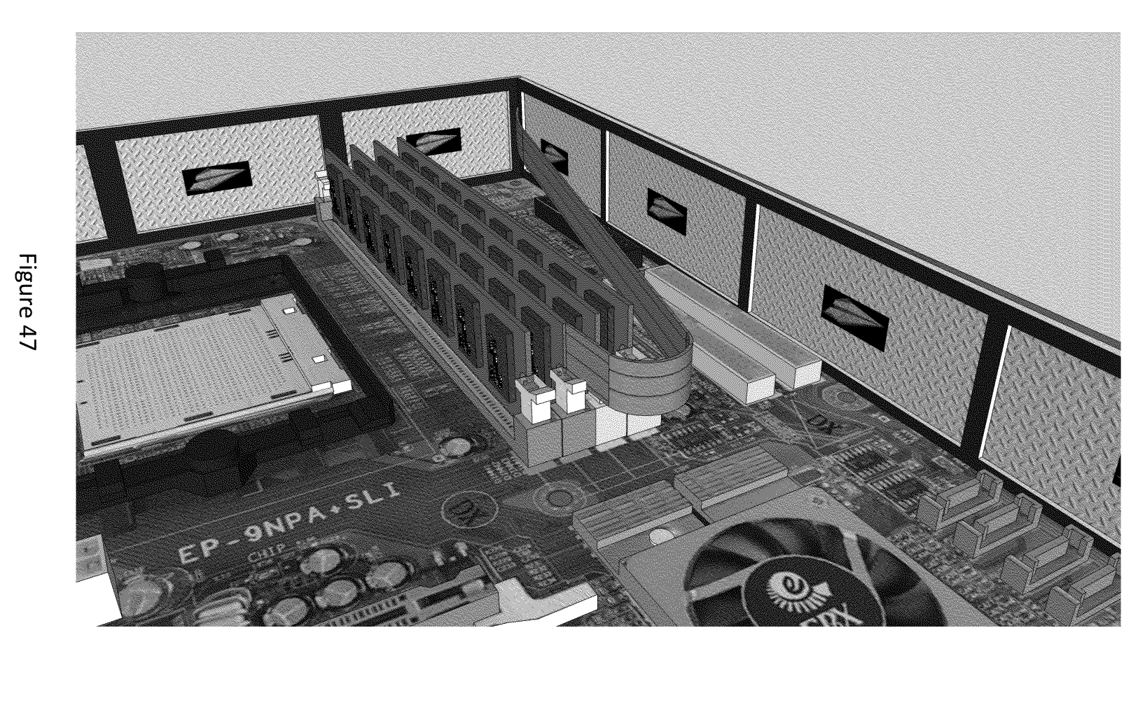

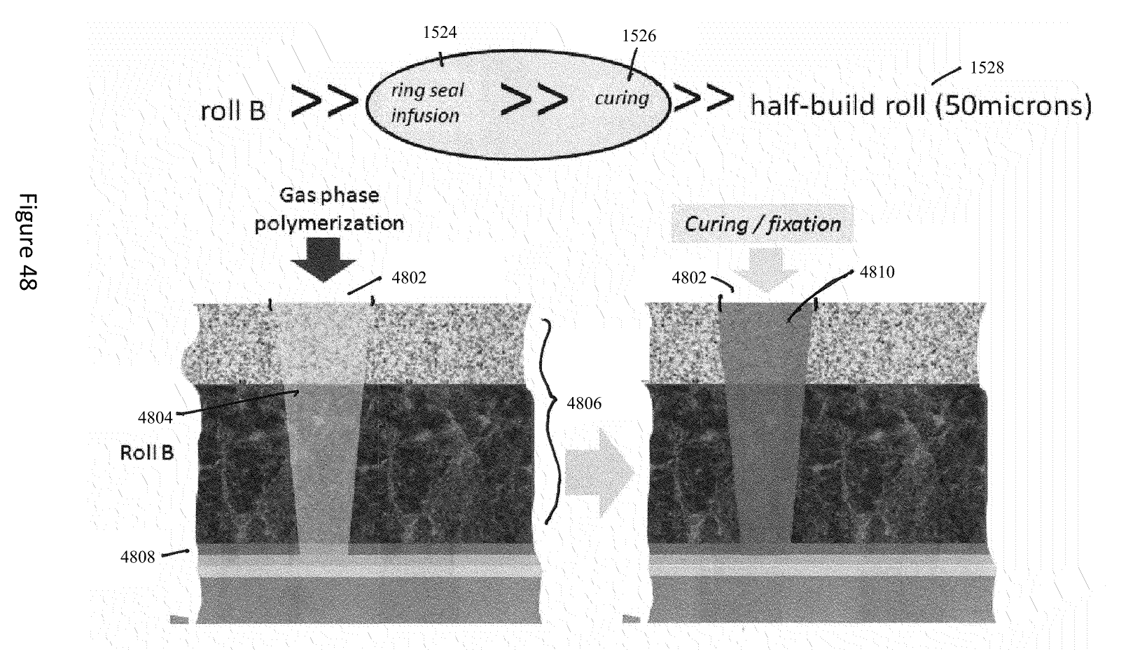

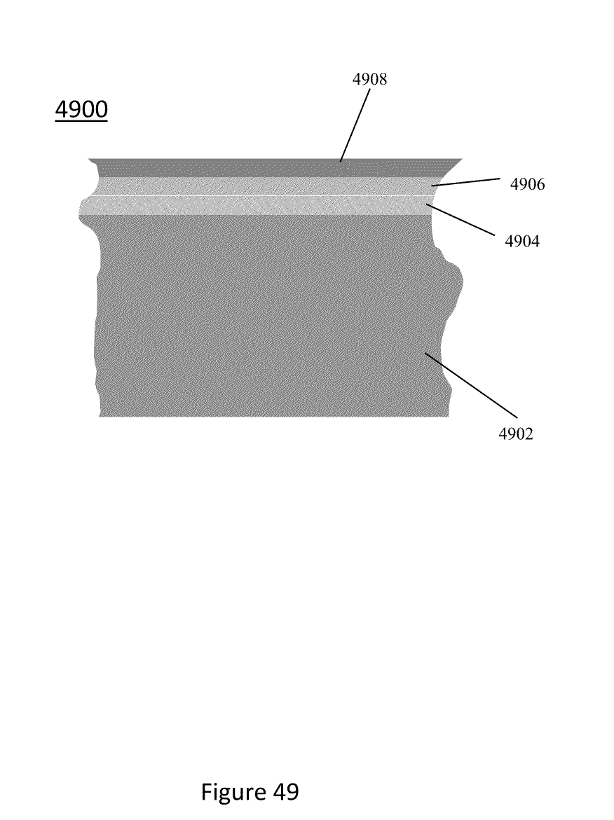

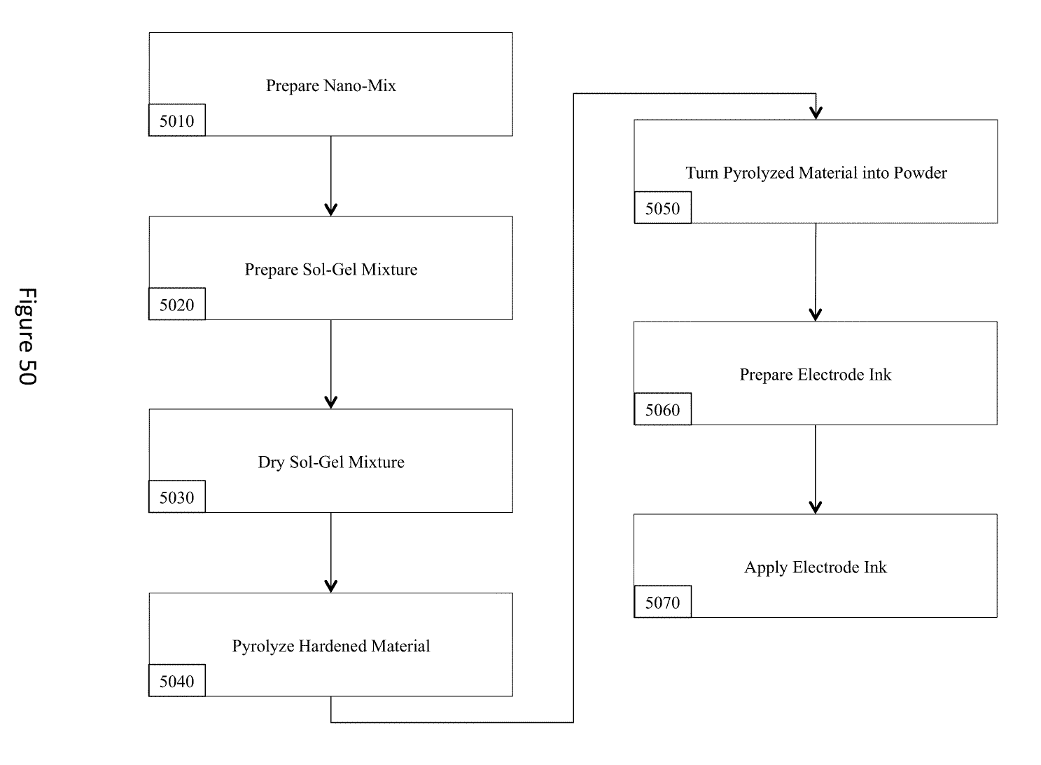

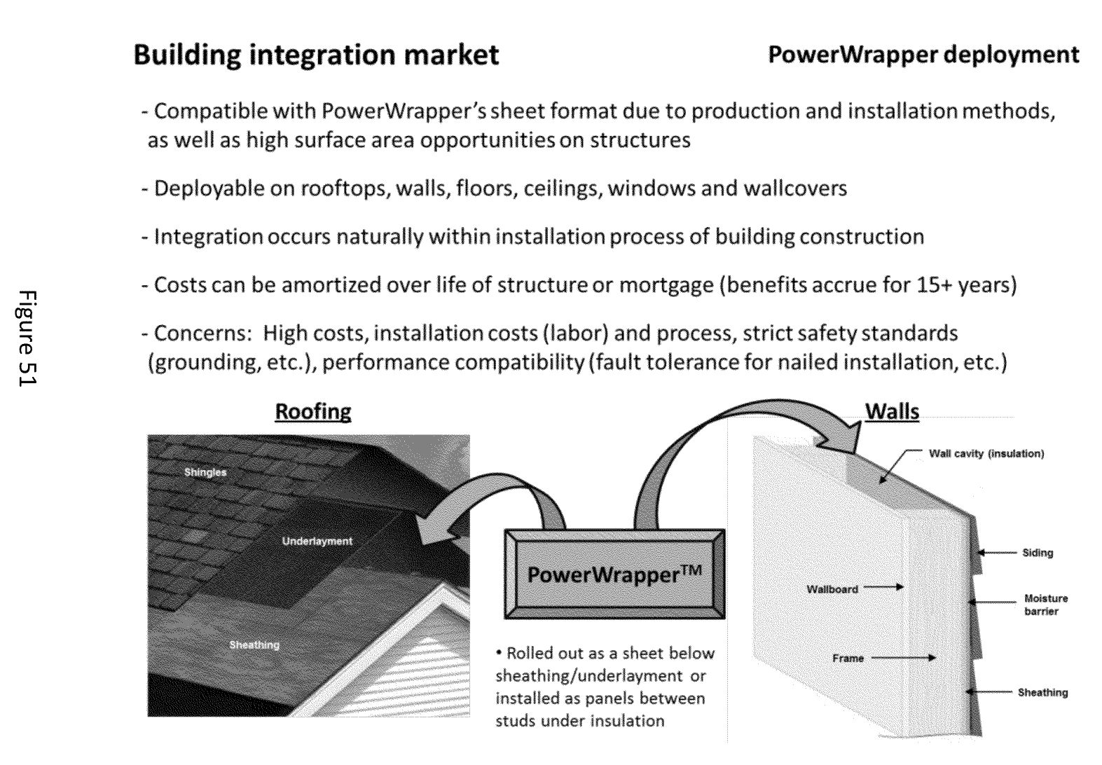

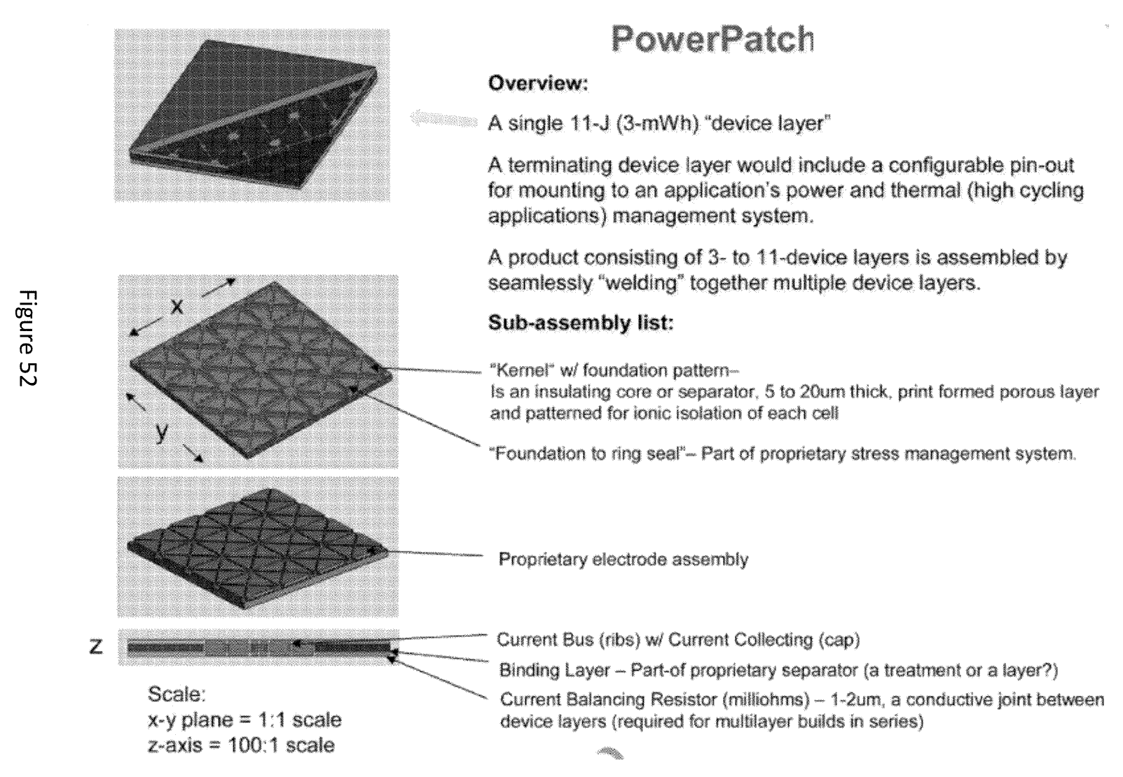

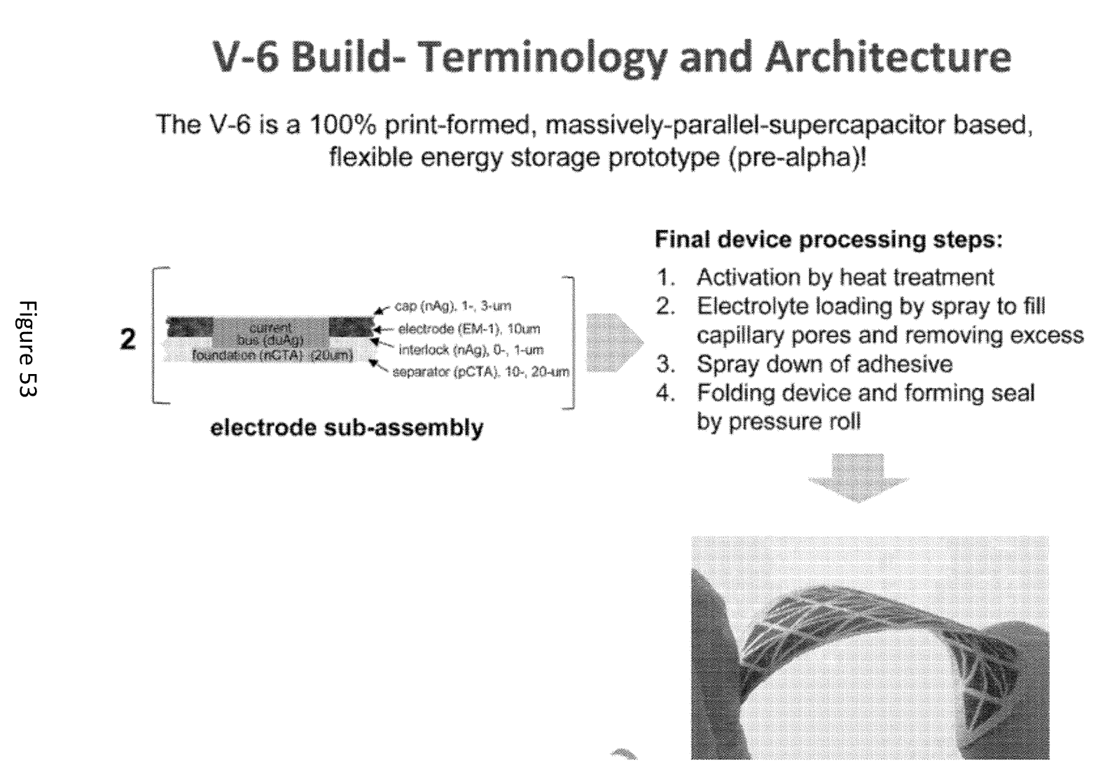

### Old Slide 20, New FIG. 21

FIG. 21 illustrates an exemplary energy storage tape according to certain embodiments. As shown in FIG. 21, the tape can include one or more current collector with electrode layers and one or more separator layers. In the figure cross-sections, the light colorations are the electrode materials.

### 22.) ETape

Single 2 to 3V device
A strip of single 2 to 3V devices
Higher voltages (not shown):
A series build up of single 2 to 3V devices or strips by over lapping edges (shingling)
An energy storage tape aggregate, comprising: a plurality of energy segment elements electrically coupled to an interconnect strip member, wherein the interconnect strip member is adapted to carry electrical current, wherein the plurality of energy segment elements is tunably overlapped such that higher overall voltages are scaled proportional to such overlap.
23.) Higher voltages:
A series stack up of single 2 to 3V devices
By z-folding
Higher capacitances:
A parallel stack up of single 2 to 3V devices
A folded energy storage tape aggregate, adapted for capacitive tuning, comprising: a plurality of successive layers comprising: a plurality of energy segment elements electrically coupled to an interconnect strip member, wherein the interconnect strip member is adapted to carry electrical current; wherein the plurality of successive layers are folded such that ???????
Do the layers need to touch?
24.) Chip/powerpatch device figures
(Uses option A preferred build) below
25.) Option A variation . . . use of Al foil as a “preformed collector”

| Property | Value |
|---|---|
| Dimensions (L × W × H), mm) | 50 × 50 × 3 |
| Weight, g | 5 |
| Operating voltage, V | 14 |
| Internal resistance, Ohms* | 1 |
| Leakage current, mA | 0.2 |
| Energy, J (at 14 V) | 30 |
| Power, W | 49 |
| Bending radius, cm | 20 |
| Operating temperature, C. | 0 to 60 |
| Cycle life at T(op) [% loss/yr) | TBD |

1.) An energy storing sheet apparatus, comprising:
a pressure tight print formed energy storing capsule (cell), comprising:
   self sealing carboneous current collector
   interlocked hairy particle based electrode
   porous separator with non-porous “foundation”
   1a.) massively repeated within print plane
   1b.) massively repeated throughout the plane of the sheet.
   1c.) massively parallel celled sheet
      pinning of electrode material between grain boundary of current collector and separator “welding” or “fusing” of interconnected hairy electrode materials
      synchronized low temperature processing to form pressure tight capsule around separator
      2-3.) A symmetrical half-build apparatus, comprising:
print formed separator module
   Sprayed porous film 5- to 60-um thick
   Pore size distribution
   Pin-hole free (˜3 kV/cm)
electrode member, having an upper and a lower . . .
   deposition of hairy particles capable of forming interlocks
   forming of interlock between nearest neighbors
   preserve transport properties of electrolyte
ring-seal member
   Patterned conductive (bus) or non-conductive (bus & seal)
   Mechanical stress management (capsule forming)
   Electrolyte seal between cells (isolation to ˜4 psi-10 psi)
collector element, upper and lower
   print formed Z-axis or planer (x-y) collection
   Low resistance collection of current from electrode
   Interlocked to electrode and adjacent layer for strength
      Symmetrical half builds
asymmetric evolution
mixed stack-up
   build ups in either direction
   stack-ups in either direction
   asymmetrical build ups in any direction
   tunable balancing and separator/foundation features

### Part A

Development by modules
Separator module
Electrode module
Ring-seal module
Collector module

### Part B—

separator half—Separator/foundation
current collector—collector/bus/electrode

### Alpha Series Build Guide

V-6
Option C
Option B
Option A
   4.) Flexible PCB device figures—one embodiment option C
   Extensibility from option A chip to
   a) Board mounted patterned flexible pcb
   b) embedded into existing pcb

### c) Flexible pcb

d) Flexible pcb embedded into plastic composites (casings)

### One Exemplary Embodiment

Ultra low profile for surface mounted applications in consumer electronics or for embedding within active components. A fault tolerant design uses massively parallel, but isolated, storage cells that enable uninterrupted power even if a loss of some cells occurs or when the product is punctured.
The stiff but flexible PowerPatch enables a conformable power source to meet the needs of special applications. Use of freeform fabrication makes the PowerPatch™ designed for manufacturing in USA.
An energy storing sheet, adapted for print form processing, comprising: a current collecting element formed into a self-sealing element comprising: a current collector member operatively coupled to a sealer element, and; an electrode element.
A method for manufacturing an energy storing sheet, comprising: a means for interlocking and electrode element with a current collector component; means for providing a high internal strength factor of the electrode element; means for providing a high internal strength factor of the current collector component.
26.) Massively parallel cell architecture (isolated cells):
1) architecture
2) Mechanical properties
a) Cloth (fingerling figure) like to stiff (not shown but should be discussed)
b) Strength—tensile
c) Bending radius
d) Fault tolerance (recovery from cuts etc)
3) cut-to-form in field
4) Micro-reactors better than single reactor
27.) Cell Isolation details
Single device
foundation
bus
Isolation element (blow-up) [½ total i.e., a mirror image is not shown]
ring seal (interfacial area)
Mirror image of details above

### 28.) Mechanical Properties Investigation

### Out-of-Plane Rupture

Electrode itself (t)
Electrode/Ring Seal together (x)
   Conventional supercaps have no internal strength
   OOPR-x: 8 mm×8 mm
   OOPR-t: 1.5 mm×1.5 mm
   Flexible PCB with energy storage capability comprising: cut-to-form capabilities with a desired Patch area (cm2) and Capacitance (F)
   An energy storing power patch, comprising: a flexible material member having a scalable patch area; a tunable dimensional element wherein the tunable dimensional element is adapted to scale capacitance proportional to the scalable patch area.
   Flexible PCB with energy storage capability comprising: mechanically, electrically and chemically isolated cells (massively parallel) for enhanced tolerance
   A method of fault tolerance in a Flexible PCB with energy storage capability comprising a recovery algorithm and electronics
   A method of fault tolerance in a Flexible PCB with energy storage capability comprising specified physical characteristics resistance to echem events (e.g., gas build up)
   Flexible PCB with energy storage capability further comprising an active Echem reactor with an area, A and a volume, V of t×A; Equivalent circuit; cycling history; Isolated reactor series; Each patch is composed of 64 triangular shaped cells with area, (tri)=A/64; Within a given device with unit area and volume, P(tot) is proportional to A=64×A(tri); For sealing: in one embodiment 64 m-reactors than a single reactor.
   A Flexible PCB with energy storage capability and method of manufacture comprising “option A” (powerpatch)
   further comprising build cross sections (preferred)
   further comprising build cross sections (alternative)
   further comprising process diagram
   A Flexible PCB with energy storage capability and method of manufacture comprising; PLATE A1—current collector; Web; Aluminum Foil; Conductive adhesive diffusion layer; Foundation—ring seal; Electrode (calendered); PLATE A2—separator; Reusable substrate (metal, glass); (optional) release layer; Porous separator; NonPorous separator
   A Flexible PCB with energy storage capability and method of manufacture comprising: Option A build—and collector design (alternative); Step 1—Form collector sub-assembly; Release layer for release from substrate; XYZ conductor+filler and sealer for xyz, strength, sealing; Conductive interfacial layer for z-axis, interlocking; Step 2—deposit foundation and electrode (patterned); Collector sub-assembly (step 1); Attachment layer for z-axis, interlocking; a) foundation; b) electrode; Step 3—mate parts and seam; T and P; Step 2 component; Attachment layer for interlocking, adhesion; Separator sub-assembly; half-separator
   A Flexible PCB with energy storage capability and method of manufacture comprising the Design objective of A) Generate sealed collector and separator subassemblies, B) deposit electrode, C) mate parts.
   A Flexible PCB with energy storage capability and method of manufacture comprising: Preformed current collector side (Plate A1); Current Collector (CC)—preformed, etched pin-hole free Aluminum foil (7-15 um); Print highly conductive, adhesive diffusion barrier in preparation for electrode deposition (patterned) on CC; Dry (cure) at appropriate temperature if needed (dependent on final materials); Print electrode (patterned); dry at high temperature to drive off water; Print foundation layer for ring seal (patterned); Partial cure ring seal foundation layer (dry in air, or UV cure); Plate A1 prepared; Separator Side (Plate A2); Coat reusable solid substrate with release layer (e.g. PTFE); FreeForm print porous separator coating over entire plate with multiple passes of print head; Convert regions to non porous foundation for ring seal pattern by printing forming pattern; Cure or dry as needed; Print adhesive bonding foundation layer for ring seal (patterned); Partial cure ring seal foundation layer (dry in air, or UV cure); Plate A2 prepared
   A Flexible PCB with energy storage capability and method of manufacture comprising: Half device Plate A formation; Plate A1; Plate A2; Align Plate A1 and A2 foundation pattern; cure; Form Ring Seal; Remove substrate of Plate A2 (separator); Plate A (Half device); Plate B—same process as Plate A; (Half device)
   A Flexible PCB with energy storage capability and method of manufacture comprising: Full device—1 layer; Plate A; Mirrored; Half devices; Plate B; Electrolyte loading; Seam formation at Ring Seal and at outside rim; Sealed, Single layer ‘Patch’ Option A device
   A Flexible PCB with energy storage capability and method of manufacture comprising: Option B—concepts; 1—use of carbon veil in collectors or electrodes or separator; 2—use of carbon veil in all component thick-films (very tough but thick composite) . . . ; ap space is fuselage, solder armor plating etc.; 3—blended composites for enhanced conductivity etc.
   A Flexible PCB with energy storage capability and method of manufacture comprising: Option B build—and collector design (alternative); Step 1—Form collector sub-assembly; Release layer for release from substrate; XYZ conductor+filler and sealer; for xyz, strength, sealing e.g., carbon veil with CTA filler; Conductive interfacial layer for z-axis, interlocking; Step 2—deposit foundation and electrode (patterned); Collector sub-assembly (step 1); Attachment layer for z-axis, interlocking; a) foundation; b) electrode; Step 3—print form separator onto electrode ensemble of step 2; half-separator; T and P; Step 2 component; Absorbent-porous layer for solvent barrier, interlocking, insulation; Print formed Separator w/foundation for electrical isolation, electrolyte reservoir
   A Flexible PCB with energy storage capability and method of manufacture comprising the Design objective: A) Generate sealed collector and separator subassemblies, B) deposit electrode, C) mate parts;
   A Flexible PCB with energy storage capability and method of manufacture comprising an Active sensor embodiment wherein at least one collector is “transparent) to ions, photons, electrons etc.
   A Flexible PCB with energy storage capability and method of manufacture comprising an Active sensor embodiment wherein the active sensor comprises a CCD or CID based sheet
   A Flexible PCB with energy storage capability and method of manufacture comprising an Active sensor embodiment wherein the active sensor comprises a FET addressable device
   A Flexible PCB with energy storage capability and method of manufacture comprising an Energy Storing Sheet wherein the sheet is print form with a pressure tight energy storing capsule (cell) that is then massively repeated throughout the plane of the sheet.
   A Flexible PCB with energy storage capability and method of manufacture comprising an Energy Storing Sheet further comprising an Isolation capsule or cell
   A Flexible PCB with energy storage capability and method of manufacture comprising an Energy Storing Sheet further comprising an Diffuse current collector (biased diffusion of ions, photons etc.)
   A Flexible PCB with energy storage capability and method of manufacture comprising an Energy Storing Sheet further comprising e.g., glassy carbon, some conductive polymers, doped carboneous
   A Flexible PCB with energy storage capability and method of manufacture comprising an Energy Storing Sheet further comprising an interlocked hairy particle based electrode
   A Flexible PCB with energy storage capability and method of manufacture comprising an Energy Storing Sheet further comprising a Porous separator with non-porous “foundation”
   A Flexible PCB with energy storage capability and method of manufacture comprising an Energy Storing Sheet further comprising a Self sealing current collector
   A Flexible PCB with energy storage capability and method of manufacture comprising an Energy Storing Sheet further comprising a massively repeated within print plane
   A Flexible PCB with energy storage capability and method of manufacture comprising an Energy Storing Sheet further comprising a Massively parallel celled sheet
   A Flexible PCB with energy storage capability and method of manufacture comprising an Energy Storing Sheet further comprising an embodiment where there is a pinning of electrode material between grain boundary of current collector and separator
   A Flexible PCB with energy storage capability and method of manufacture comprising an Energy Storing Sheet further comprising an embodiment where there is a “welding” or “fusing” of interconnected hairy electrode materials
   A Flexible PCB with energy storage capability and method of manufacture comprising an Energy Storing Sheet further comprising an embodiment where there is a synchronized low temperature processing to form pressure tight capsule around separator
   A Flexible PCB with energy storage capability and method of manufacture comprising a Separator design wherein the separator is standalone w/and w/o isolation features
   A Flexible PCB with energy storage capability and method of manufacture comprising a Separator design wherein the separator further comprises isolation and strength building features of foundation
   A Flexible PCB with energy storage capability and method of manufacture comprising a Separator design wherein the separator has a chemical reaction isolation for reactive or high temp
   A Flexible PCB with energy storage capability and method of manufacture comprising a Separator design wherein the separator has an enhanced fault tolerance
   A Flexible PCB with energy storage capability and method of manufacture comprising a Separator Module.
   A Flexible PCB with energy storage capability and method of manufacture comprising a Separator Module wherein the inks and processes for print forming a range of mechanical properties (rubber like elasticity to brittle films)
   A Flexible PCB with energy storage capability and method of manufacture comprising a Separator Module wherein the inks and processes to transform porous zones to non-porous zones.
   A Flexible PCB with energy storage capability and method of manufacture comprising a Separator Module wherein the reduction of the number of print steps 10-fold with extensibility to further reduce (5-passes is the design goal)
   A Flexible PCB with energy storage capability and method of manufacture comprising a Separator Module wherein there is extensibility to non-CTA based materials (e.g., Elvax resin and polyurethane)
   A Flexible PCB with energy storage capability and method of manufacture wherein there is a Print formable separator with 100% solid forming inks (non-evaporative process)
   A Flexible PCB with energy storage capability and method of manufacture wherein there is a means to form isolated patterned partitions to isolate electrolyte within cells
   A Flexible PCB with energy storage capability and method of manufacture wherein there are engineered polymeric materials having a wide range of mechanical attributes (e.g, foundation)
   A Flexible PCB with energy storage capability and method of manufacture further comprising 5 mm to 50 mm thick films with greater than 3 KV/cm breakdown voltages
   A Flexible PCB with energy storage capability and method of manufacture wherein there are in-hole free films or ability to recover from pin-holes
   A Flexible PCB with energy storage capability and method of manufacture further comprising a porous, pCTA—(separator)
   A Flexible PCB with energy storage capability and method of manufacture further comprising a pCTA (separator)
   A Flexible PCB with energy storage capability and method of manufacture further comprising a nCTA (fpCTA) (separator)
   A Flexible PCB with energy storage capability and method of manufacture further comprising an Electrode Module.
   A Flexible PCB with energy storage capability and method of manufacture further comprising an Electrode Module further comprising super aggregate of hairy particles
   A Flexible PCB with energy storage capability and method of manufacture further comprising an Electrode Module further comprising Binder (2-types) for super aggregates or hairy particles
   A Flexible PCB with energy storage capability and method of manufacture further comprising an Electrode Module further comprising conductor (cloth like properties)
   Electrode Material for a Flexible PCB with energy storage capability and method of manufacture.
   Electrode Material for a Flexible PCB with energy storage capability and method of manufacture wherein the scale is 0 to 30 nm.
   Electrode Material for a Flexible PCB with energy storage capability and method of manufacture further comprising one or more super-aggregate (hairy particle also).
   Electrode Material for a Flexible PCB with energy storage capability and method of manufacture further comprising phase segregation within sol-gel.
   Electrode Material for a Flexible PCB with energy storage capability and method of manufacture wherein the MWNT or nanowires are fused within aerogel formed from sol-gel
   Electrode Material for a Flexible PCB with energy storage capability and method of manufacture further comprising MWNT or CNT bundles
   Electrode Material for a Flexible PCB with energy storage capability and method of manufacture further comprising nanowires
   Electrode Material for a Flexible PCB with energy storage capability and method of manufacture further comprising aerogel primary particles
   Electrode Material for a Flexible PCB with energy storage capability and method of manufacture wherein one or more electrodes is a cluster of fused super-aggregates
   Electrode Material for a Flexible PCB with energy storage capability and method of manufacture wherein the conductivity between aggregates is made by contact, splicing or fusing of hairs
   Electrode Material for a Flexible PCB with energy storage capability and method of manufacture further comprising a fusion mode for aggregates
   Flexible PCB with energy storage capability and method of manufacture further comprising a current Collector Module (LDL3C)
   Flexible PCB with energy storage capability and method of manufacture further comprising a current Collector Module wherein the print process determines the sealing and mechanical properties of the build
   Flexible PCB with energy storage capability and method of manufacture further comprising a current Collector Module further comprising cloth like properties (z-axis collection . . . “fingerlings”)
   Flexible PCB with energy storage capability and method of manufacture further comprising a current Collector Module further comprising tuned stiffness (planer collection . . . “B” and “Fletcher”)
   Flexible PCB with energy storage capability and method of manufacture further comprising a current Collector Module further comprising 100% Print formed onto porous surfaces for interlocking
   Flexible PCB with energy storage capability and method of manufacture further comprising a current Collector Module further comprising Interlock formation
   Flexible PCB with energy storage capability and method of manufacture further comprising a current Collector Module further comprising low density at Low cost current collector (LDL3C technology), <3 g/cc
   Flexible PCB with energy storage capability and method of manufacture further comprising a current Collector Module further comprising print formable with 100% solids
   Flexible PCB with energy storage capability and method of manufacture further comprising a current Collector Module further comprising under 30 mOhms resistance per film
   Flexible PCB with energy storage capability and method of manufacture further comprising a freeformed fingerlings as z-axis conductors
   Flexible PCB with energy storage capability and method of manufacture further comprising print forming inks with desired characteristics
   Flexible PCB with energy storage capability and method of manufacture further comprising conductive (M) only
   Flexible PCB with energy storage capability and method of manufacture further comprising conductive and non-conductive (M+P) mixed
   Flexible PCB with energy storage capability and method of manufacture further comprising non-conductive (P) only
   Flexible PCB with energy storage capability and method of manufacture f further comprising after print
   Flexible PCB with energy storage capability and method of manufacture further comprising densification
   Flexible PCB with energy storage capability and method of further comprising a final form
   Flexible PCB with energy storage capability and method of further comprising a cap
   Flexible PCB with energy storage capability and method of manufacture further comprising one or more filament (fingerling)
   Flexible PCB with energy storage capability and method of manufacture further comprising a non-conductive matrix
   Flexible PCB with energy storage capability and method of manufacture further comprising a freeform fabricated low density conductive film
   Flexible PCB with energy storage capability and method of manufacture further comprising a Rough side of film (air interface) wherein: Rth=rs t/A; Rth=(1)(0.001)/(0.33); Rth=3 mohms; Assume 10 microns; conductive surface; conductive core.
   Smooth side of film (substrate interface)

### Rth=rpp t/A

### Rth=(34)(0.001)/(0.33)

Rth=103 mohms
print process

### Solution

Non-conductive surface
conductive core

53.) density of platelets and fibers!
Fibers and platelets within film boundaries
   (interconnectivity of “white” lines for conduction)
   platelets within film boundaries
   A method of providing power to a non-planar encasement lining comprising the steps of: Providing a flexible PCB with energy storage capability; Conforming the flexible PCB to fit the encasement
   Flexible PCB with energy storage capability comprising: the use of Al foil as a “preformed collector”
   Flexible PCB with energy storage capability comprising: the following physical properties:

| Property | Value |
|---|---|
| Dimensions (L × W × H), mm) | 50 × 50 × 3 |
| Weight, g | 5 |
| Operating voltage, V | 14 |
| Internal resistance, Ohms* | 1 |
| Leakage current, mA | 0.2 |
| Energy, J (at 14 V) | 30 |
| Power, W | 49 |
| Bending radius, cm | 20 |
| Operating temperature, C. | 0 to 60 |
| Cycle life at T(op) [% loss/yr) | TBD |

Flexible PCB with energy storage capability comprising: Ultra low profile for surface mounted applications in consumer electronics or for embedding within active components.
Flexible PCB with energy storage capability comprising: A fault tolerant design further comprising massively parallel, but isolated, storage cells that enable uninterrupted power even if a loss of some cells occurs or when the product is punctured.
Flexible PCB with energy storage capability comprising: The stiff but flexible PowerPatch enables a conformable power source to meet the needs of special applications.
Flexible PCB with energy storage capability comprising: freeform fabrication to enable the following electrical/power characteristics: 6V, 14 J, 4.5 W alpha build
Product Configurations—1 (saddle bagged module)*
An energy storage device comprising two linked units such that the units may be supported by the device using the energy provided.
ETape application: An energy storage sheet comprising one or more parallel isolated energy storage devices.
Flexible PCB with energy storage capability comprising: Electrode and half-separator
59.) Flexible PCB with energy storage capability comprising:
Plate A1—current collector; Web; Aluminum foil; Conductive adhesive diffusion layer; Foundation—ring seal; Electrode (calendered); Plate A2—separator; Reusable substrate (metal, glass); (optional) release layer; Porous separator; Non-Porous separator

What is claimed is:

1.) A print formed energy storing and dispensing sheeting, comprising:
(a.) a printed isolated massively parallel energy storing and dispensing sealed elements or cells, and;
(b.) at least one printed interconnection.

2.) An energy storing and dispensing sheeting, comprising:
(a.) a printed porous separator having patterned non-porous continuous foundation;
(b.) at least one printed compact electrode, and;
(c.) at least one printed current collector.

3.) The energy storing and dispensing sheeting of claim 2, further comprising a plurality of sealed massively parallel isolated cells.

4.) A flexible printed circuit board, comprising:
(a.) a print formed power plane;
(b.) a print formed ground plane;
(c.) a print formed energy storing massively paralleled cells, and;
(d.) a printed pattered open region having an electronic interconnection.

5- Claim 4 that is serial stackable for higher voltages

6- Claim 4 that is parallel stackable for higher capacitances
